(19) United States
(12) Patent Application Publication
(10) Pub. No.: US 2023/0391800 A1
(43) Pub. Date: Dec. 7, 2023

(54) ORGANIC MOLECULES FOR OPTOELECTRONIC DEVICES

(71) Applicant: CYNORA GMBH, Bruchsal (DE)

(72) Inventors: Sebastian DÜCK, Heidelberg (DE); Nico-Patrick THÖBES, Bruchsal (DE); Damien JOLY, Beinheim (FR)

(21) Appl. No.: 18/249,527

(22) PCT Filed: Oct. 22, 2021
(86) PCT No.: PCT/EP2021/079337

§ 371 Date: Apr. 18, 2023

(30) Foreign Application Priority Data
Oct. 23, 2020 (EP) 20203549.9

(51) Int. Cl. C07F 5/02; H10K 85/60; C09K 11/06

(52) U.S. Cl. CPC C07F 5/027; H10K 85/658; H10K 85/631; C09K 11/06; C07B 2200/05

(57) ABSTRACT

The disclosure provides an organic molecule for use in optoelectronic devices. The organic molecule has a structure of formula I. The variables in formula I are as defined in the disclosure.

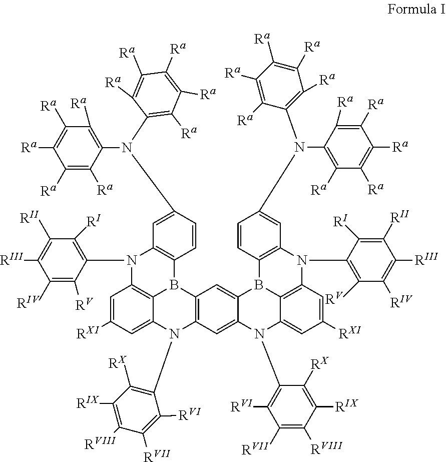

### CROSS-REFERENCE TO RELATED APPLICATIONS

This application is a U.S. National Phase Patent Application of International Patent Application Number PCT/EP2021/079337, filed on Oct. 22, 2021, which claims priority to European Patent Application Number 20203549.9, filed on Oct. 23, 2020, the entire content of all of which is hereby incorporated by reference.

### FIELD

Embodiments of the present disclosure relates to light-emitting organic molecules and their use in organic light-emitting diodes (OLEDs) and in other optoelectronic devices.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 Emission spectrum of example 1 (2% by weight) in PMMA.

FIG. 2 Emission spectrum of example 2 (2% by weight) in PMMA.

FIG. 3 Emission spectrum of example 3 (2% by weight) in PMMA.

FIG. 4 Emission spectrum of example 4 (2% by weight) in PMMA.

FIG. 5 Emission spectrum of example 5 (2% by weight) in PMMA.

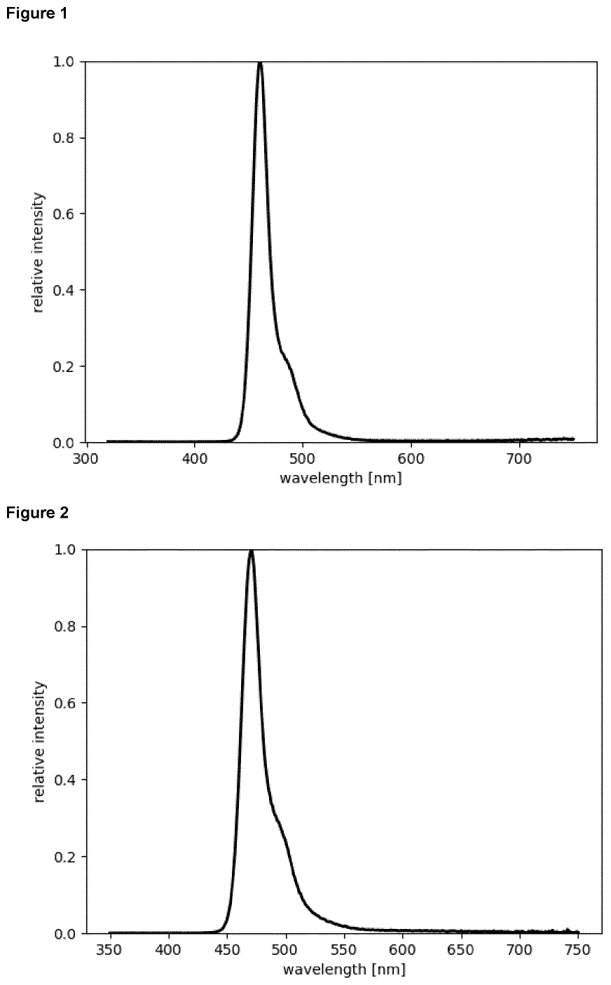

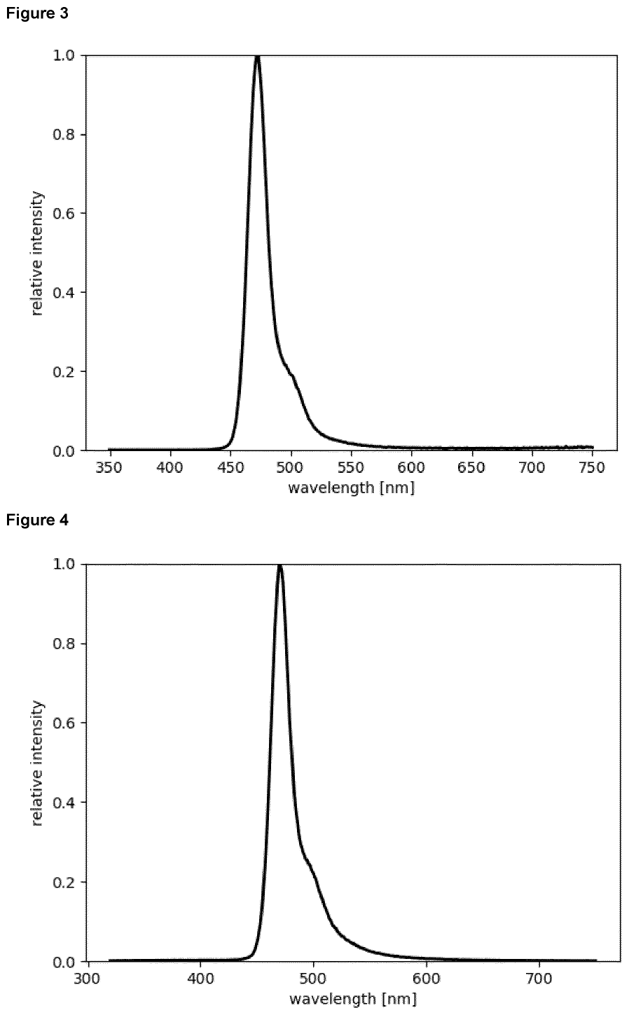

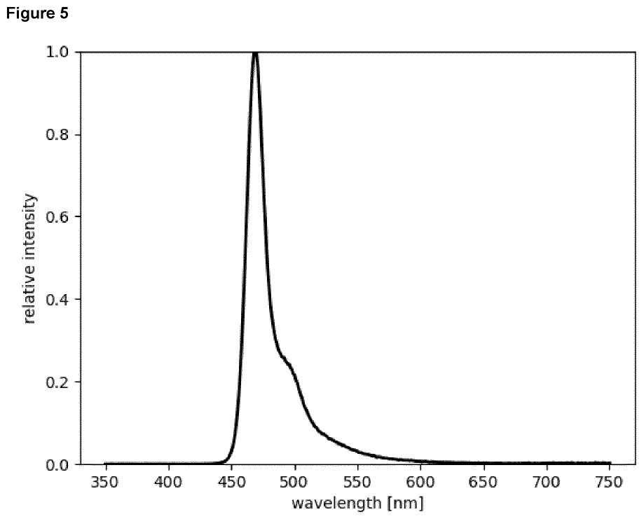

### DETAILED DESCRIPTION

An object of embodiments of the present disclosure is to provide molecules which are suitable for use in optoelectronic devices.

This object is achieved by embodiments of the present disclosure which provides a class of organic molecules.

Optoelectronic devices containing one or more light-emitting layers based on organics such as, e.g., organic light emitting diodes (OLEDs), light emitting electrochemical cells (LECs) and light-emitting transistors gain increasing importance. For example, OLEDs are promising devices for electronic products such as screens, displays and illumination devices. In contrast to most electroluminescent devices essentially based on inorganics, organic optoelectronic devices based on organics are often rather flexible and producible in particularly thin layers. The OLED-based screens and displays already available today have either good efficiencies and long lifetimes or good color purity and long lifetimes, but do not combine all three properties, e.g., good efficiency, long lifetime, and good color purity.

Thus, there is still an unmet technical need for optoelectronic devices which have a high quantum yield, a long lifetime, and good color purity.

The color purity and/or color point of an OLED may generally be provided by CIEx and CIEy coordinates, whereas the color gamut for the next display generation is provided by so-called BT-2020 and DCPI3 values. Generally, in order to achieve these color coordinates, top emitting devices are needed to adjust the color coordinates by changing the cavity. In order to achieve high efficiency in top emitting devices while targeting this color gamut, a narrow emission spectrum in bottom emitting devices is required or desired.

The organic molecules according to embodiments of the present disclosure exhibit emission maxima in the deep blue, sky blue, or green spectral range, in the deep blue, or sky blue spectral range, or in the deep blue spectral range. The organic molecules exhibit emission maxima between 420 nm and 520 nm, between 440 nm and 495 nm, or between 450 nm and 475 nm. The photoluminescence quantum yields of the organic molecules according to embodiments of the present disclosure are, for example, 50% or more. The excited state lifetime is not more than 4 μs. Additionally, the molecules of embodiments of the present disclosure exhibit a narrow—expressed by a small full width at half maximum (FWHM)—emission. The emission spectra of the organic molecules show a full width at half maximum (FWHM) of less than or equal to 0.15 eV (0.15 eV), unless stated otherwise, measured with 2% by weight of emitter in poly(methyl methacrylate) PMMA at room temperature (e.g., approximately 25° C.). The photoluminescence quantum yields of the organic molecules according to embodiments of the present disclosure are, for example, 50% or more.

The use of the molecules according to embodiments of the present disclosure in an optoelectronic device, for example, an organic light-emitting diode (OLED), leads to a narrow emission and high efficiency of the device. Corresponding OLEDs have a higher stability than OLEDs including existing emitter materials and comparable color and/or by employing the molecules according to embodiments of the present disclosure in an OLED display, a more accurate reproduction of visible colors in nature, e.g., a higher resolution in the displayed image, is achieved. In one or more embodiments, the molecules can be used in combination with an energy pump to achieve hyper-fluorescence and/or hyper-phosphorescence. In these cases, another species included in an optoelectronic device transfers energy to the organic molecules of embodiments of the present disclosure which then emit light.

The organic molecules according to embodiments of the present disclosure include or consist of a structure of formula I:

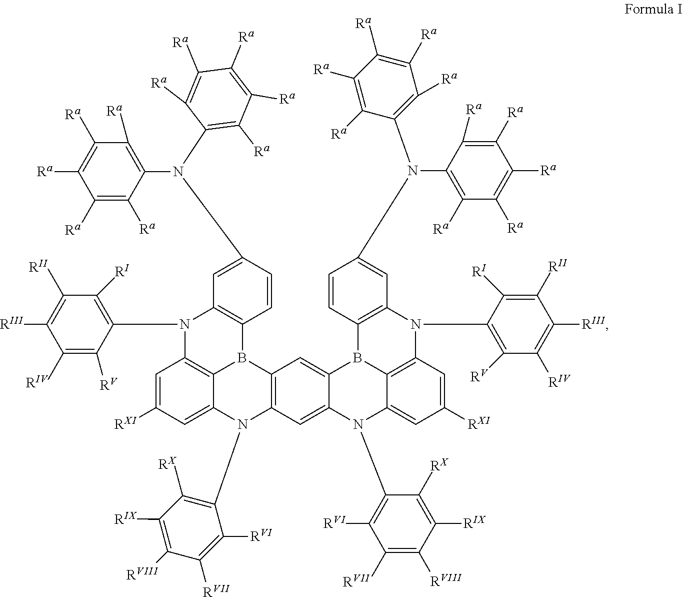

wherein:
R^{a} is at each occurrence independently selected from the group consisting of:
hydrogen, deuterium, N(R⁵)₂, OR⁵, SR⁵, CF₃, CN, halogen,
C₁-C₄₀ alkyl,
which is optionally substituted with one or more substituents R⁵ and
wherein one or more non-adjacent CH₂ groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀ alkoxy,
which is optionally substituted with one or more substituents R⁵ and
wherein one or more non-adjacent CH₂ groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀ thioalkoxy,
which is optionally substituted with one or more substituents R⁴ and
wherein one or more non-adjacent CH₂ groups are optionally substituted by R⁵C═CR⁵, CC, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀ aryl,
which is optionally substituted with one or more substituents R⁵; and
C₃-C₅₇ heteroaryl,
which is optionally substituted with one or more substituents R⁵;
R⁵ is at each occurrence independently selected from the group consisting of:
hydrogen, deuterium, halogen,
C₁-C₁₂ alkyl,
wherein optionally one or more hydrogen atoms are independently substituted by R⁶;
C₆-C₁₈ aryl,
wherein optionally one or more hydrogen atoms are independently substituted R⁶; and
C₃-C₁₅ heteroaryl,
wherein optionally one or more hydrogen atoms are independently substituted R⁶;
R⁶ is at each occurrence independently selected from the group consisting of:
hydrogen, deuterium, halogen,
C₁-C₁₂ alkyl,
C₆-C₁₈ aryl,
wherein optionally one or more hydrogen atoms are independently substituted by C₁-C₅ alkyl substituents; and
C₃-C₁₅ heteroaryl,
wherein optionally one or more hydrogen atoms are independently substituted by C₁-C₅ alkyl substituents;
R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen, deuterium, N(R⁴)₂, OR⁴, SR⁴, Si(R⁴)₃, B(OR⁴)₂, OSO₂R⁴, CF₃, CN, halogen,
C₁-C₄₀ alkyl,
which is optionally substituted with one or more substituents R⁴ and
wherein one or more non-adjacent CH₂ groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀ alkoxy,
which is optionally substituted with one or more substituents R⁴ and
wherein one or more non-adjacent CH₂ groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀ thioalkoxy,
which is optionally substituted with one or more substituents R⁴ and
wherein one or more non-adjacent CH₂ groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀ alkenyl,
which is optionally substituted with one or more substituents R⁴ and
wherein one or more non-adjacent CH₂ groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀ alkynyl,
which is optionally substituted with one or more substituents R⁴ and
wherein one or more non-adjacent CH₂ groups are optionally substituted by R⁴C═CR⁴, CC, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₆₀ aryl,
which is optionally substituted with one or more substituents R⁴; and
C₃-C₅₇ heteroaryl,
which is optionally substituted with one or more substituents R⁴;
R⁴ is at each occurrence independently from another selected from the group consisting of:
hydrogen, deuterium, halogen, Oph (Ph=phenyl), SPh, CF₃, CN, Si(C₁-C₅ alkyl)₃, Si(Ph)₃,
C₁-C₅ alkyl,
wherein optionally one or more hydrogen atoms are independently substituted by deuterium, halogen, CN, or CF₃;
C₁-C₅ alkoxy,
wherein optionally one or more hydrogen atoms are independently substituted by deuterium, halogen, CN, or CF₃;
C₁-C₅ thioalkoxy,
wherein optionally one or more hydrogen atoms are independently substituted by deuterium, halogen, CN, or CF₃;
C₂-C₅ alkenyl,
wherein optionally one or more hydrogen atoms are independently substituted by deuterium, halogen, CN, or CF₃;
C₂-C₅ alkynyl,
wherein optionally one or more hydrogen atoms are independently substituted by deuterium, halogen, CN, or CF₃;
C₆-C₁₈ aryl,
which is optionally substituted with one or more substituents R⁵;
C₃-C₁₇ heteroaryl,
which is optionally substituted with one or more substituents R⁵;
N(C₆-C₁₈ aryl)₂,
N(C₃-C₁₇ heteroaryl)₂; and
N(C₃-C₁₇ heteroaryl)(C₆-C₁₈ aryl).

In one embodiment of the present disclosure, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In one embodiment of the present disclosure R^{I}, R^{II}, R^{III}, R^{IV}, R^{V}, R^{VI}, R^{VII}, R^{VIII}, R^{IX} R^{X}, and R^{XI} are at each occurrence independently selected from the group consisting of:
hydrogen, Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph.

In one embodiment of the present disclosure, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen, Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph.

In one embodiment of the present disclosure, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, F

Ph, which is optionally substituted with one or more substituents independently from each other selected from the group consisting of Me, ⁱPr, ^{t}Bu, CN, CF₃, F and Ph.

In one embodiment of the present disclosure, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, F

Ph, which is optionally substituted with one or more substituents independently from each other selected from the group consisting of Me, ⁱPr, ^{t}Bu, and Ph.

In one embodiment of the present disclosure, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph.

In an embodiment of the present disclosure, R^{I} and R^{X} are hydrogen.

In a certain embodiment of the present disclosure, R^{I}, R^{V}, R^{VI} and R^{X} are hydrogen.

In one embodiment of the present disclosure, R^{XI} is at each occurrence independently selected from the group consisting of:
hydrogen,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In an embodiment of the present disclosure, R^{XI} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In an embodiment of the present disclosure, R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In one embodiment of the present disclosure, R^{XI} is at each occurrence independently selected from the group consisting of:
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a certain embodiment of the present disclosure, R^{XI} is at each occurrence independently:
N(Ph)₂, which is optionally substituted with one or more substituents independently from each other selected from the group consisting of Me, ⁱPr, ^{t}Bu, and Ph.

In one embodiment of the present disclosure, R^{XI} is at each occurrence independently N(Ph)₂.

In one embodiment of the present disclosure, R^{a} is at each occurrence independently selected from the group consisting of:
hydrogen,
Me, ⁱPr, ^{t}Bu, CN, CF₃, F,
Aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, R^{a} is at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, R^{a} is at each occurrence independently selected from the group consisting of:
hydrogen,
Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
and N(Ph)₂, which is optionally substituted with one or more substituents independently from each other selected from the group consisting of Me, ⁱPr, ^{t}Bu, F and Ph.

In a further embodiment of the present disclosure, R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, R^{a} is at each occurrence independently selected from the group consisting of:
hydrogen,
Me, ⁱPr, ^{t}Bu,
and
Ph, which is optionally substituted with one or more substituents independently from each other selected from the group consisting of Me, ⁱPr, ^{t}Bu, and Ph.

In one embodiment of the present disclosure, R^{a} is at each occurrence independently selected from the group consisting of:
hydrogen,
Ph.

In one embodiment of the present disclosure, R^{a} is at each occurrence hydrogen.

In an embodiment of the present disclosure, R^{V}═R^{X} and R^{I}═R^{VI}.

In one embodiment of the present disclosure, R⁵ is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph.

In one embodiment of the present disclosure, R⁵ is at each occurrence independently selected from the group consisting of:
hydrogen, and
Ph.

In one embodiment of the present disclosure, R⁵ is at each occurrence hydrogen.

In one embodiment of the present disclosure, the organic molecules include or consist of a structure of formula II-a, formula II-b and formula II-c:

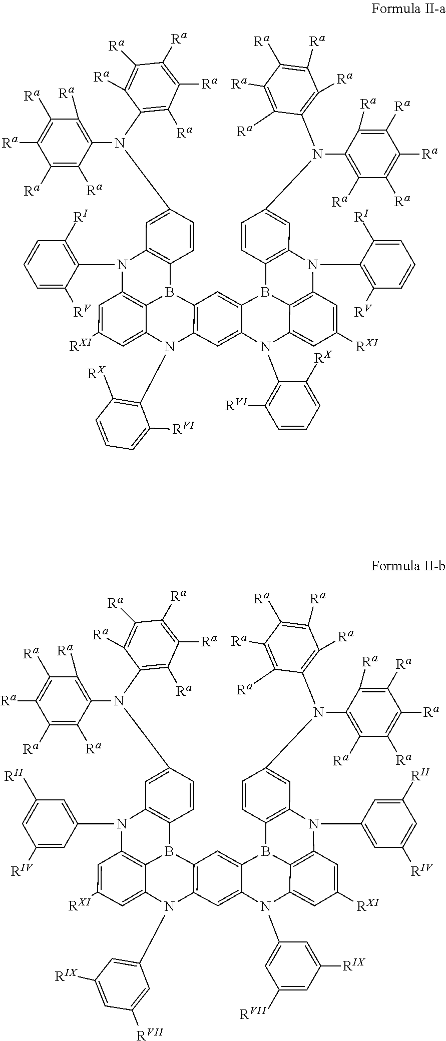

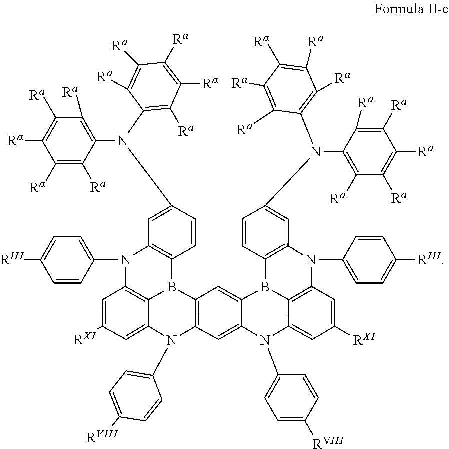

In this description, reference to the substituents R^{I} to R^{XI} of may be made in a general manner in connection to example structures, such as those of the formulas II-a, II-b and II-c. A person of skill in the art will appreciate that the formulas define certain substituents to be hydrogen. In that case, only the remaining substituents may be chosen from the groups defined herein.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph,

if not defined to be H in formulas II-a, II-b, and II-c, respectively.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,

if not defined to be H in formulas II-a, II-b, and II-c, respectively.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
if not defined to be H in formulas II-a, II-b, and II-c, respectively.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
if not defined to be H in formulas II-a, II-b, and II-c, respectively.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, and Ph,
if not defined to be H in formulas II-a, II-b, and II-c, respectively.

In one embodiment of the present disclosure, the organic molecules include or consist of a structure according to any selected from formulas II-a, II-b, II-c, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
if not defined to be H in formulas II-a, II-b, and II-c, respectively.

In an embodiment of the present disclosure, the organic molecules include or consist of a structure according to any selected from formulas II-a, II-b, II-c, wherein R^{I} and R^{X} are hydrogen.

In a certain embodiment of the present disclosure, the organic molecules include or consist of a structure according to any selected from formulas II-a, II-b, II-c, wherein R^{I}, R^{V}, R^{VI} and R^{X} are hydrogen.

In one embodiment of the present disclosure, the organic molecules include or consist of a structure according to any selected from formulas II-a, II-b, II-c, wherein R^{XI} is at each occurrence independently selected from the group consisting of:
hydrogen,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In an embodiment of the present disclosure, the organic molecules include or consist of a structure according to any selected from formulas II-a, II-b, II-c, wherein R^{XI} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In an embodiment of the present disclosure, the organic molecules include or consist of a structure according to any selected from formulas wherein II-a, II-b, II-c, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In one embodiment of the present disclosure, the organic molecules include or consist of a structure according to any selected from formulas II-a, II-b, II-c, wherein R^{XI} is at each occurrence independently selected from the group consisting of:
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a certain embodiment of the present disclosure, the organic molecules include or consist of a structure according to any selected from formulas II-a, II-b, II-c, wherein R^{XI} is at each occurrence independently:
N(Ph)₂, which is optionally substituted with one or more substituents independently from each other selected from the group consisting of Me, ⁱPr, ^{t}Bu, and Ph.

In one embodiment of the present disclosure, the organic molecules include or consist of a structure according to any selected from formulas II-a, II-b, II-c, wherein R^{XI} is at each occurrence independently:
N(Ph)₂.

In one embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu, CN, CF₃, F,
Aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure according to any selected from formulas II-a, II-b, II-c, wherein R^{a} is at each occurrence independently selected from the group consisting of:
hydrogen,
Me, ⁱPr, ^{t}Bu, and
Ph, which is optionally substituted with one or more substituents independently from each other selected from the group consisting of Me, ⁱPr, ^{t}Bu, and Ph.

In an embodiment of the present disclosure, the organic molecules include or consist of a structure according to any selected from formulas II-a, II-b, II-c, wherein R^{V}═R^{X} and R^{I}═R^{VI}.

In an embodiment of the present disclosure, the organic molecules include or consist of a structure of formula II-a.

In an embodiment of the present disclosure, the organic molecules include or consist of a structure of formula II-a, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, F, and Ph.

In one embodiment of the present disclosure, the organic molecules include or consist of a structure of formula II-a, wherein R^{XI} is at each occurrence independently selected from the group consisting of:
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a certain embodiment of the present disclosure, the organic molecules include or consist of a structure of formula II-a, wherein R^{XI} is at each occurrence independently:
N(Ph)₂, which is optionally substituted with one or more substituents independently from each other selected from the group consisting of Me, ⁱPr, ^{t}Bu, and Ph.

In one embodiment of the present disclosure, the organic molecules include or consist of a structure of formula II-a, wherein R^{XI} is at each occurrence independently:
N(Ph)₂.

In another embodiment of the present disclosure, the organic molecules include or consist of a structure of formula III:

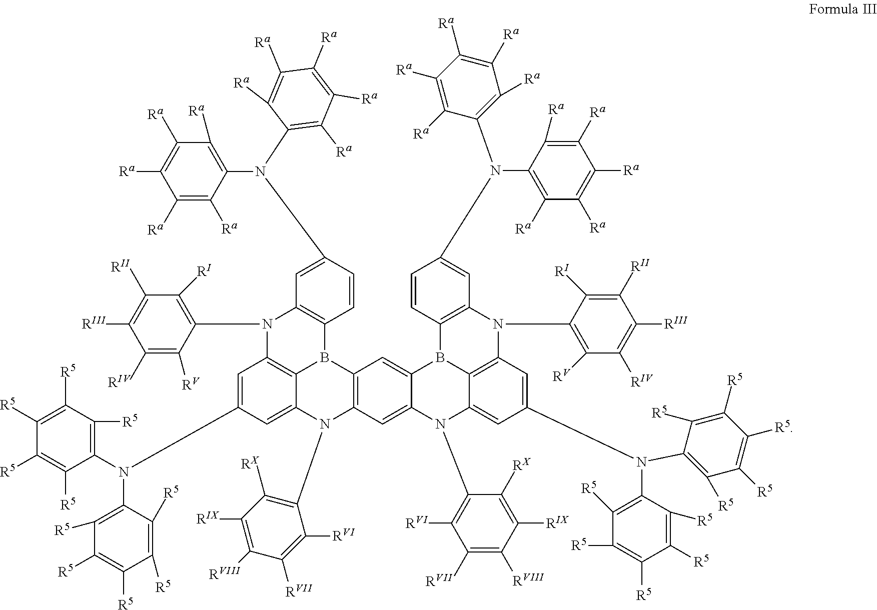

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, and Ph.

In one embodiment of the present disclosure, the organic molecules include or consist of a structure of formula III, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph.

In an embodiment of the present disclosure, the organic molecules include or consist of a structure of formula III, wherein R^{I} and R^{X} are hydrogen.

In a certain embodiment of the present disclosure, the organic molecules include or consist of a structure of formula III, wherein R^{I}, R^{V}, R^{VI} and R^{X} are hydrogen.

In one embodiment of the present disclosure, the organic molecules include or consist of a structure of formula III, wherein R^{XI} is at each occurrence independently selected from the group consisting of:
hydrogen,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In an embodiment of the present disclosure, the organic molecules include or consist of a structure of formula III, wherein R^{XI} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In an embodiment of the present disclosure, the organic molecules include or consist of a structure of formula III, wherein R^{XI} is at each occurrence independently selected from the group consisting of:
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In one embodiment of the present disclosure, the organic molecules include or consist of a structure of formula III, wherein R^{XI} is at each occurrence independently selected from the group consisting of:
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a certain embodiment of the present disclosure, the organic molecules include or consist of a structure of formula III, wherein R^{XI} is at each occurrence independently:
N(Ph)₂, which is optionally substituted with one or more substituents independently from each other selected from the group consisting of Me, ⁱPr, ^{t}Bu, and Ph.

In one embodiment of the present disclosure, the organic molecules include or consist of a structure of formula III, wherein R^{XI} is at each occurrence independently:
N(Ph)₂.

In one embodiment of the present disclosure, the organic molecules include or consist of a structure of formula III, wherein R^{a} is at each occurrence independently selected from the group consisting of:
hydrogen,
Me, ⁱPr, ^{t}Bu, CN, CF₃, F,
aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula III, wherein R^{a} is at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula III, wherein R^{a} is at each occurrence independently selected from the group consisting of:
hydrogen,
Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula III, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure of formula III, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure of formula III, wherein R^{a} is at each occurrence independently selected from the group consisting of:
hydrogen,
Me, ⁱPr, ^{t}Bu, and
Ph, which is optionally substituted with one or more substituents independently from each other selected from the group consisting of Me, ⁱPr, ^{t}Bu, and Ph.

In an embodiment of the present disclosure, the organic molecules include or consist of a structure of formula III, wherein R^{V}═R^{X} and R^{I}═R^{VI}.

In another embodiment of the present disclosure, the organic molecules include or consist of a structure of formula IV:

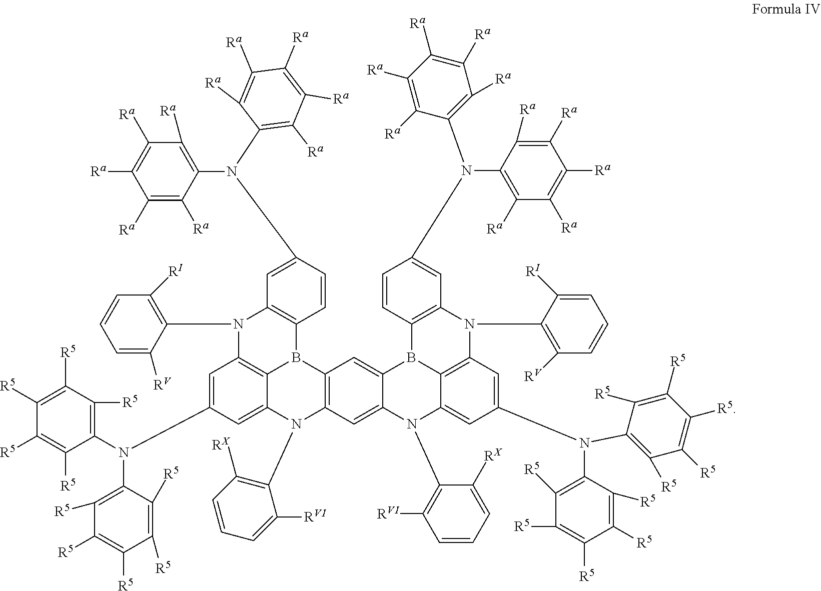

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph.

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, and Ph.

In one embodiment of the present disclosure, the organic molecules include or consist of a structure of formula IV, wherein R^{I}, R^{V}, R^{VI}, and R^{X} are at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph.

In an embodiment of the present disclosure, the organic molecules include or consist of a structure of formula IV, wherein R^{I} and R^{X} are hydrogen.

In a certain embodiment of the present disclosure, the organic molecules include or consist of a structure of formula IV, wherein R^{I}, R^{V}, R^{VI}, and R^{X} are at each occurrence independently selected from the group consisting of:
Hydrogen, Me, F.

In a certain embodiment of the present disclosure, the organic molecules include or consist of a structure of formula IV, wherein R^{I}, and R^{X} are at each occurrence independently selected from the group consisting of: Me, F.

In one embodiment of the present disclosure, the organic molecules include or consist of a structure of formula IV, wherein R^{a} is at each occurrence independently selected from the group consisting of:
hydrogen,
Me, ⁱPr, ^{t}Bu, CN, CF₃, F,
Aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula IV, wherein R^{a} is at each occurrence independently selected from the group consisting of:
hydrogen,
Me, ⁱPr, ^{t}Bu, F,
Ph, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula IV, wherein R^{a} is at each occurrence independently selected from the group consisting of:
hydrogen,
Me, ⁱPr, ^{t}Bu, F
Ph, which is optionally substituted with one or more substituents independently from each other selected from the group consisting of Me, ⁱPr, ^{t}Bu, F and Ph,
carbazolyl, which is optionally substituted with one or more substituents independently from each other selected from the group consisting of Me, ⁱPr, ^{t}Bu, F and Ph,
and N(Ph)₂, which is optionally substituted with one or more substituents independently from each other selected from the group consisting of Me, ⁱPr, ^{t}Bu, F and Ph.

In a further embodiment of the present disclosure, the organic molecules include or consist of a structure of formula IV, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
carbazolyl, which is optionally substituted with one or more substituents independently from each other selected from the group consisting of Me, ⁱPr, ^{t}Bu, and Ph, and
N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure of formula IV, wherein R^{a} is at each occurrence independently selected from the group consisting of:
hydrogen,
Me, ⁱPr, ^{t}Bu,
Ph, which is optionally substituted with one or more substituents independently from each other selected from the group consisting of Me, ⁱPr, ^{t}Bu, and Ph,
and N(Ph)₂, which is optionally substituted with one or more substituents independently from each other selected from the group consisting of Me, ⁱPr, ^{t}Bu, and Ph.

In a further embodiment of the present disclosure, the organic molecules include or consist of a structure of formula IV, wherein R^{a} is at each occurrence independently selected from the group consisting of:
hydrogen,
Me, ⁱPr, ^{t}Bu, and
Ph, which is optionally substituted with one or more substituents independently from each other selected from the group consisting of Me, ⁱPr, ^{t}Bu, and Ph.

In an embodiment of the present disclosure, the organic molecules include or consist of a structure of formula IV, wherein R^{V}═R^{X} and R^{I}═R^{VI}.

In one embodiment of the present disclosure, the organic molecules include or consist of a structure of formula IV, wherein R^{a} is at each occurrence independently selected from the group consisting of:
hydrogen, and
Ph.

In one embodiment of the present disclosure, the organic molecules include or consist of a structure of formula IV, wherein R^{a} is at each occurrence hydrogen.

In one embodiment of the present disclosure, the organic molecules include or consist of a structure of formula IV, wherein R⁵ is at each occurrence independently selected from the group consisting of:
hydrogen,
Me, ⁱPr, ^{t}Bu, and
Ph, which is optionally substituted with one or more substituents independently from each other selected from the group consisting of Me, ⁱPr, ^{t}Bu, and Ph.

In one embodiment of the present disclosure, the organic molecules include or consist of a structure of formula IV, wherein R⁵ is at each occurrence independently selected from the group consisting of:
hydrogen, and
Ph.

In one embodiment of the present disclosure, the organic molecules include or consist of a structure of formula IV, wherein R⁵ is at each occurrence hydrogen.

In another embodiment of the present disclosure, the organic molecules include or consist of a structure of formula V:

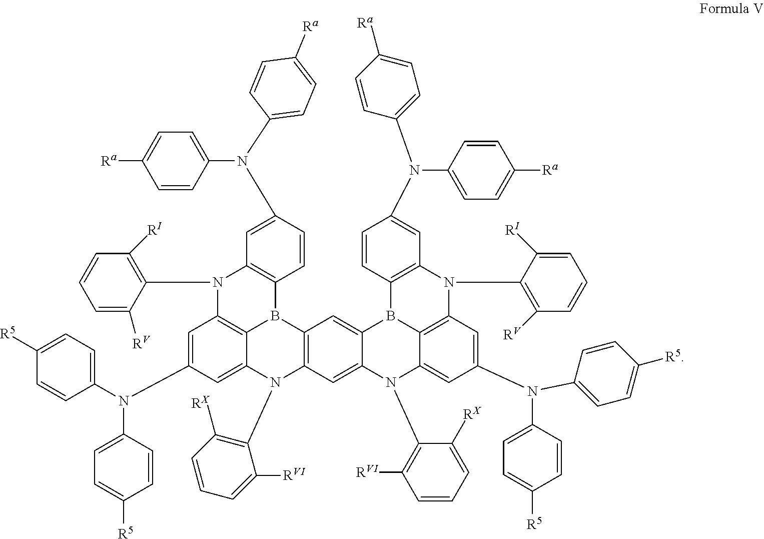

As used throughout the present application, the term “cyclic group” may be understood in the broadest sense as any suitable mono-, bi- or polycyclic moieties.

As used throughout the present application, the terms “ring” and “ring system” may be understood in the broadest sense as any suitable mono-, bi- or polycyclic moieties.

As used throughout the present application, the term “carbocycle” may be understood in the broadest sense as any suitable cyclic group in which the cyclic core structure includes only carbon atoms that may of course be substituted with hydrogen or any other suitable substituents defined in the example embodiments of the present disclosure. It is understood that the term “carbocyclic” as adjective refers to cyclic groups in which the cyclic core structure includes only carbon atoms that may of course be substituted with hydrogen or any other suitable substituents defined in the example embodiments of the present disclosure.

As used throughout the present application, the term “heterocycle” may be understood in the broadest sense as any suitable cyclic group in which the cyclic core structure includes not just carbon atoms, but also at least one heteroatom. It is understood that the term “heterocyclic” as adjective refers to cyclic groups in which the cyclic core structure includes not just carbon atoms, but also at least one heteroatom.

The heteroatoms may, unless stated otherwise in example embodiments, at each occurrence be the same or different and be individually selected from the group consisting of N, O, S, and Se. All carbon atoms or heteroatoms included in a heterocycle in the context of embodiments of the present disclosure may of course be substituted with hydrogen or any other suitable substituents defined in the example embodiments of the present disclosure.

As used throughout the present application, the term “aromatic ring system” may be understood in the broadest sense as any suitable bi- or polycyclic aromatic moiety.

As used throughout the present application, the term “heteroaromatic ring system” may be understood in the broadest sense as any suitable bi- or polycyclic heteroaromatic moiety.

As used throughout the present application, the term “fused” when referring to aromatic or heteroaromatic ring systems means that the aromatic or heteroaromatic rings that are “fused” share at least one bond that is part of both ring systems. For example, naphthalene (or naphthyl when referred to as substituent) or benzothiophene (or benzothiophenyl when referred to as substituent) are considered fused aromatic ring systems in the context of embodiments of the present disclosure, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic system. Additionally, it is understood, that more than one bond may be shared by the aromatic or heteroaromatic rings building up a fused aromatic or heteroaromatic ring system (e.g., in pyrene). Furthermore, it will be understood that aliphatic ring systems may also be fused and that this has the same meaning as for aromatic or heteroaromatic ring systems, with the exception of course, that fused aliphatic ring systems are not aromatic.

As used throughout the present application, the terms “aryl” and “aromatic” may be understood in the broadest sense as any suitable mono-, bi- or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In one or more embodiments, the heteroaromatic ring includes one to three heteroatoms. Again, the terms “heteroaryl” and “heteroaromatic” may be understood in the broadest sense as any suitable mono-, bi- or polycyclic hetero-aromatic moieties that include at least one heteroatom. The heteroatoms may, unless stated otherwise in example embodiments, at each occurrence be the same or different and be individually selected from the group consisting of N, O, S, and Se. Accordingly, the term “arylene” refers to a divalent substituent that bears two binding sites to other molecular structures and thereby serving as a linker structure. In case a group in the example embodiments is defined differently from the definitions given here, for example, the number of aromatic ring atoms or number of heteroatoms differs from the given definition, the definition in the example embodiments is to be applied. According to embodiments of the present disclosure, a condensed (annulated) aromatic or heteroaromatic polycycle is built of two or more single aromatic or heteroaromatic cycles, which formed the polycycle via a condensation reaction.

As used throughout the present application the term “aryl group” or “heteroaryl group” includes groups which can be bound via any suitable position of the aromatic or heteroaromatic group, derived from benzene, naphthalene, anthracene, phenanthrene, pyrene, dihydropyrene, chrysene, perylene, fluoranthene, benzanthracene, benzphenanthrene, tetracene, pentacene, benzpyrene, furan, benzofuran, isobenzofuran, dibenzofuran, thiophene, benzothiophene, isobenzothiophene, dibenzothiophene, selenophene, benzoselenophene, isobenzoselenophene, dibenzoselenophene; pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazol, phenanthroxazol, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the abovementioned groups.

As used throughout the present application, the term “aliphatic” when referring to ring systems may be understood in the broadest sense and means that none of the rings that build up the ring system is an aromatic or heteroaromatic ring. It is understood that such an aliphatic ring system may be fused to one or more aromatic rings so that some (but not all) carbon- or heteroatoms included in the core structure of the aliphatic ring system are part of an attached aromatic ring.

As used above and herein, the term “alkyl group” may be understood in the broadest sense as any linear, branched, or cyclic alkyl substituent. In one or more embodiments, the term alkyl includes the substituents methyl (Me), ethyl (Et), n-propyl (ⁿPr), i-propyl (APr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluorethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyln-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

As used above and herein, the term “alkenyl” includes linear, branched, and cyclic alkenyl substituents. The term alkenyl group, as an example, includes the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used above and herein, the term “alkynyl” includes linear, branched, and cyclic alkynyl substituents. The term alkynyl group, as an example, includes ethynyl, propynyl, butynyl, pentynyl, hexynyl, heptynyl or octynyl.

As used above and herein, the term “alkoxy” includes linear, branched, and cyclic alkoxy substituents. The term alkoxy group, as an example, includes methoxy, ethoxy, n-propoxy, i-propoxy, n-butoxy, i-butoxy, s-butoxy, t-butoxy and 2-methylbutoxy.

As used above and herein, the term “thioalkoxy” includes linear, branched, and cyclic thioalkoxy substituents, in which the O of the example alkoxy groups is replaced by S.

As used above and herein, the terms “halogen” and “halo” may be understood in the broadest sense as being fluorine, chlorine, bromine or iodine.

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

All hydrogen atoms (H) included in any structure referred to herein may at each occurrence independently of each other, and without this being indicated specifically, be replaced by deuterium (D). The process for replacement of hydrogen by deuterium should be readily apparent to the person skilled in the art upon review of this disclosure. Thus, there are numerous suitable methods by which this can be achieved and several review articles describing them (see for example: A. Michelotti, M. Roche, Synthesis 2019, 51(06), 1319-1328, DOI: 10.1055/s-0037-1610405; J. Atzrodt, V. Derdau, T. Fey, J. Zimmermann, Angew. Chem. Int. Ed. 2007, 46(15), 7744-7765, DOI: 10.1002/anie.200700039; Y. Sawama, Y. Monguchi, H. Sajiki, Synlett 2012, 23(7), 959-972, DOI: 10.1055/s-0031-1289696).

The excited state lifetime includes or consists of a plurality of components. For example, in case for TADF emitters it includes or consists of prompt fluorescence which usually lies in the order of magnitude of nanoseconds and delayed fluorescence which usually lies in the order of magnitude of microseconds. Because the delayed fluorescence is three orders of magnitude larger, the prompt fluorescence is insignificant which implies that the excited state lifetime can be estimated by the lifetime of the delayed fluorescence.

In one embodiment, the organic molecules according to embodiments of the present disclosure have an excited state lifetime of not more than 10 μs, of not more than 8 μs, of not more than 6 μs, of not more than 5 μs, not more than 4 μs, or of not more than 3 μs in a film of poly(methyl methacrylate) (PMMA) with 1-5% by weight, or with 2% by weight of organic molecule at room temperature (e.g., approximately 25° C.).

In one embodiment of the present disclosure, the organic molecules according to embodiments of the present disclosure represent thermally-activated delayed fluorescence (TADF) emitters, which exhibit a ΔE_{ST} value, which corresponds to the energy difference between the first excited singlet state (S1) and the first excited triplet state (T1), of less than 5000 cm⁻¹, less than 3000 cm¹, less than 1500 cm¹, less than 1000 cm¹, or less than 500 cm¹.

In a further embodiment, the organic molecules according to embodiments of the present disclosure have an excited state lifetime of not more than 10 μs, of not more than 8 μs, of not more than 6 μs, of not more than 5 μs or not more than 4 μs, or of not more than 3 μs, having a full width at half maximum of less than 0.23 eV, less than 0.20 eV, less than 0.19 eV, less than 0.15 eV or less than 0.12 eV in a film of poly(methyl methacrylate) (PMMA) with 1-5% by weight, or with 2% by weight of organic molecule at room temperature (e.g., approximately 25° C.).

If not stated otherwise, excited state lifetime in the context of the organic molecules according to embodiments of the present disclosure is equal to and/or is determined by the delayed fluorescence lifetime or delayed fluorescence decay time.

In a further embodiment of the present disclosure, the organic molecules according to embodiments of the present disclosure have an emission peak in the visible or nearest ultraviolet range, e.g., in the range of a wavelength of from 380 nm to 800 nm, having a full width at half maximum of less than 0.23 eV, less than 0.20 eV, less than 0.19 eV, less than 0.15 eV or less than 0.12 eV in a film of poly(methyl methacrylate) (PMMA) with 2% by weight of organic molecule at room temperature.

Orbital and excited state energies can be determined either by means of experimental methods or by calculations employing quantum-chemical methods, for example, density functional theory calculations. The energy of the highest occupied molecular orbital E^{HOMO} may be determined by any suitable methods generally used in the art, including cyclic voltammetry measurements having an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

Unless stated otherwise, the energy of the first excited triplet state T1 is determined from the onset the phosphorescence spectrum at 77K (steady-state spectrum; film of 2% by weight of emitter in PMMA).

Unless stated otherwise, the energy of the first excited singlet state S1 is determined from the onset the fluorescence spectrum at room temperature (e.g., approx. 25° C.; steady-state spectrum; film of 2% by weight of emitter in PMMA).

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

The ΔE_{ST} value, which corresponds to the energy difference between the first excited singlet state (S1) and the first excited triplet state (T1), is determined based on the first excited singlet state energy and the first excited triplet state energy, which were determined as stated above.

A further aspect of embodiments of the present disclosure relates to the use of an organic molecule according to embodiments of the present disclosure as a luminescent emitter or as an absorber, and/or as host material and/or as electron transport material, and/or as hole injection material, and/or as hole blocking material in an optoelectronic device.

The optoelectronic device may be understood in the broadest sense as any suitable device based on organic materials that is suitable for emitting light in the visible or nearest ultraviolet (UV) range, e.g., in the wavelength range from 380 nm to 800 nm. In one or more embodiments, the optoelectronic device may be able to emit light in the visible range, e.g., of from 400 nm to 800 nm.

In the context of such use, the optoelectronic device may be selected from the group consisting of:
organic light-emitting diodes (OLEDs),
light-emitting electrochemical cells,
OLED sensors, for example, in gas and/or vapor sensors not hermetically shielded to the outside,
organic diodes,
organic solar cells,
organic transistors,
organic field-effect transistors,
organic lasers, and
down-conversion elements.

A light-emitting electrochemical cell includes three layers, namely a cathode, an anode, and an active layer, which contains the organic molecule according to embodiments of the present disclosure.

In an embodiment in the context of such use, the optoelectronic device is a device selected from the group consisting of an organic light emitting diode (OLED), a light emitting electrochemical cell (LEC), an organic laser, and a light-emitting transistor.

In one embodiment, the light-emitting layer of an organic light-emitting diode includes the organic molecules according to embodiments of the present disclosure.

In one embodiment, the light-emitting layer of an organic light-emitting diode includes not only the organic molecules according to embodiments of the present disclosure but also a host material whose triplet (T1) and singlet (S1) energy levels are energetically higher than the triplet (T1) and singlet (S1) energy levels of the organic molecule.

A further aspect of embodiments of the present disclosure relates to a composition including or consisting of:
(a) the organic molecule of embodiments of the present disclosure, in the form of an emitter and/or a host, and
(b) one or more emitter and/or host materials, which differ from the organic molecule of embodiments of the present disclosure, and
optionally, one or more dyes and/or one or more solvents.

In a further embodiment of the present disclosure, the composition has a photoluminescence quantum yield (PLQY) of more than 10%, more than 20%, more than 40%, more than 60% or more than 70% at room temperature.

Compositions including at least one further emitter

One embodiment of the present disclosure relates to a composition including or consisting of:
(i) 1-50% by weight, 5-40% by weight, or 10-30% by weight, of the organic molecule according to embodiments of the present disclosure;
(ii) 5-98% by weight, 30-93.9% by weight, or 40-88% by weight, of one host compound H;
(iii) 1-30% by weight, 1-20% by weight, or 1-5% by weight, of at least one further emitter molecule F having a structure differing from the structure of the molecules according to embodiments of the present disclosure; and
(iv) optionally 0-94% by weight, 0.1-65% by weight, or 1-50% by weight, of at least one further host compound D having a structure differing from the structure of the molecules according to embodiments of the present disclosure; and
(v) optionally 0-94% by weight, 0-65% by weight, or 0-50% by weight, of a solvent.

The components or the compositions are chosen such that the sum of the weight of the components add up to 100%.

In a further embodiment of the present disclosure, the composition has an emission peak in the visible or nearest ultraviolet range, e.g., in the range of a wavelength of from 380 to 800 nm.

In one embodiment of the present disclosure, the at least one further emitter molecule F is a purely organic emitter.

In one embodiment of the present disclosure, the at least one further emitter molecule F is a purely organic TADF emitter. Other purely organic TADF emitters are available, e.g., Wong and Zysman-Colman (“Purely Organic Thermally Activated Delayed Fluorescence Materials for Organic Light-Emitting Diodes”, Adv. Mater. 2017, 29(22), 1605444-1605498, DOI: 10.1002/adma.201605444).

In one embodiment of the present disclosure, the at least one further emitter molecule F is a fluorescence emitter, for example, a blue, a green, a yellow or a red fluorescence emitter.

In a further embodiment of the present disclosure, the composition, containing the at least one further emitter molecule F shows an emission peak in the visible or nearest ultraviolet range, e.g., in the range of a wavelength of from 380 to 800 nm, having a full width at half maximum of less than 0.30 eV, less than 0.25 eV, less than 0.22 eV, less than 0.19 eV or less than 0.17 eV at room temperature, with a lower limit of 0.05 eV.

### Composition Wherein the at Least One Further Emitter Molecule F is a Green Fluorescence Emitter

In a further embodiment of the present disclosure, the at least one further emitter molecule F is a fluorescence emitter, for example, a green fluorescence emitter.

In one embodiment, the at least one further emitter molecule F is a fluorescence emitter selected from the following group:

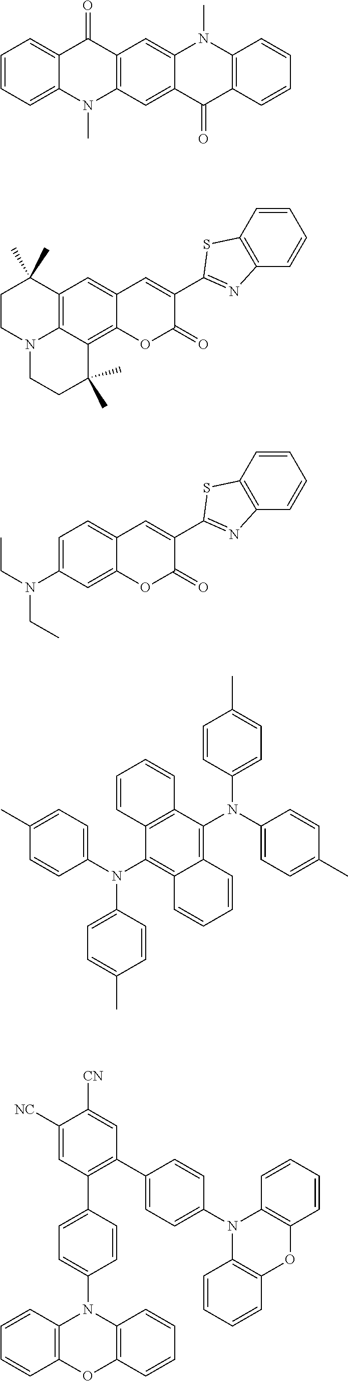

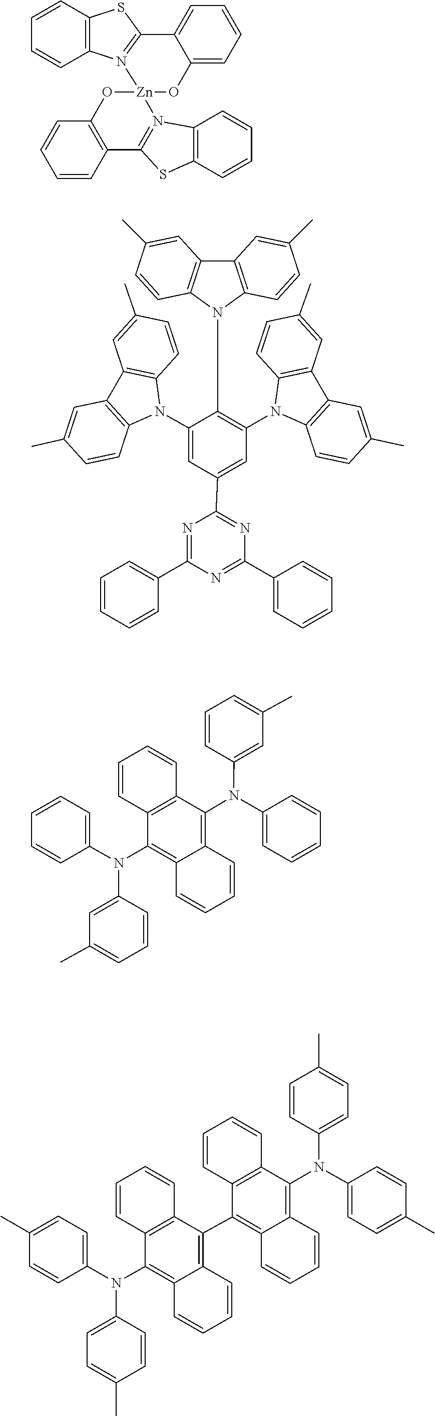

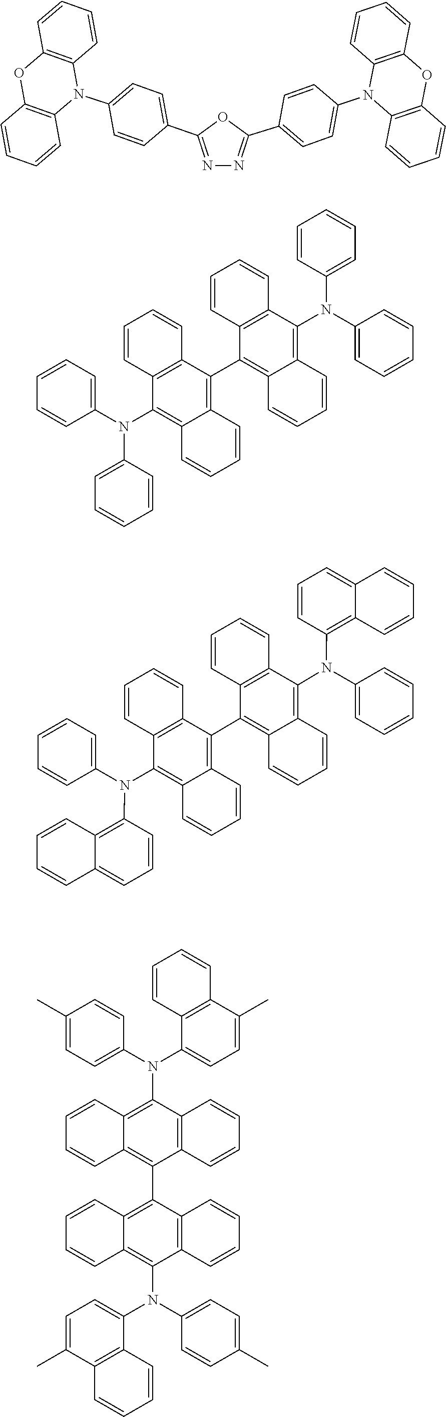

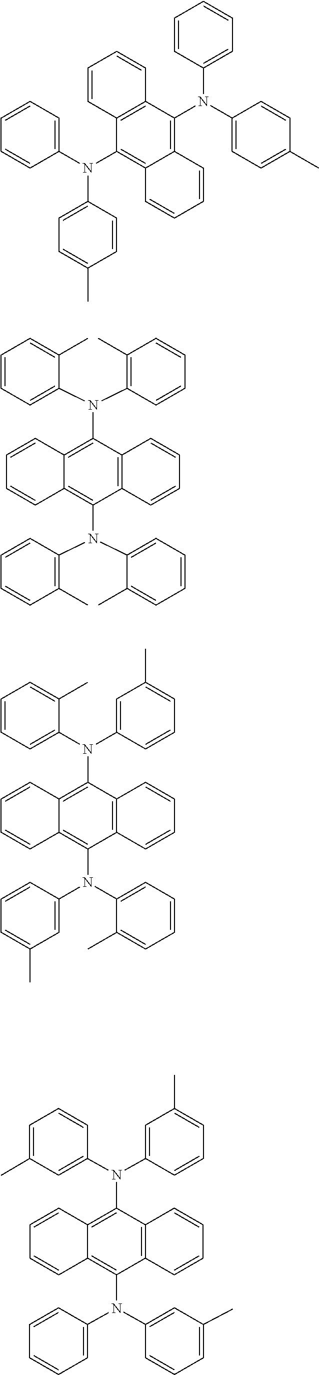

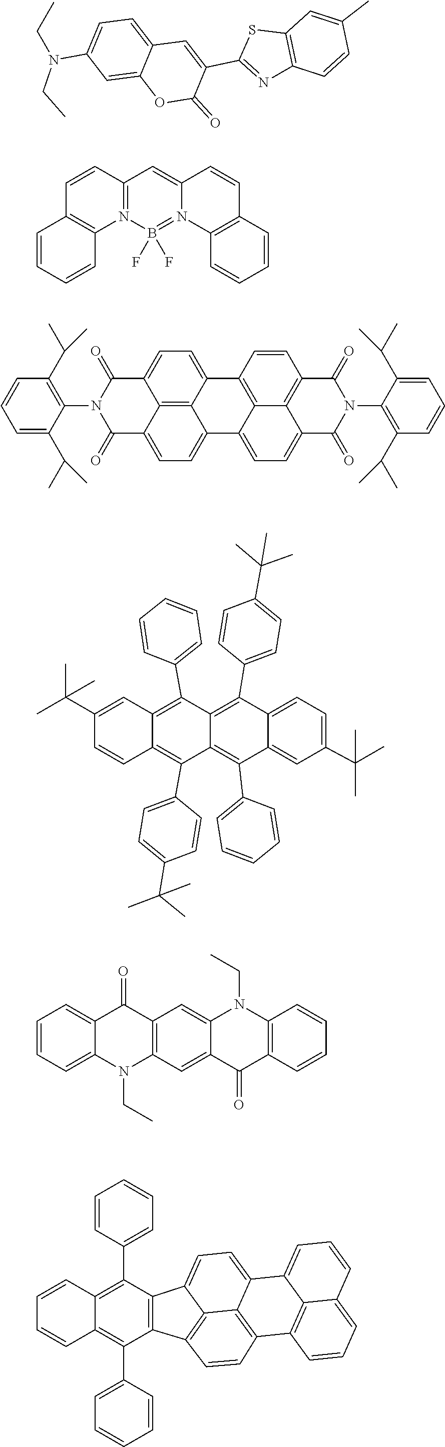

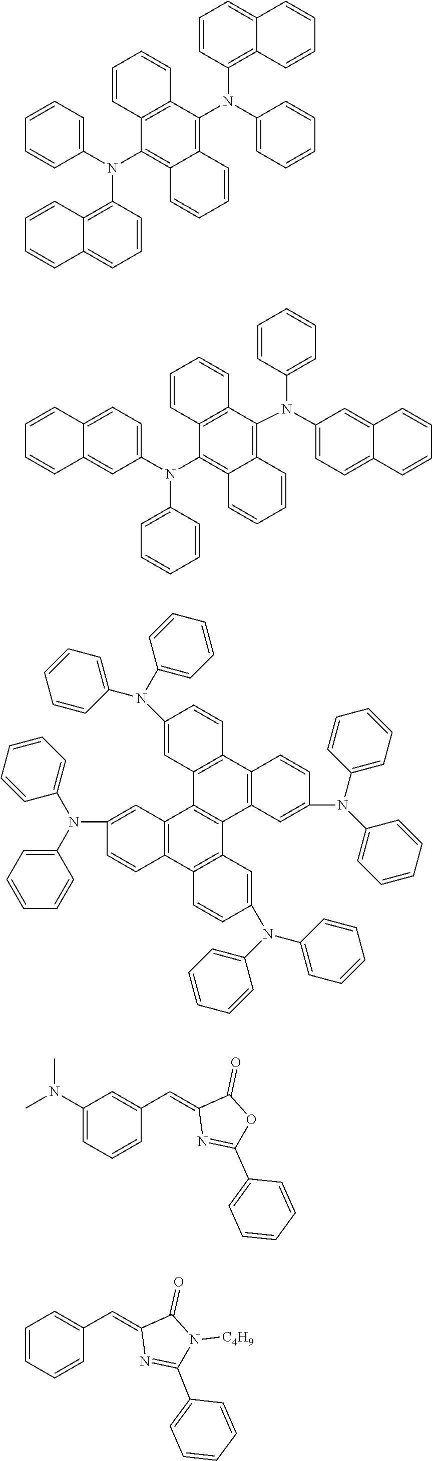

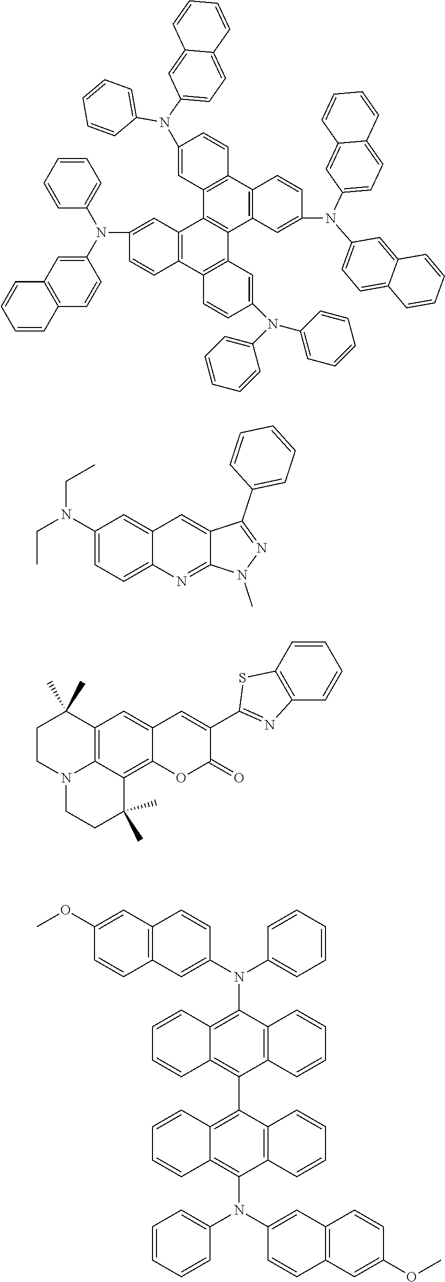

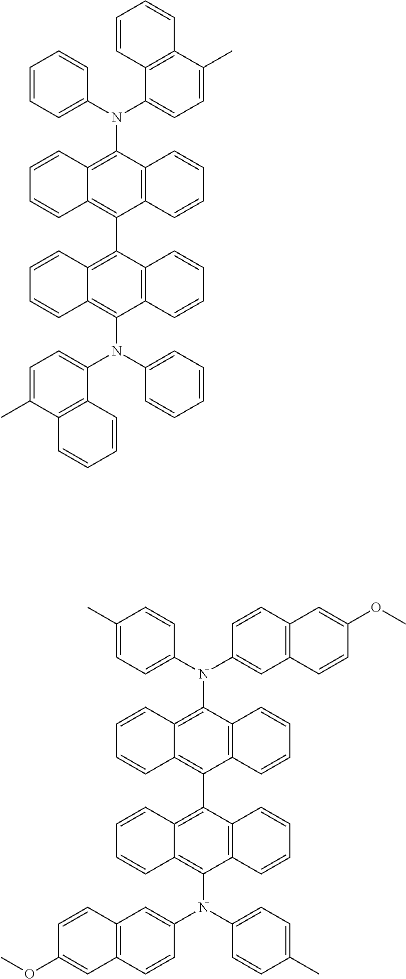

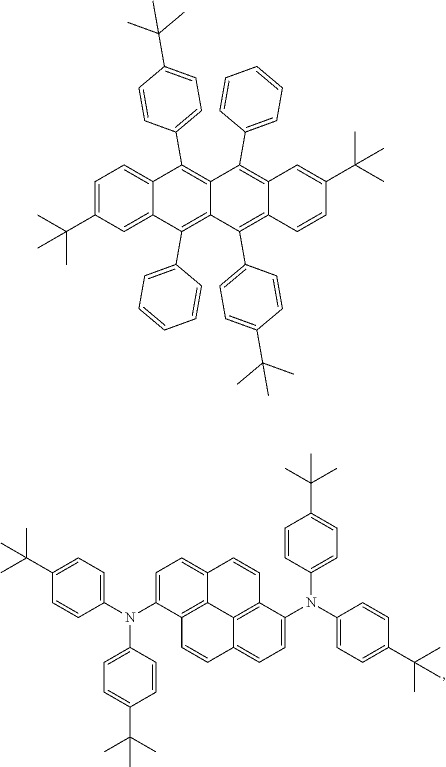

In a further embodiment of the present disclosure, the composition has an emission peak in the visible or nearest ultraviolet range, e.g., in the range of a wavelength of from 380 to 800 nm, between 485 nm and 590 nm, between 505 nm and 565 nm, or between 515 nm and 545 nm.

### Composition Wherein the at Least One Further Emitter Molecule F is a Red Fluorescence Emitter

In a further embodiment of the present disclosure, the at least one further emitter molecule F is a fluorescence emitter, for example, a red fluorescence emitter.

In one embodiment, the at least one further emitter molecule F is a fluorescence emitter selected from the following group:

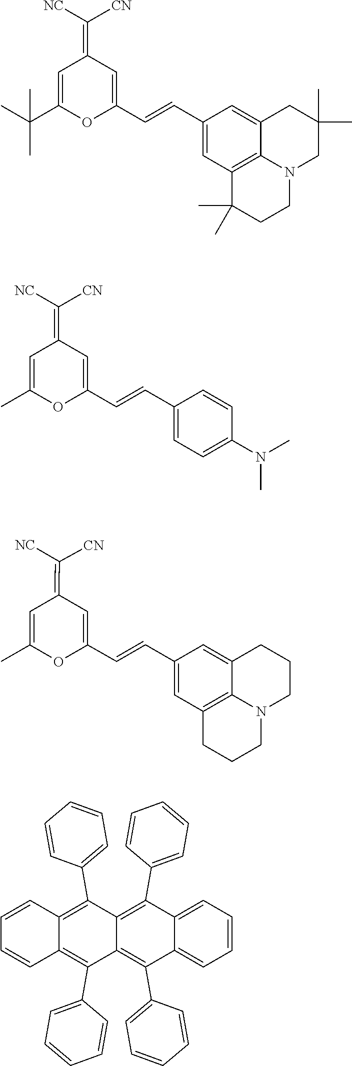

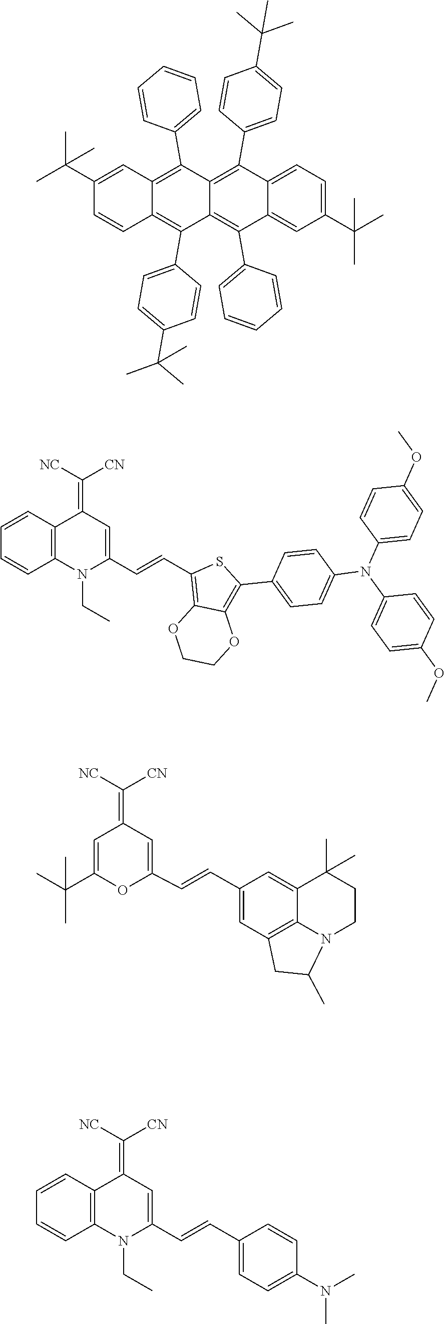

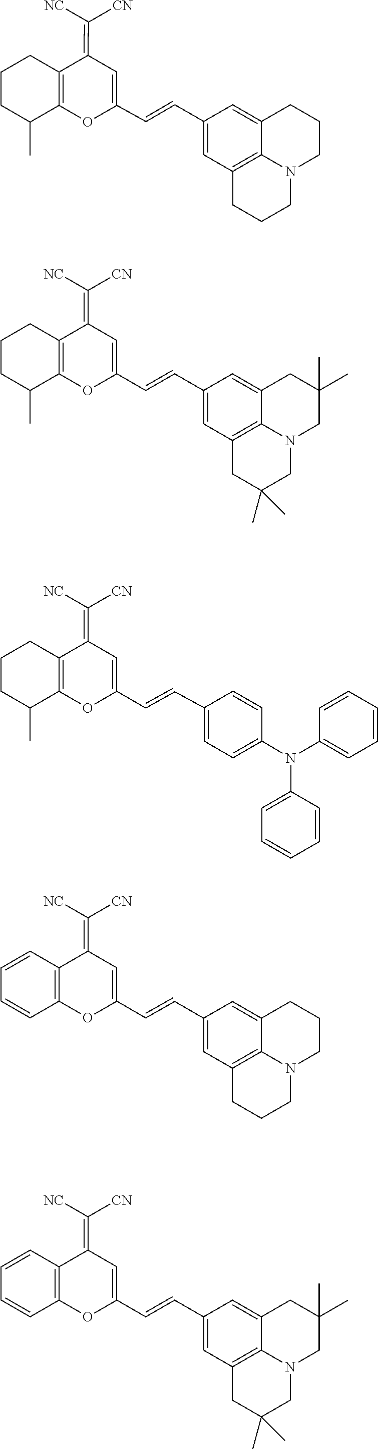 [SMILES: CC1CCCC2=C1OC(/C=C/c1cc3c4c(c1)CCCN4CCC3)=CC2=C(C#N)C#N ; CC1CCCC2=C1OC(/C=C/c1cc3c4c(c1)CC(C)(C)CN4CC(C)(C)C3)=CC2=C(C#N)C#N ; CC1CCCC2=C1OC(/C=C/c1ccc(N(c3ccccc3)c3ccccc3)cc1)=CC2=C(C#N)C#N ; N#CC(C#N)=C1C=C(/C=C/c2cc3c4c(c2)CCCN4CCC3)Oc2ccccc21 ; CC1(C)Cc2cc(/C=C/C3=CC(=C(C#N)C#N)c4ccccc4O3)cc3c2N(C1)CC(C)(C)C3]

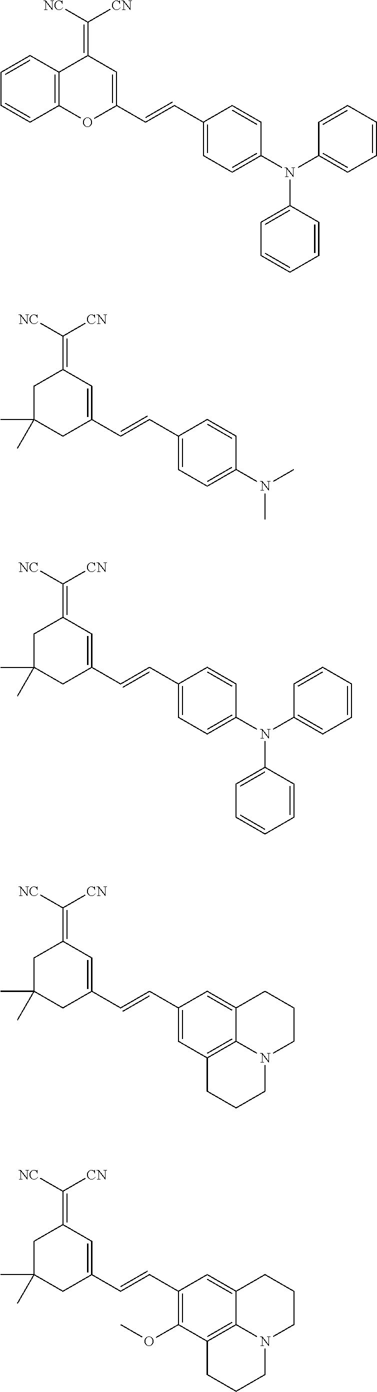

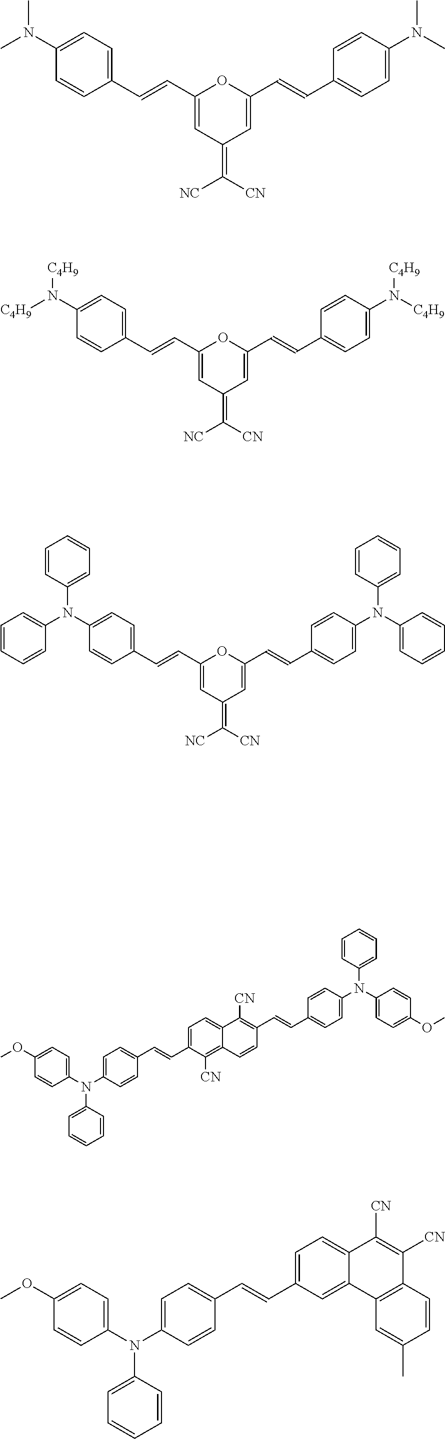

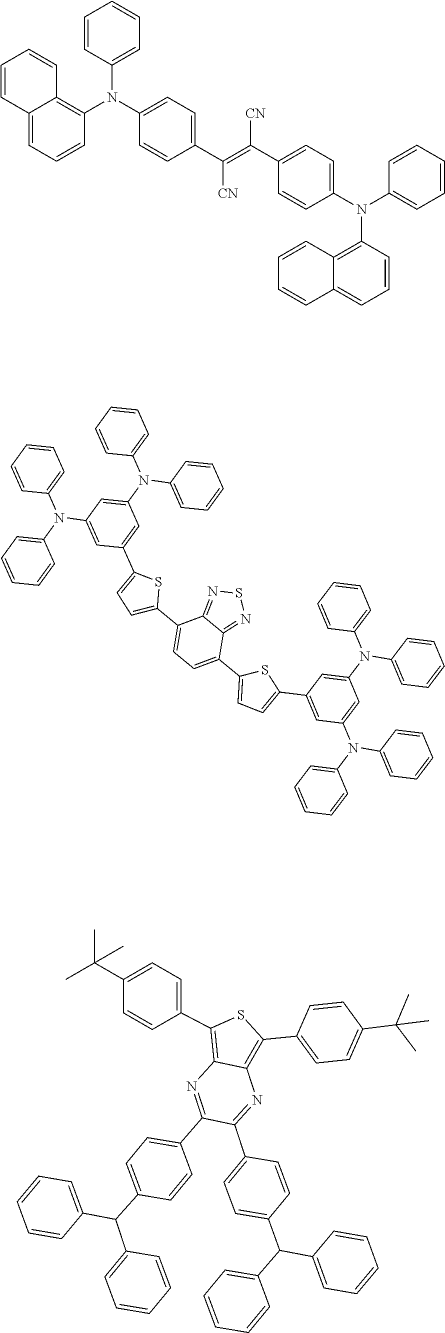 [SMILES: N#C/C(=C(/C#N)c1ccc(N(c2ccccc2)c2cccc3ccccc23)cc1)c1ccc(N(c2ccccc2)c2cccc3ccccc23)cc1 ; c1ccc(N(c2ccccc2)c2cc(-c3ccc(-c4ccc(-c5ccc(-c6cc(N(c7ccccc7)c7ccccc7)cc(N(c7ccccc7)c7ccccc7)c6)s5)c5nsnc45)s3)cc(N(c3ccccc3)c3ccccc3)c2)cc1 ; CC(C)(C)c1ccc(-c2sc(-c3ccc(C(C)(C)C)cc3)c3nc(-c4ccc(C(c5ccccc5)c5ccccc5)cc4)c(-c4ccc(C(c5ccccc5)c5ccccc5)cc4)nc23)cc1]

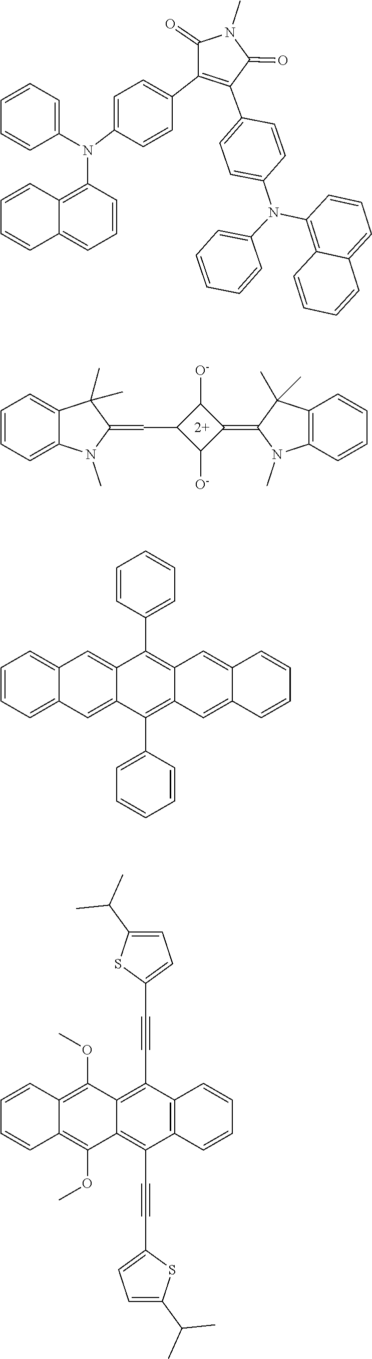

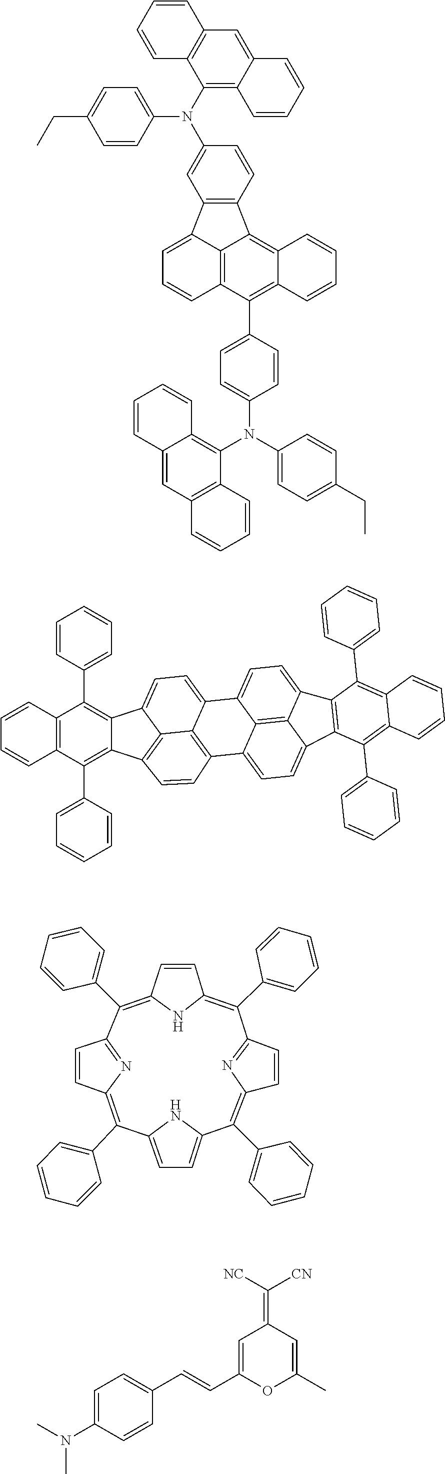

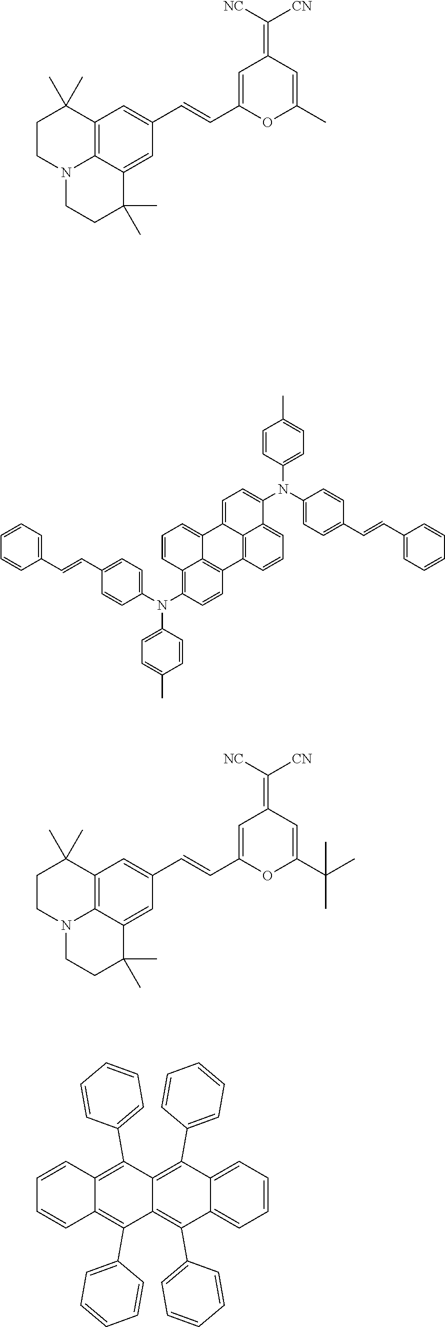

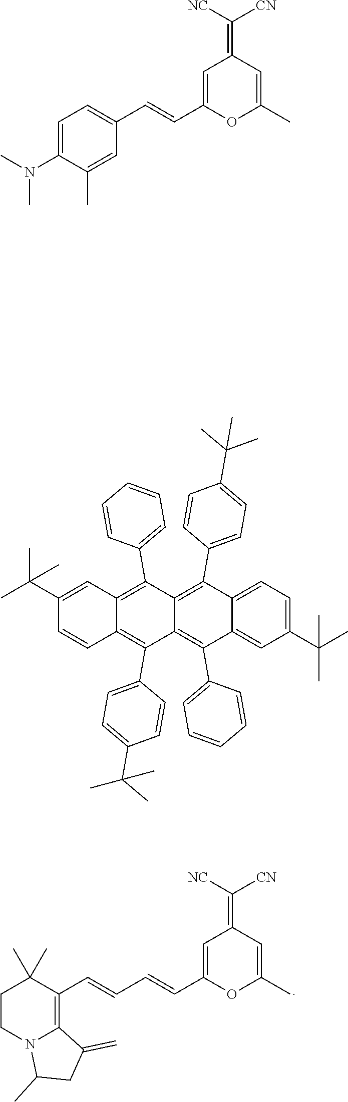

In a further embodiment of the present disclosure, the composition has an emission peak in the visible or nearest ultraviolet range, e.g., in the range of a wavelength of from 380 to 800 nm, between 590 nm and 690 nm, between 610 nm and 665 nm, or between 620 nm and 640 nm.

### Light-Emitting Layer EML

In one embodiment, the light-emitting layer EML of an organic light-emitting diode of embodiments of the present disclosure includes (or essentially consists of) a composition including or consisting of:
(i) 1-50% by weight, 5-40% by weight, or 10-30% by weight, of one or more organic molecules according to embodiments of the present disclosure;
(ii) 5-99% by weight, 30-94.9% by weight, or 40-89% by weight, of at least one host compound H; and
(iii) optionally 0-94% by weight, 0.1-65% by weight, or 1-50% by weight, of at least one further host compound D having a structure differing from the structure of the molecules according to embodiments of the present disclosure; and
(iv) optionally 0-94% by weight, 0-65% by weight, or 0-50% by weight, of a solvent; and
(v) optionally 0-30% by weight, 0-20% by weight, or 0-5% by weight, of at least one further emitter molecule F having a structure differing from the structure of the molecules according to embodiments of the present disclosure.

In one or more embodiments, energy can be transferred from the host compound H to the one or more organic molecules of embodiments of the present disclosure, for example, transferred from the first excited triplet state T1(H) of the host compound H to the first excited triplet state T1(E) of the one or more organic molecules according to embodiments of the present disclosure and/or from the first excited singlet state S1(H) of the host compound H to the first excited singlet state S1(E) of the one or more organic molecules according to embodiments of the present disclosure.

In one embodiment, the host compound H has a highest occupied molecular orbital HOMO(H) having an energy E^{HOMO}(H) in the range of from −5 eV to −6.5 eV and one organic molecule according to embodiment E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H) and the one organic molecule according to embodiment E has a lowest unoccupied molecular orbital LUMO(E) having an energy E^{LUMO}(E), wherein E^{LUMO}(H)>E^{LUMO}(E).

### Light-Emitting Layer EML Including at Least One Further Host Compound D

In a further embodiment, the light-emitting layer EML of an organic light-emitting diode of embodiments of the present disclosure includes (or essentially consists of) a composition including or consisting of:
(i) 1-50% by weight, 5-40% by weight, or 10-30% by weight, of one organic molecule according to embodiments of the present disclosure;
(ii) 5-99% by weight, 30-94.9% by weight, or 40-89% by weight, of one host compound H; and
(iii) 0-94% by weight, 0.1-65% by weight, or 1-50% by weight, of at least one further host compound D having a structure differing from the structure of the molecules according to embodiments of the present disclosure; and
(iv) optionally 0-94% by weight, 0-65% by weight, or 0-50% by weight, of a solvent; and
(v) optionally 0-30% by weight, 0-20% by weight, or 0-5% by weight, of at least one further emitter molecule F having a structure differing from the structure of the molecules according to embodiments of the present disclosure.

In one embodiment of the organic light-emitting diode of embodiments of the present disclosure, the host compound H has a highest occupied molecular orbital HOMO(H) having an energy E^{HOMO}(H) in the range of from −5 eV to −6.5 eV and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors an efficient hole transport.

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors an efficient electron transport.

In one embodiment of the organic light-emitting diode of embodiments of the present disclosure, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D)
the organic molecule of embodiment E of has a highest occupied molecular orbital HOMO(E) having an energy E^{HOMO}(E) and a lowest unoccupied molecular orbital LUMO(E) having an energy E^{LUMO}(E),
wherein:
E^{HOMO}(H)>E^{HOMO}(D) and the difference between the energy level of the highest occupied molecular orbital HOMO(E) of organic molecule according to embodiments of the present disclosure (E^{HOMO}(E)) and the energy level of the highest occupied molecular orbital HOMO(H) of the host compound H (E^{HOMO}(H)) is between 0.5 eV and 0.5 eV, between −0.3 eV and 0.3 eV, between −0.2 eV and 0.2 eV or between −0.1 eV and 0.1 eV; and
E^{LUMO}(H)>E^{LUMO}(D) and the difference between the energy level of the lowest unoccupied molecular orbital LUMO(E) of organic molecule according to embodiments of the present disclosure (E^{LUMO}(E)) and the lowest unoccupied molecular orbital LUMO(D) of the at least one further host compound D (E^{LUMO}(D)) is between −0.5 eV and 0.5 eV, between −0.3 eV and 0.3 eV, between −0.2 eV and 0.2 eV or between −0.1 eV and 0.1 eV.

Light-emitting layer EML including at least one further emitter molecule F

In a further embodiment, the light-emitting layer EML includes (or (essentially) consists of) a composition including or consisting of:
(i) 1-50% by weight, 5-40% by weight, or 10-30% by weight, of one organic molecule according to embodiments of the present disclosure;
(ii) 5-98% by weight, 30-93.9% by weight, or 40-88% by weight, of one host compound H;
(iii) 1-30% by weight, 1-20% by weight, or 1-5% by weight, of at least one further emitter molecule F having a structure differing from the structure of the molecules according to embodiments of the present disclosure; and
(iv) optionally 0-94% by weight, 0.1-65% by weight, or 1-50% by weight, of at least one further host compound D having a structure differing from the structure of the molecules according to embodiments of the present disclosure; and
(v) optionally 0-94% by weight, 0-65% by weight, or 0-50% by weight, of a solvent.

In a further embodiment, the light-emitting layer EML includes (or (essentially) consists of) a composition as described in Compositions including at least one further emitter, with the at least one further emitter molecule F as defined in Composition wherein the at least one further emitter molecule F is a green fluorescence emitter.

In a further embodiment, the light-emitting layer EML includes (or (essentially) consists of) a composition as described in Compositions including at least one further emitter, with the at least one further emitter molecule F as defined in Composition wherein the at least one further emitter molecule F is a red fluorescence emitter.

In one embodiment of the light-emitting layer EML including at least one further emitter molecule F, energy can be transferred from the one or more organic molecules of embodiment E to the at least one further emitter molecule F, for example, transferred from the first excited singlet state S1(E) of one or more organic molecules of embodiment E to the first excited singlet state S1(F) of the at least one further emitter molecule F.

In one embodiment, the first excited singlet state S1(H) of one host compound H of the light-emitting layer is higher in energy than the first excited singlet state S1(E) of the one or more organic molecules of embodiments of the present disclosure E: S1(H)>S1(E), and the first excited singlet state S1(H) of one host compound H is higher in energy than the first excited singlet state S1(F) of the at least one emitter molecule F: S1(H)>S1(F).

In one embodiment, the first excited triplet state T1(H) of one host compound H is higher in energy than the first excited triplet state T1(E) of the one or more organic molecules of embodiments of the present disclosure E: T1(H)>T1(E), and the first excited triplet state T1(H) of one host compound H is higher in energy than the first excited triplet state T1(F) of the at least one emitter molecule F: T1(H)>T1(F).

In one embodiment, the first excited singlet state S1(E) of the one or more organic molecules of embodiment E is higher in energy than the first excited singlet state S1(F) of the at least one emitter molecule F: S1(E)>S1(F).

In one embodiment, the first excited triplet state T1(E) of the one or more organic molecules of embodiment E is higher in energy than the first excited singlet state T1(F) of the at least one emitter molecule F: T1€>T1(F).

In one embodiment, the first excited triplet state€(E) of the one or more organic molecules of embodiment E is higher in energy than the first excited singlet state T1(F) of the at least one emitter molecule F: T1(E)>T1(F), wherein the absolute value of the energy difference between T1(E) and T1(F) is larger than 0.3 eV, larger than 0.4 eV, or larger than 0.5 eV.

In one embodiment, the host compound H has a highest occupied molecular orbital HOMO(H) having an energy E^{HOMO}(H) in the range of from −5 to −6.5 eV and the at least one further host compound D has a highest occupied molecular orbital HOMO(D) having an energy E^{HOMO}(D), wherein E^{HOMO}(H)>E^{HOMO}(D).

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D).

In one embodiment, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D)
the organic molecule according to embodiment E has a highest occupied molecular orbital HOMO(E) having an energy E^{HOMO}(E) and a lowest unoccupied molecular orbital LUMO(E) having an energy E^{LUMO}(E), wherein:
E^{HOMO}(H)>E^{HOMO}(D) and the difference between the energy level of the highest occupied molecular orbital HOMO(E) of the organic molecule according to embodiment E (E^{HOMO}(E)) and the energy level of the highest occupied molecular orbital HOMO(H) of the host compound H (E^{HOMO}(H)) is between −0.5 eV and 0.5 eV, between −0.3 eV and 0.3 eV, between −0.2 eV and 0.2 eV or between −0.1 eV and 0.1 eV; and
E^{LUMO}(H)>E^{LUMO}(D) and the difference between the energy level of the lowest unoccupied molecular orbital LUMO(E) of the organic molecule according embodiment E (E^{LUMO}(E)) and the lowest unoccupied molecular orbital LUMO(D) of the at least one further host compound D (E^{LUMO}(D)) is between −0.5 eV and 0.5 eV, between −0.3 eV and 0.3 eV, between −0.2 eV and 0.2 eV or between −0.1 eV and 0.1 eV.

In one embodiment of the present disclosure the host compound D and/or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. In one or more embodiments the TADF material exhibits a ΔE_{ST} value of less than 3000 cm⁻¹, less than 1500 cm⁻¹, less than 1000 cm⁻¹ or less than 500 cm⁻¹.

In one embodiment, the host compound D is a TADF material and the host compound H exhibits a ΔE_{ST} value of more than 2500 cm⁻¹. In an embodiment, the host compound D is a TADF material and the host compound H is selected from group consisting of CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. In an embodiment, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine).

In a further aspect, embodiments of the present disclosure relate to an optoelectronic device including an organic molecule or a composition of the type or kind described here, for example, in the form of a device selected from the group consisting of organic light-emitting diode (OLED), light-emitting electrochemical cell, OLED sensor, for example, gas and/or vapor sensors not hermetically externally shielded, organic diode, organic solar cell, organic transistor, organic field-effect transistor, organic laser and down-conversion element.

In an embodiment, the optoelectronic device is a device selected from the group consisting of an organic light emitting diode (OLED), a light emitting electrochemical cell (LEC), and a light-emitting transistor.

In one embodiment of the optoelectronic device of embodiments of the present disclosure, the organic molecule according to embodiment E is used as emission material in a light-emitting layer EML.

In one embodiment of the optoelectronic device of embodiments of the present disclosure, the light-emitting layer EML includes or consists of the composition according to embodiments of the present disclosure described here.

When the optoelectronic device is an OLED, it may, For example, have the following layer structure:
1. Substrate
2. Anode layer, A
3. Hole injection layer, HIL
4. Hole transport layer, HTL
5. Electron blocking Layer, EBL
6. Emitting layer, EML
7. Hole blocking layer, HBL
8. Electron transport layer, ETL
9. Electron injection layer, EIL
10. Cathode layer, C

Wherein the OLED includes each layer selected from the group of HIL, HTL, EBL, HBL, ETL, and EIL only optionally, different layers may be merged and the OLED may include more than one layer of each layer type or kind defined above.

Furthermore, the optoelectronic device may, in one embodiment, include one or more protective layers protecting the device from damaging exposure to harmful species in the environment including, for example, moisture, vapor and/or gases.

In one embodiment of the present disclosure, the optoelectronic device is an OLED, with the following inverted layer structure:
1. Substrate
2. Cathode layer, C
3. Electron injection layer, EIL
4. Electron transport layer, ETL
5. Hole blocking layer, HBL
6. Emitting layer, B
7. Electron blocking layer, EBL
8. Hole transport layer, HTL
9. Hole injection layer, HIL
10. Anode layer, A

Wherein the OLED includes each layer selected from the group of HIL, HTL, EBL, HBL, ETL, and EIL only optionally, different layers may be merged and the OLED may include more than one layer of each layer types or kinds defined above.

In one embodiment of the present disclosure, the optoelectronic device is an OLED, which may have a stacked architecture. In this architecture, contrary to other arrangements in which the OLEDs are placed side by side, the individual units are stacked on top of each other. Blended light may be generated with OLEDs exhibiting a stacked architecture, for example, white light may be generated by stacking blue, green and red OLEDs. Furthermore, the OLED exhibiting a stacked architecture may include a charge generation layer (CGL), which is between two OLED subunits and includes or consists of a n-doped and p-doped layer with the n-doped layer of one CGL being located closer to the anode layer.

In one embodiment of the present disclosure, the optoelectronic device is an OLED, which includes two or more emission layers between anode and cathode. In one or more embodiments, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked.

In a further embodiment, the tandem OLED includes a charge generation layer between each two emission layers. In addition, adjacent emission layers or emission layers separated by a charge generation layer may be merged.

The substrate may be formed by any suitable material or composition of materials. Most frequently, glass slides are used as substrates. In one or more embodiments, thin metal layers (e.g., copper, gold, silver or aluminum films) and/or plastic films and/or slides may be used. This may allow for a higher degree of flexibility. The anode layer A is mostly composed of materials allowing to obtain an (essentially) transparent film. As at least one selected from the electrodes should be (essentially) transparent in order to allow light emission from the OLED, either the anode layer A or the cathode layer C is transparent. In one or more embodiments, the anode layer A includes a large content or consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrol and/or doped polythiophene.

The anode layer A (essentially) may include or consist of indium tin oxide (ITO) (e.g., (InO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (e.g., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC or CuI, for example, a mixture of PEDOT and PSS. The hole injection layer (HIL) may also prevent or reduce the diffusion of metals from the anode layer A into the hole transport layer (HTL). The HIL may, for example, include PEDOT:PSS (poly-3,4-ethylendioxy thiophene: polystyrene sulfonate), PEDOT (poly-3,4-ethylendioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

A hole transport layer (HTL) may be adjacent to the anode layer A or hole injection layer (HIL). Herein, any suitable hole transport compound generally used in the art may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). In one or more embodiments, hole transport compounds bear comparably high energy levels of their triplet states T1. For example, the hole transport layer (HTL) may include a star-shaped heterocycle such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix.

Transition metal oxides such as vanadium oxide, molybdenum oxide and/or tungsten oxide may, for example, be used as inorganic dopant.

Tetrafluorotetracyanoquinodimethane (F₄-TCNQ), copper-pentafluorobenzoate (Cu(I)pFBz) and/or transition metal complexes may, for example, be used as organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

The light-emitting layer EML may be adjacent to the hole transport layer (HTL). The light-emitting layer EML includes at least one light emitting molecule. In one or more embodiments, the EML includes at least one light emitting molecule according to embodiment E. In one embodiment, the light-emitting layer includes only the organic molecules according to embodiments of the present disclosure. In one or more embodiments, the EML additionally includes one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl]ether oxide), 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material H may be selected to exhibit first triplet (T1) and first singlet (S1) energy levels, which are energetically higher than the first triplet (T1) and first singlet (S1) energy levels of the organic molecule. In one or more embodiments, the EML additionally includes one or more host materials H, wherein the host is a triplet-triplet annihilation (TTA) material. A TTA material may convert energy from first excited triplet states T1 to first excited singlet state S1 by triplet-triplet annihilation. A TTA material should be selected that twice the energy of the lowermost excited triplet state energy level T1 of the TTA material is larger than the energy of the lowermost excited singlet state energy level of the light emitting molecule according to embodiments of the present disclosure, e.g., 2T1(TTA material)>S1 (light emitting molecule according to embodiments of the present disclosure).

In one embodiment of the present disclosure, the EML includes a so-called mixed-host system including at least one hole-dominant host and one electron-dominant host. In an embodiment, the EML includes exactly one light emitting organic molecule according to embodiments of the present disclosure and a mixed-host system including T2T as electron-dominant host and a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as hole-dominant host. In a further embodiment the EML includes 50-80% by weight, or 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, 15-30% by weight of T2T and 5-40% by weight, or 10-30% by weight of light emitting molecule according to embodiments of the present disclosure.

Adjacent to the light-emitting layer EML, an electron transport layer (ETL) may be located. Herein, any suitable electron transporter generally used in the art may be used. In one or more embodiments, electron-poor compounds such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include Nbphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BpyTP2 (2,7-di(2,2′-bipyridin-5-yl)triphenyle), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block (or reduce transport of) holes and/or a holeblocking layer (HBL) is introduced.

The HBL may, for example, include BCP (2,9-dimethyl-4,7-diphenyl-1,10-phenanthroline=Bathocuproine), BAIq (bis(8-hydroxy-2-methylquinoline)-(4-phenylphenoxy)aluminum), Nbphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl) benzene).

Adjacent to the electron transport layer (ETL), a cathode layer C may be located. The cathode layer C may, for example, include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) intransparent (reflective) metals such as Mg, Ca or Al. Alternatively or additionally, the cathode layer C may also include graphite and/or carbon nanotubes (CNTs). In one or more embodiments, the cathode layer C may include or consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, the electron transport layer (ETL) and/or a hole blocking layer (HBL) may also include one or more host compounds H.

In order to modify the emission spectrum and/or the absorption spectrum of the light-emitting layer EML further, the light-emitting layer EML may further include one or more further emitter molecules F. Such an emitter molecule F may be any suitable emitter molecule generally used in the art. In one or more embodiments, such an emitter molecule F is a molecule having a structure differing from the structure of the molecules according to embodiments of the present disclosure E. The emitter molecule F may optionally be a TADF emitter. In one or more embodiments, the emitter molecule F may optionally be a fluorescent and/or phosphorescent emitter molecule which is able to shift the emission spectrum and/or the absorption spectrum of the light-emitting layer EML. In one or more embodiments, the triplet and/or singlet excitons may be transferred from the organic emitter molecule according to embodiments of the present disclosure to the emitter molecule F before relaxing to the ground state S0 by emitting light that may be red-shifted in comparison to the light emitted by an organic molecule. Optionally, the emitter molecule F may also provoke two-photon effects (e.g., the absorption of two photons of half the energy of the absorption maximum).

Optionally, an optoelectronic device (e.g., an OLED) may, for example, be an essentially white optoelectronic device. For example, such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, a red emitter has an emission maximum in a range of from >620 to 800 nm.

A deep blue emitter may have an emission maximum of below 480 nm, below 470 nm, below 465 nm or below 460 nm. It will be above 420 nm, above 430 nm, above 440 nm or above 450 nm.

Accordingly, a further aspect of embodiments of the present disclosure relates to an OLED, which exhibits an external quantum efficiency at 1000 cd/m² of more than 8%, of more than 10%, of more than 13%, of more than 15% or of more than 20% and/or exhibits an emission maximum between 420 nm and 500 nm, between 430 nm and 490 nm, between 440 nm and 480 nm, between 450 nm and 470 nm and/or exhibits a LT80 value at 500 cd/m² of more than 100 h, more than 200 h, more than 400 h, more than 750 h or more than 1000 h. Accordingly, a further aspect of embodiments of the present disclosure relates to an OLED, whose emission exhibits a CIEy color coordinate of less than 0.45, less than 0.30, less than 0.20 or less than 0.15 or less than 0.10.

A further aspect of embodiments of the present disclosure relates to an OLED, which emits light at a distinct color point. According to embodiments of the present disclosure, the OLED emits light having a narrow emission band (small full width at half maximum (FWHM)). In one aspect, the OLED according to embodiments of the present disclosure emits light having a FWHM of the main emission peak of less than 0.30 eV, less than 0.25 eV, less than 0.18 eV, less than 0.15 eV or less than 0.12 eV.

A further aspect of embodiments of the present disclosure relates to an OLED, which emits light at a distinct color point. According to embodiments of the present disclosure, the OLED emits light having a narrow emission band (small full width at half maximum (FWHM)). In one aspect, the OLED according to embodiments of the present disclosure emits light having a FWHM of the main emission peak of less than 0.30 eV, less than 0.25 eV, less than 0.18 eV, less than 0.15 eV or less than 0.12 eV and having an excited state lifetime of not more than 10 μs, of not more than 8 μs, of not more than 6 μs, of not more than 5 μs, not more than 4 μs, or of not more than 3 μs.

A further aspect of embodiments of the present disclosure relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g., UHD-TVs. Accordingly, a further aspect of embodiments of the present disclosure relates to an OLED, whose emission exhibits a CIEx color coordinate of between 0.02 and 0.30, between 0.03 and 0.25, between 0.05 and 0.20 or between 0.08 and 0.18 or between 0.10 and 0.15 and/or a CIEy color coordinate of between 0.00 and 0.45, between 0.01 and 0.30, between 0.02 and 0.20 or between 0.03 and 0.15 or between 0.04 and 0.10.

In a further aspect, embodiments of the present disclosure relate to a method for producing an optoelectronic device. In this case an organic molecule of embodiments of the present disclosure is used.

The optoelectronic device, for example, the OLED according to embodiments of the present disclosure can be fabricated by any suitable method of vapor deposition and/or liquid processing. Accordingly, at least one layer is:
prepared by means of a sublimation process,
prepared by means of an organic vapor phase deposition process,
prepared by means of a carrier gas sublimation process,
solution processed or printed.

The methods used to fabricate the optoelectronic device, for example, the OLED according to embodiments of the present disclosure, may be any suitable methods generally used in the art. The different layers are individually and successively deposited on a suitable substrate by means of subsequent deposition processes. The individual layers may be deposited using the same or differing deposition methods.

Vapor deposition processes, for example, include thermal (co)evaporation, chemical vapor deposition and physical vapor deposition. For active matrix OLED display, an AMOLED backplane is used as a substrate. The individual layer may be processed from solutions and/or dispersions employing suitable solvents. Solution deposition process, for example, include spin coating, dip coating and jet printing. Liquid processing may optionally be carried out in an inert atmosphere (e.g., in a nitrogen atmosphere) and the solvent may be completely or partially removed by any suitable method generally used in the art.

### EXAMPLES

### General Synthesis Scheme I

General synthesis scheme I provides a synthesis scheme for organic molecules according to embodiments of the present disclosure wherein R^{I}═R^{X}, R^{II}═R^{IX}, R^{III}═R^{VII}, R^{IV}═R^{VI}, R^{V}═R^{VI}:

### General Procedure for Synthesis AAV0:

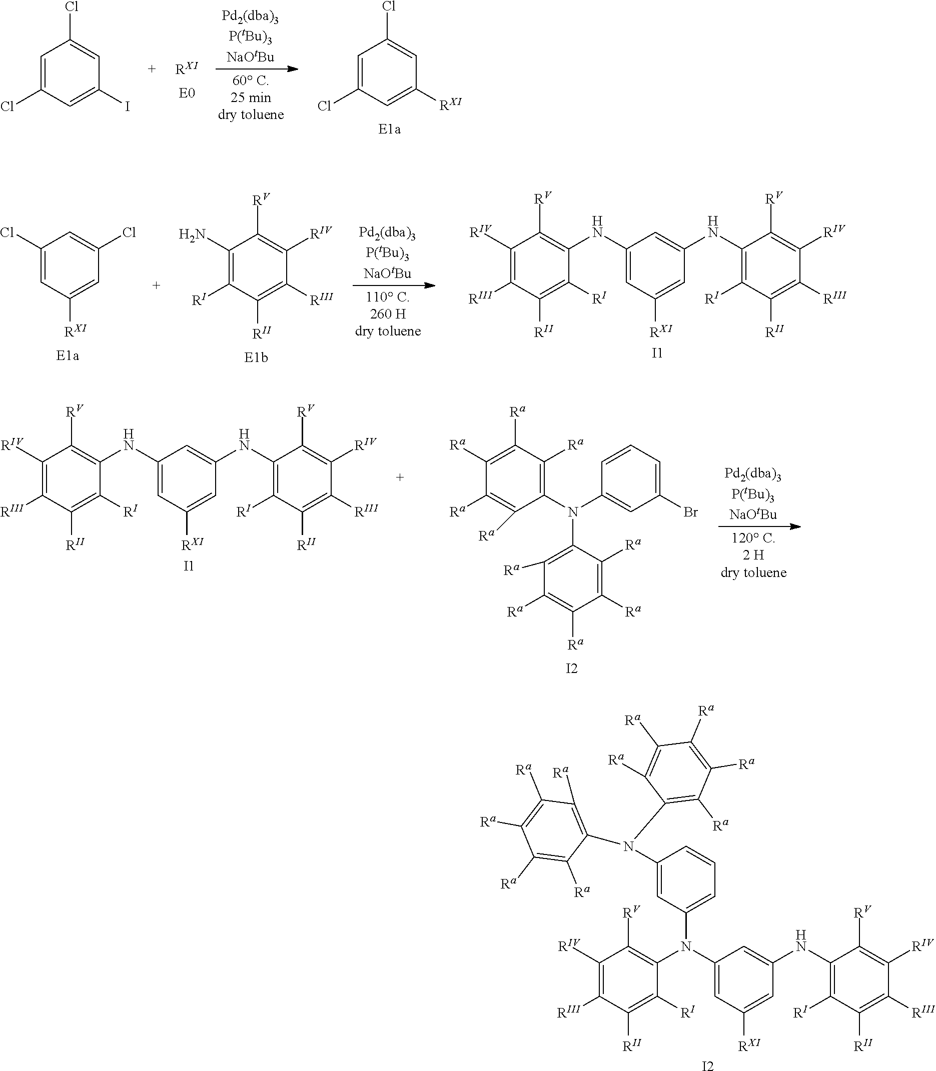

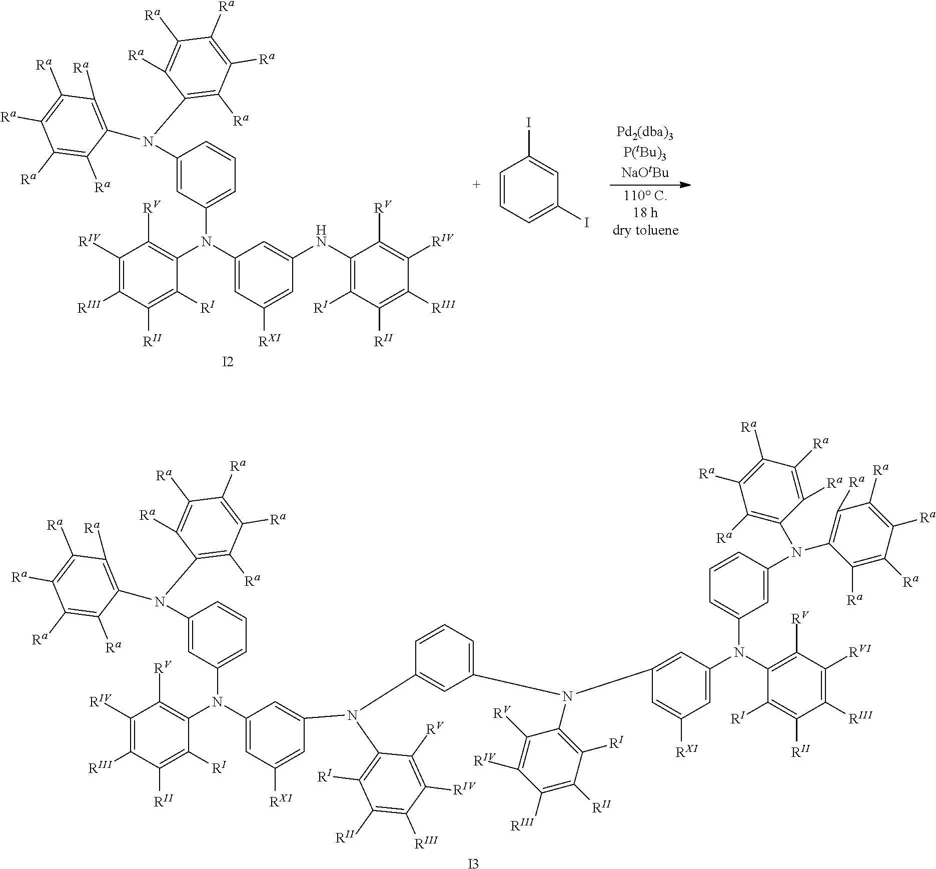

### General Procedure for Synthesis AAV0:

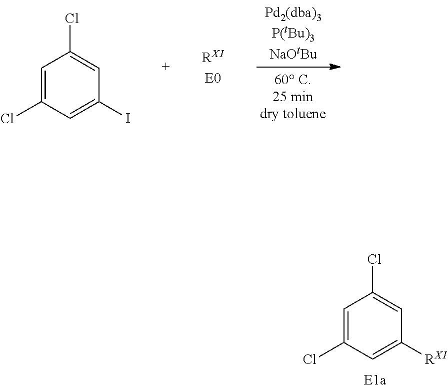

E0 (1.00 equivalents), 1,3-Dichloro-5-iodobenzene (1.10 equivalents; CAS: 3032-81-3), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 2.00 equivalents) are stirred under nitrogen atmosphere in toluene at 60° C. for 25 min. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and E1a is obtained as solid.

### General Procedure for Synthesis AAV1:

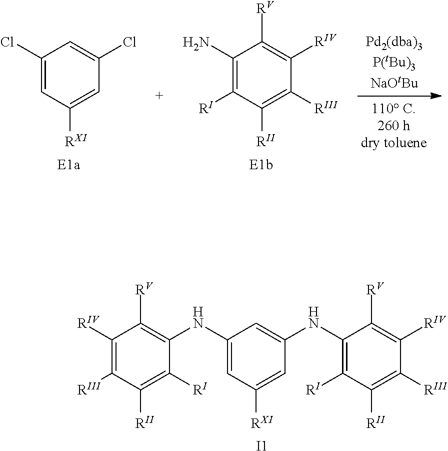

E1a (1.00 equivalents), E1b (5.00 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 5.00 equivalents) are stirred under nitrogen atmosphere in toluene at 110° C. for 260 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I1 is obtained as solid.

### General Procedure for Synthesis AAV2:

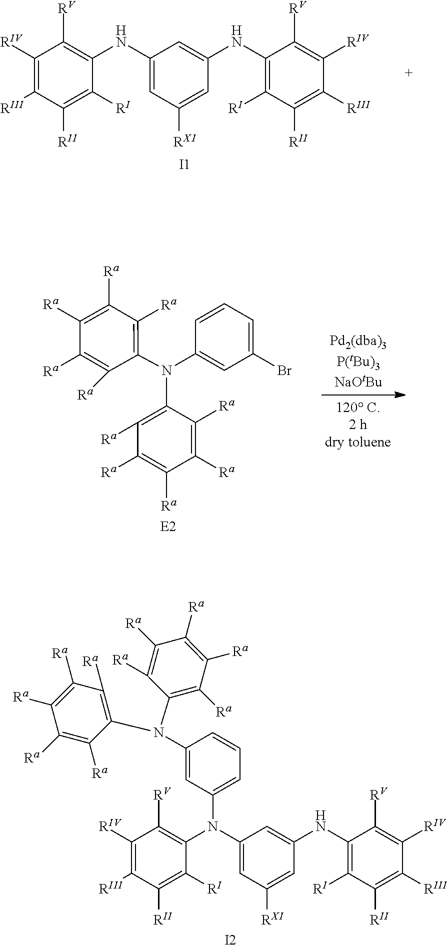

I1 (1.20 equivalents), E2 (1.00 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 2.00 equivalents) are stirred under nitrogen atmosphere in toluene at 120° C. for 2 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I2 is obtained as solid.

### General Procedure for Synthesis AAV3:

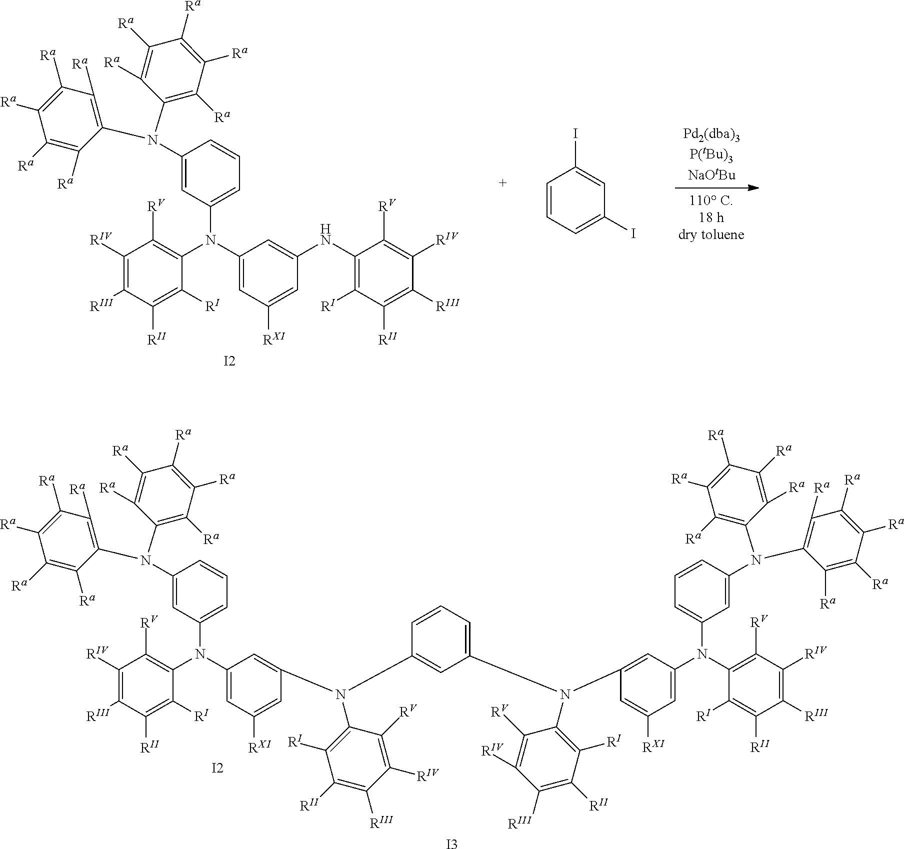

I2 (1.00 equivalents), 1,3-diiodobenzene (2.80 equivalents; CAS: 626-00-6), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.09 equivalents) and sodium tert-butoxide (NaO^{t}Bu; 11.40 equivalents) are stirred under nitrogen atmosphere in toluene at 110° C. overnight. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I3 is obtained as solid.

### General Procedure for Synthesis AAV4:

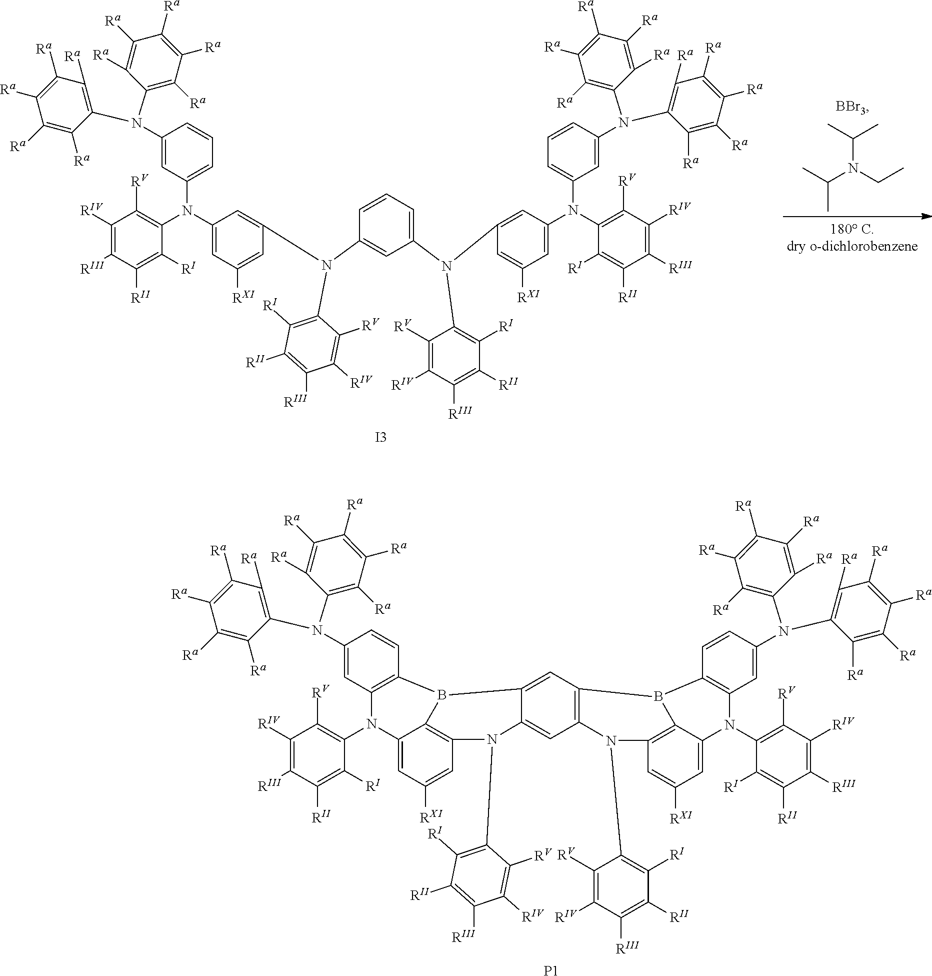

Under nitrogen atmosphere, boron tribromide (CAS 10294-33-4, 4.00 equivalents) is slowly added to a solution of I3 (1.00 equivalents) in o-dichlorobenzene. The reaction mixture is stirred at 180° C. overnight and, upon cooling to room temperature, quenched by the addition of N,N-diisopropylethylamine (CAS 7087-68-5; 16.0 equivalents). The reaction mixture is extracted with dichloromethane and water and the phases are separated. The combined organic layers are dried over MgSO₄ and then the solvent is removed under reduced pressure. The crude product obtained is purified by recrystallization or column chromatography and P1 is obtained as solid.

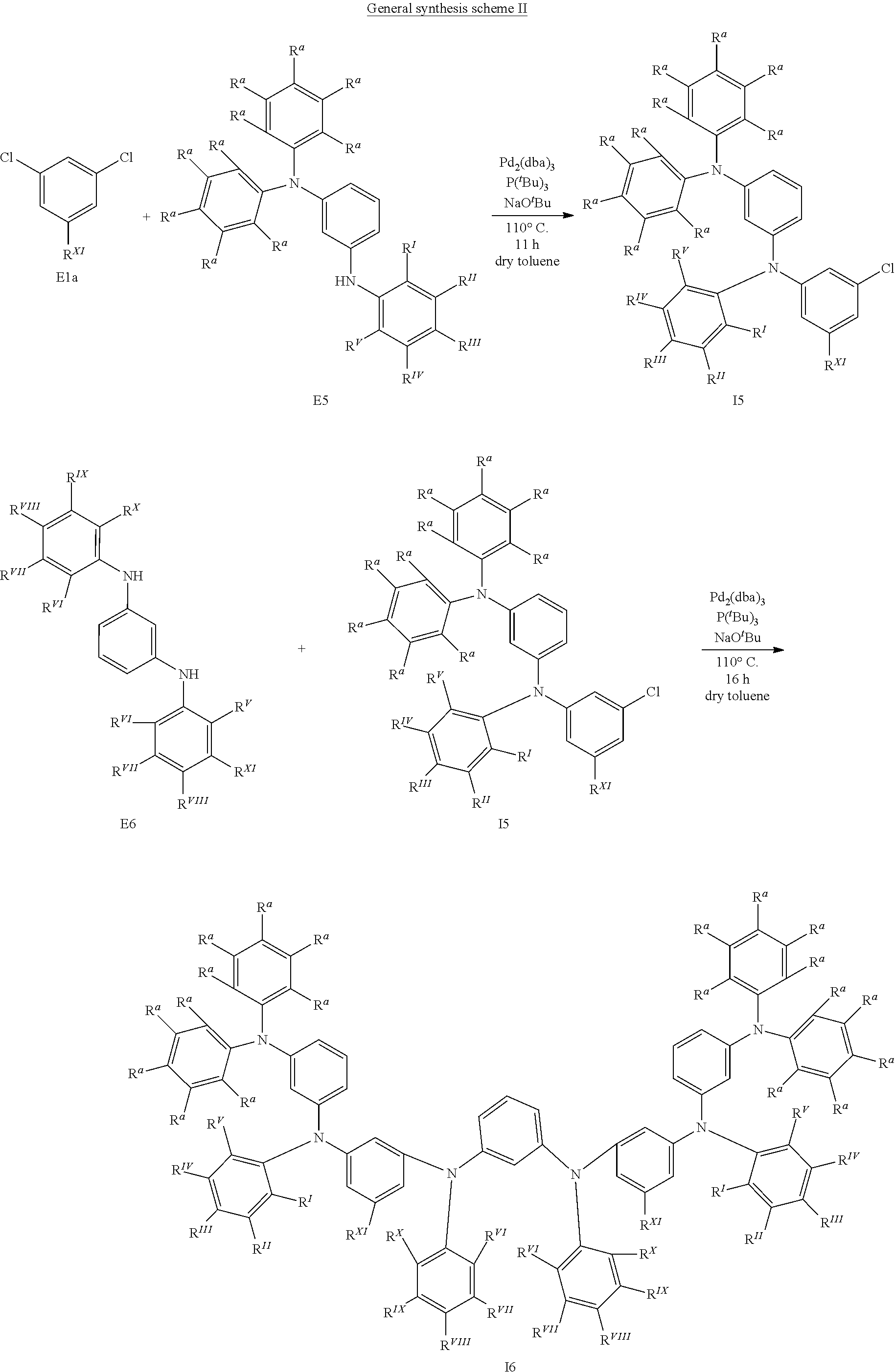

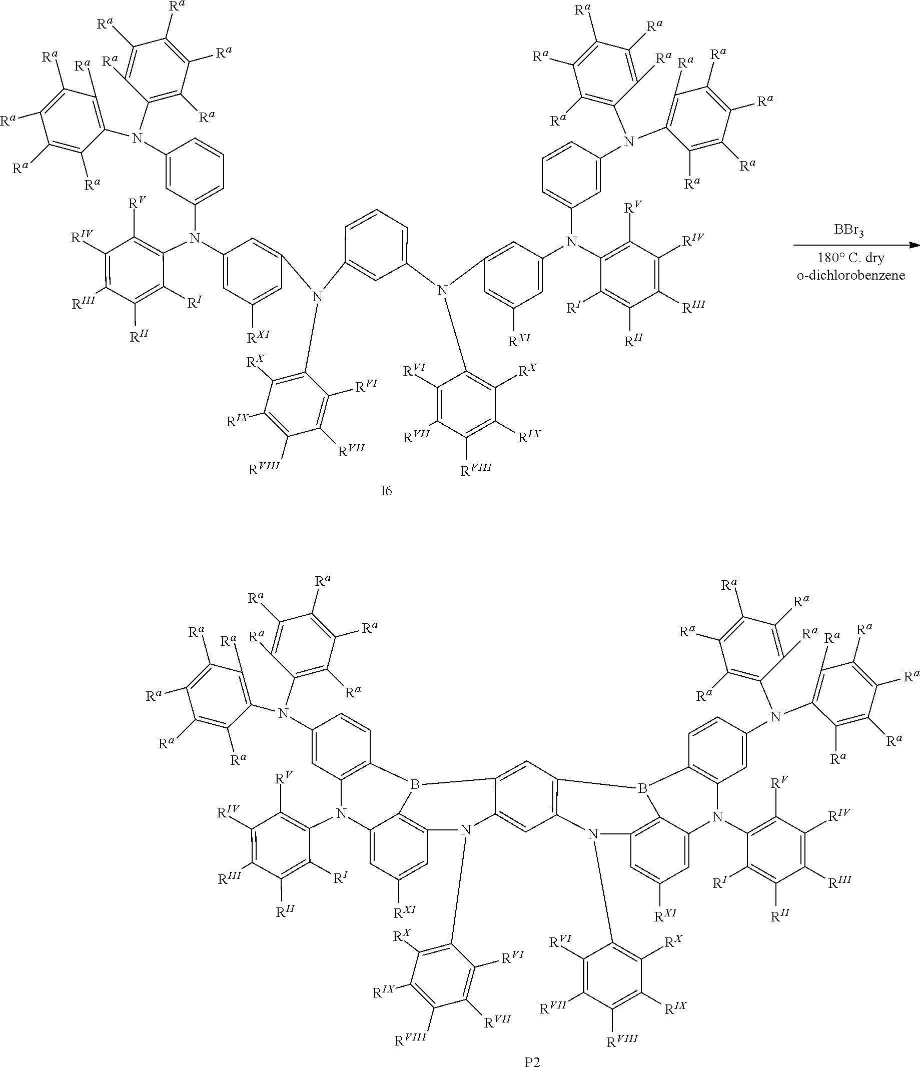

### General Procedure for Synthesis AAV5:

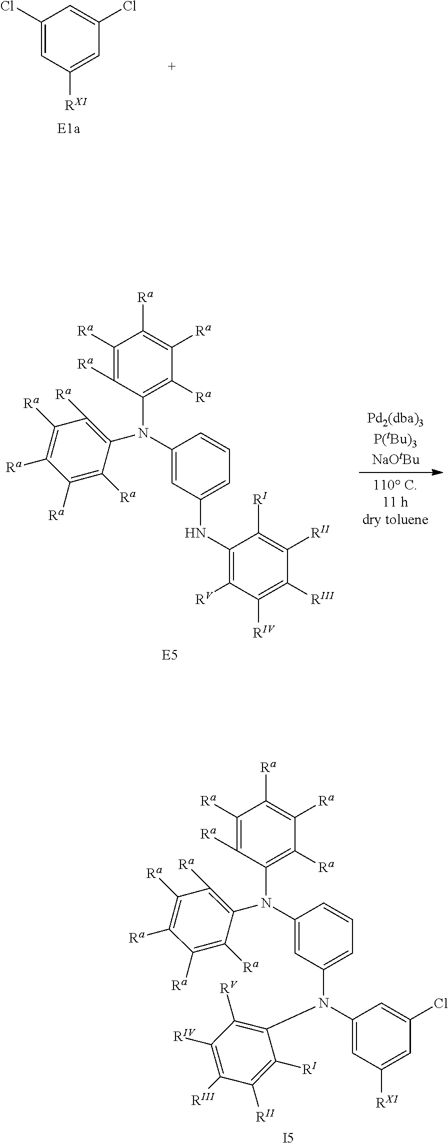

E1a (1.20 equivalents), E5 (1.00 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 2.00 equivalents) are stirred under nitrogen atmosphere in toluene at 110° C. for 11 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I5 is obtained as solid.

### General Procedure for Synthesis AAV6:

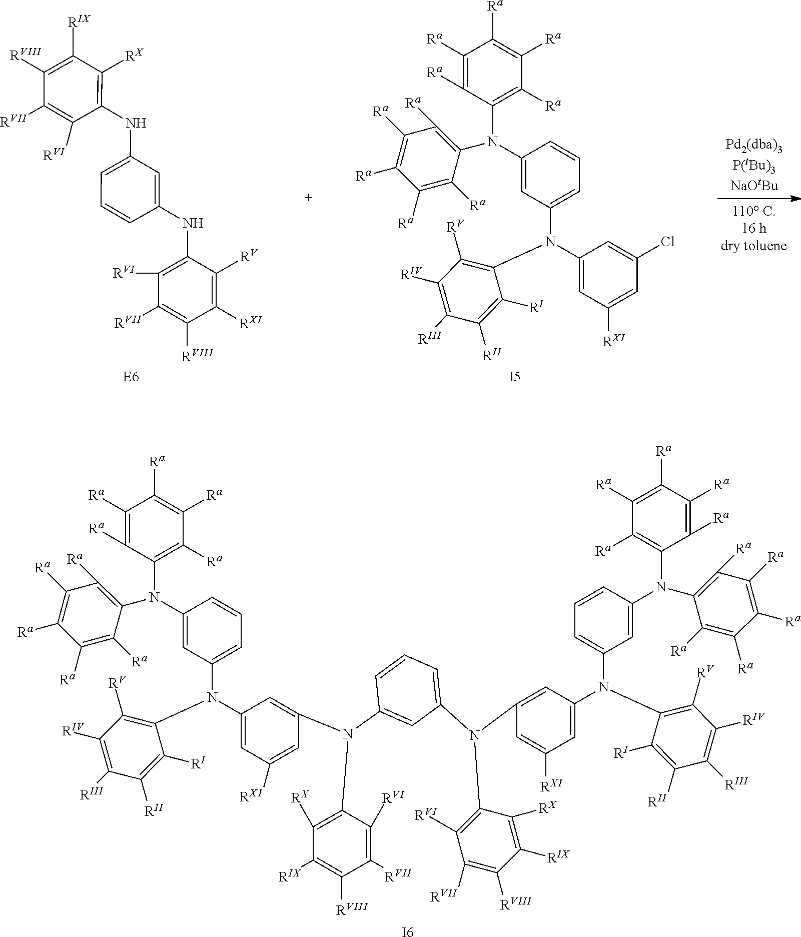

E6 (1.00 equivalents), I5 (2.20 equivalents), tris(dibenzylideneacetone)dipalladium Pd₂(dba)₃ (0.02 equivalents; CAS: 51364-51-3), tri-tert-butyl-phosphine (P(^{I}Bu)₃, CAS: 13716-12-6, 0.08 equivalents) and sodium tert-butoxide (NaO^{t}Bu; 4.00 equivalents) are stirred under nitrogen atmosphere in toluene at 110° C. overnight. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I6 is obtained as solid.

### General Procedure for Synthesis AAV7:

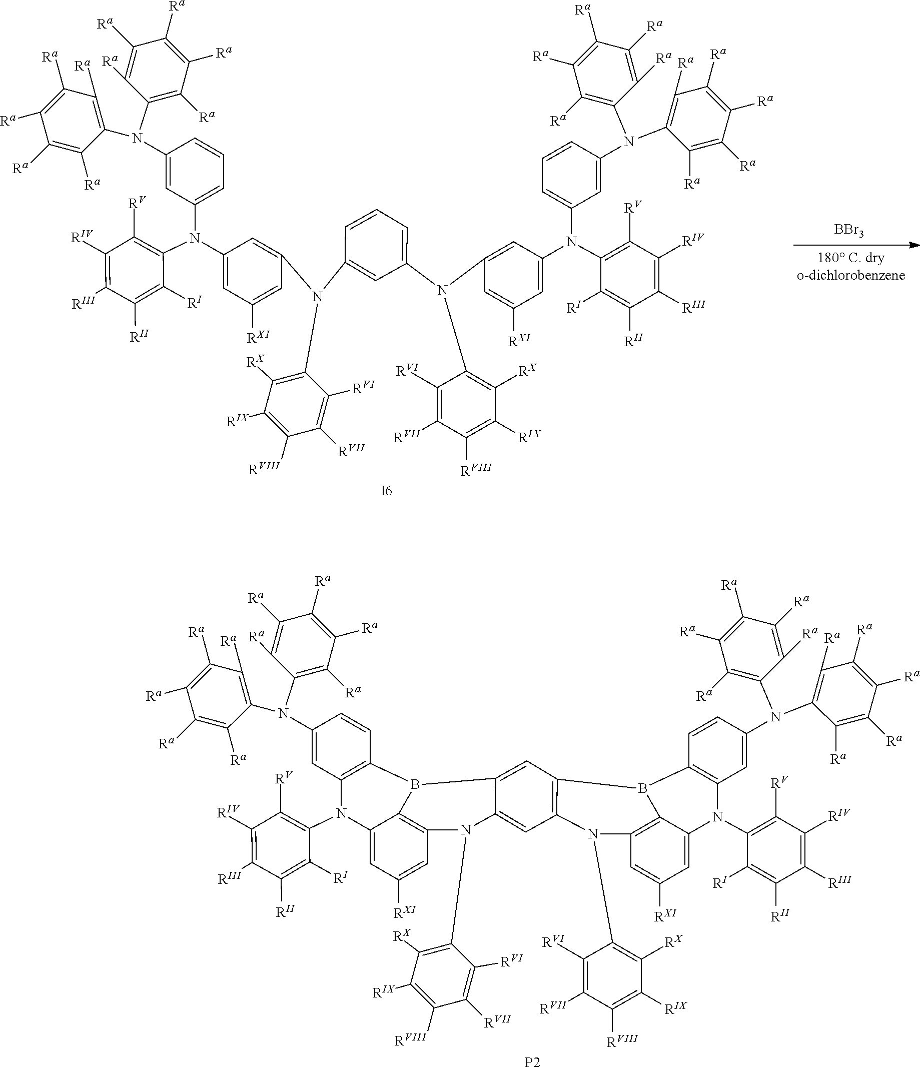

Under nitrogen atmosphere, boron tribromide (CAS 10294-33-4, 4.00 equiv.) is slowly added to a solution of I6 (1.00 equiv.) in o-dichlorobenzene. The reaction mixture is stirred at 180° C. overnight and, upon cooling to room temperature, quenched by the addition of N,N-diisopropylethylamine (CAS 7087-68-5; 16.0 equivalents). The reaction mixture is extracted with dichloromethane and water and the phases are separated. The combined organic layers are dried over MgSO₄ and then the solvent is removed under reduced pressure. The crude product obtained is purified by recrystallization or column chromatography and P2 is obtained as solid.

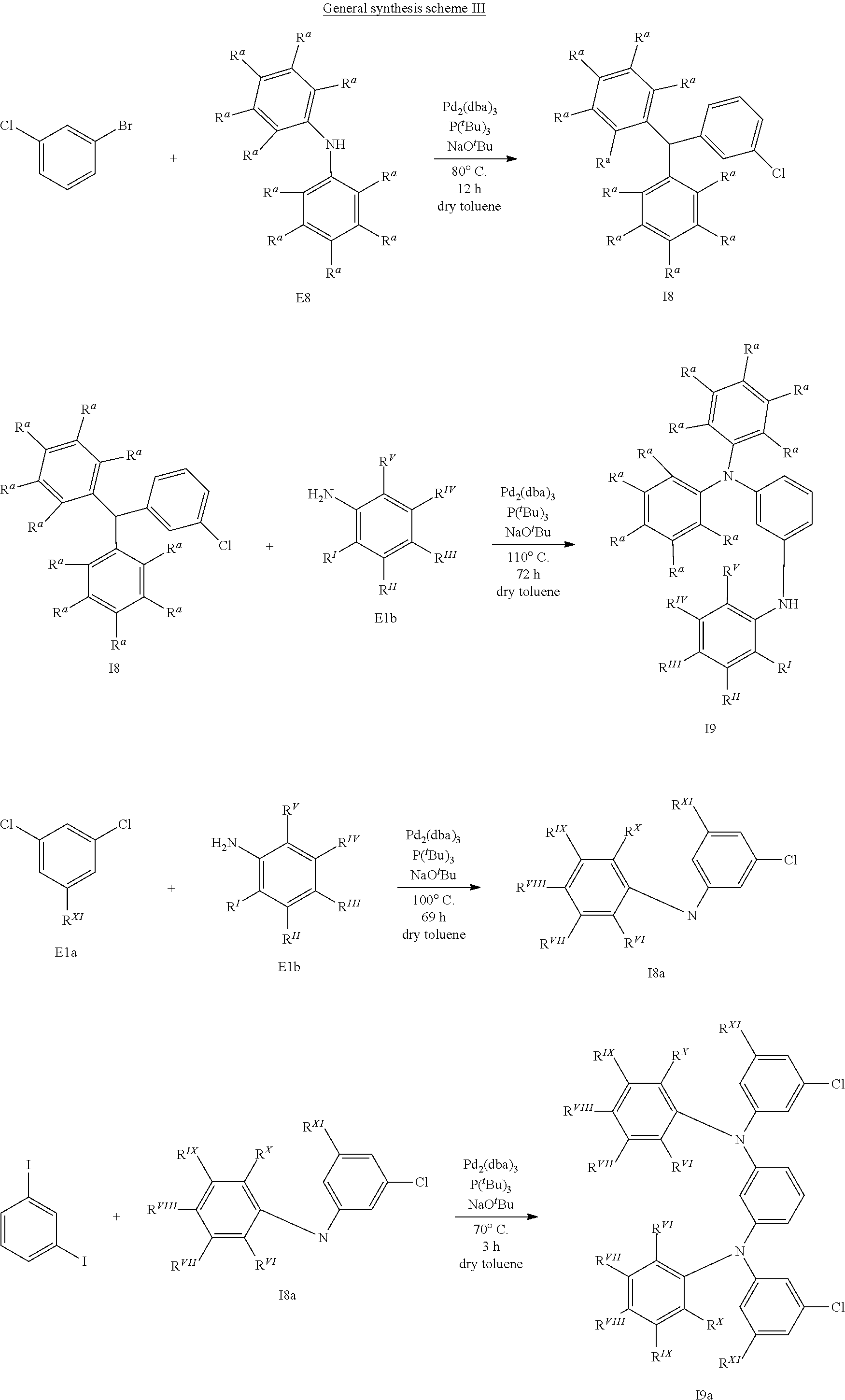

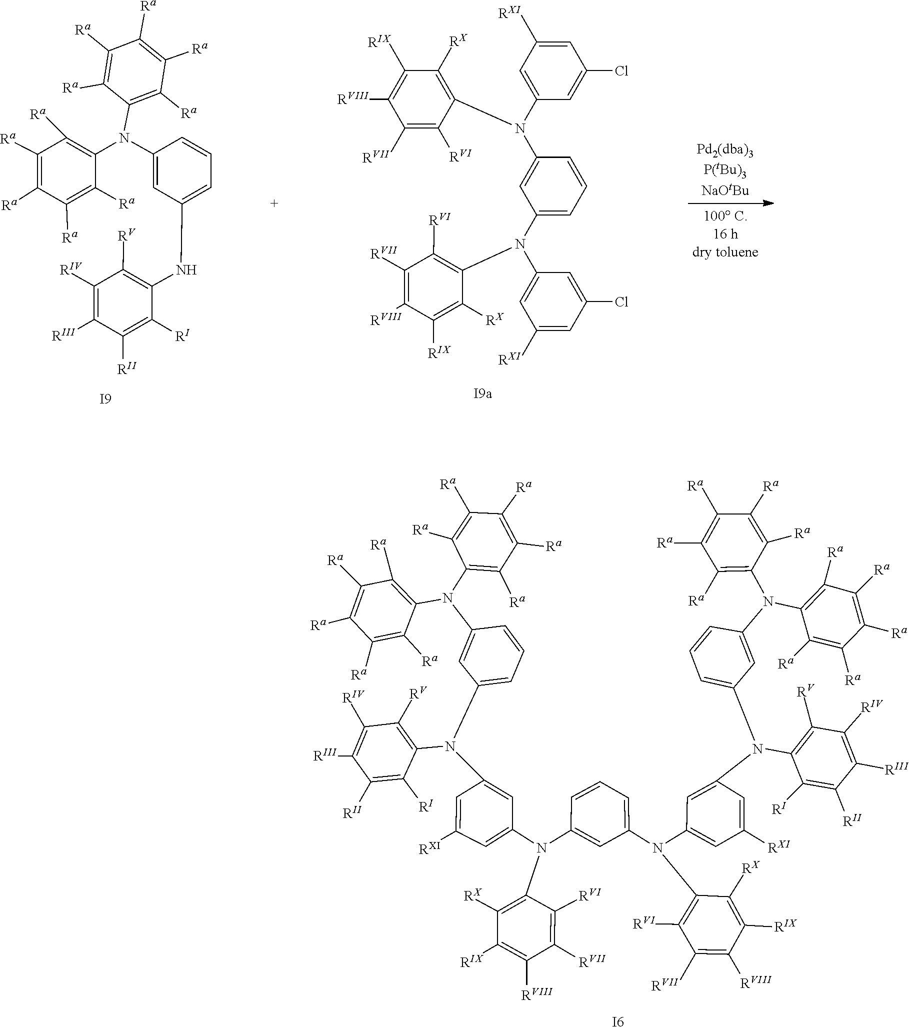

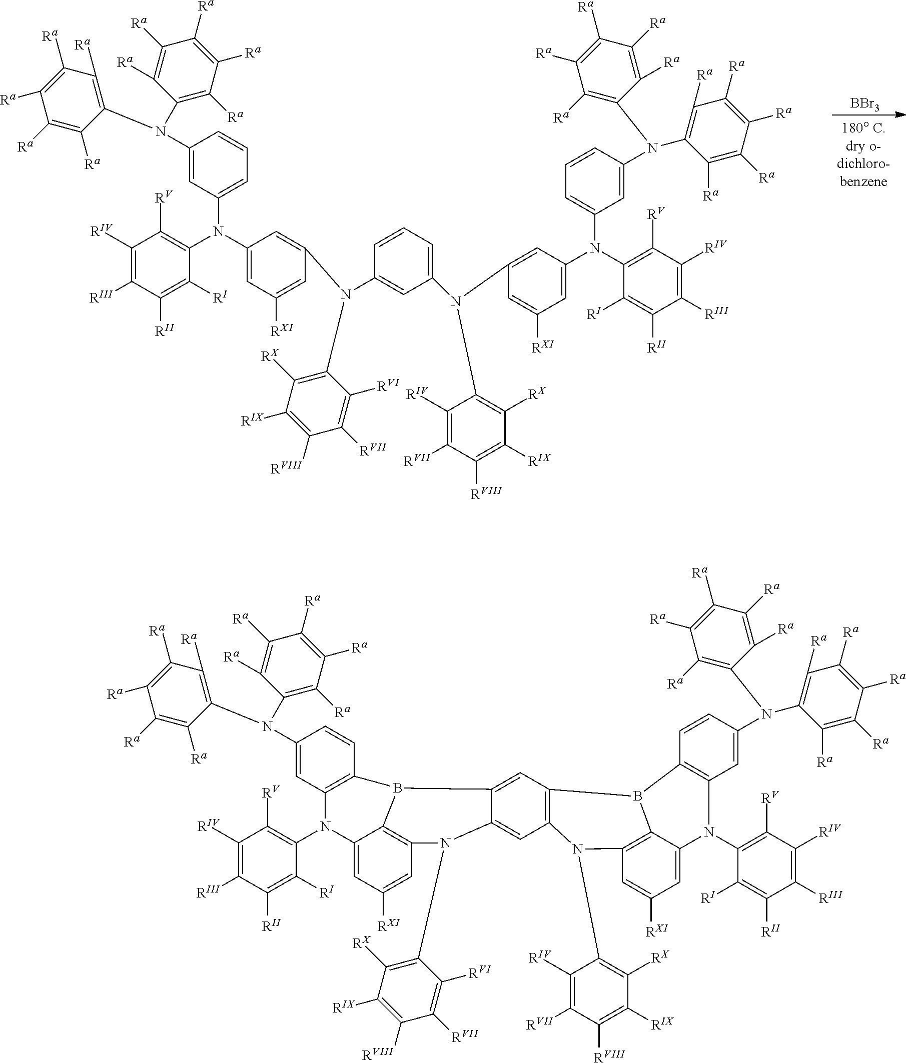

### General Procedure for Synthesis AAV8:

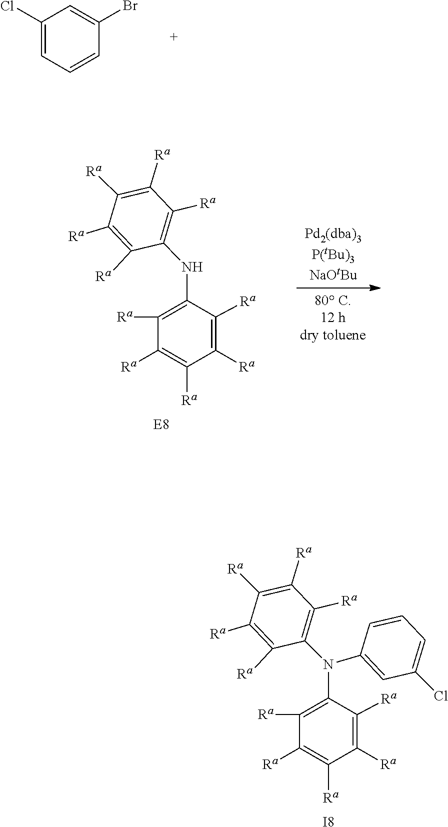

3-Bromochlorobenzene (1.50 equivalents; GAS 108-37-2), E8 (1.00 equivalents), tris(dibenzylideneacetone)dipalladium Pd₂(dba)₃ (0.02 equivalents; GAS: 51364-51-3), tri-tert-butyl-phosphine (P(^{t}Bu)₃; 0.08 equivalents; GAS: 1371 6-12-6) and sodium tert-butoxide (NaO^{t}Bu; 4.00 equivalents) are stirred under nitrogen atmosphere in toluene at 80° C. for 12 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I8 is obtained as solid.

### General Procedure for Synthesis AAV9:

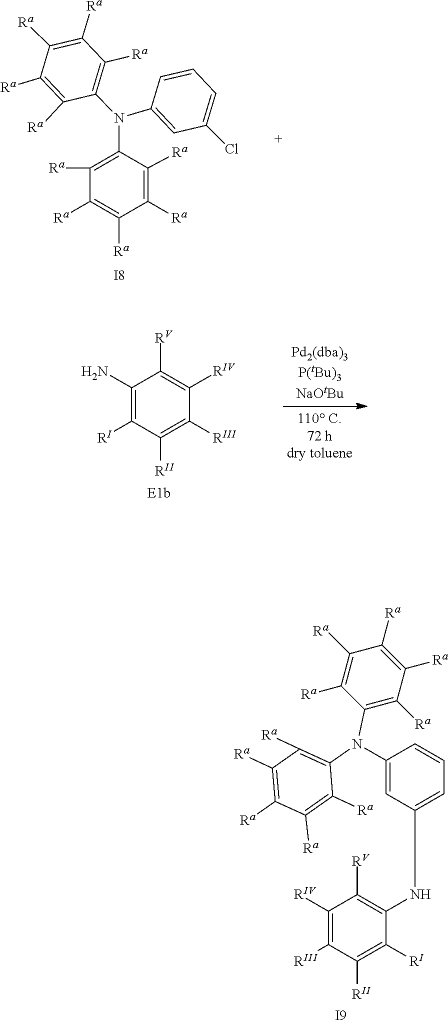

I8 (1.00 equivalents), E1 b (1.50 equivalents), tris(dibenzylideneacetone)dipalladium Pd₂(dba)₃ (0.06 equivalents; CAS: 51364-51-3), tri-tert-butyl-phosphine (P(^{t}Bu)₃; 0.02 equivalents; CAS: 13716-12-6) and sodium tert-butoxide (NaO^{t}Bu; 6.00 equivalents) are stirred under nitrogen atmosphere in toluene at 110° C. for 72 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I9 is obtained as solid.

### General Procedure for Synthesis AAV8a:

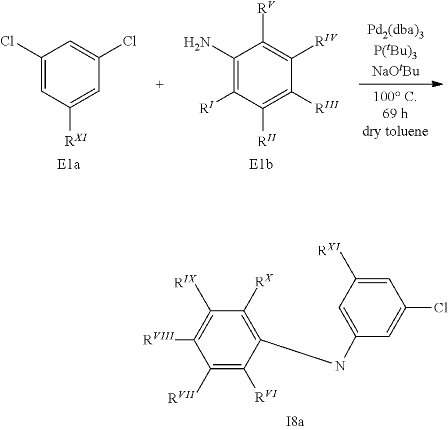

E1a (1.20 equivalents), E1b (1.00 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 2.00 equivalents) are stirred under nitrogen atmosphere in toluene at 110° C. for 11 h. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I8a is obtained as solid.

### General Procedure for Synthesis AAV9a:

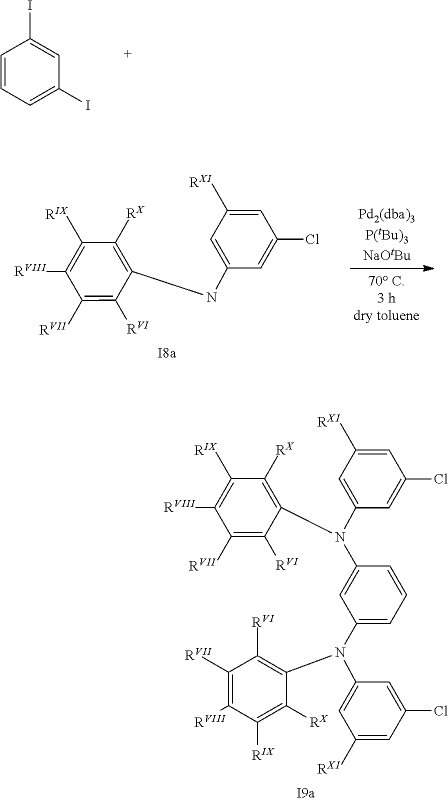

I8a (0.66 equivalents), 1,3-Diiodobenzene (1.00 equivalents; CAS: 626-00-6), tris(dibenzylideneacetone)dipalladium Pd₂(dba)₃ (0.01 equivalents; CAS: 51364-51-3), tri-tert-butyl-phosphine (P(^{t}Bu)₃, CAS: 13716-12-6, 0.04 equivalents) and sodium tert-butoxide (NaO^{t}Bu; 4.00 equivalents) are stirred under nitrogen atmosphere in toluene at 70° C. for 3 h. After cooling down to room temperature (rt) the reaction mixture is extracted with ethyl acetate and brine and the phases are separated. The combined organic layers are dried over MgSO₄ and then the solvent is removed under reduced pressure. The crude product obtained is purified by recrystallization or column chromatography and I9a is obtained as solid.

### General Procedure for Synthesis AAV10:

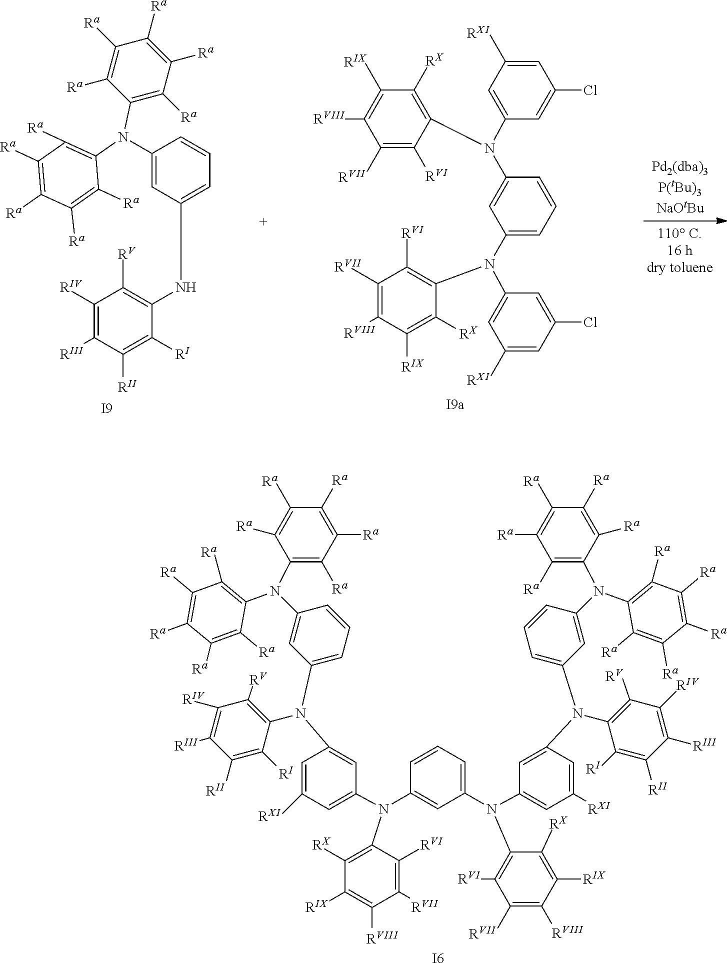

I9a (1.00 equivalents), I9 (2.55 equivalents), tris(dibenzylideneacetone)dipalladium Pd₂(dba)₃ (0.04 equivalents; CAS: 51364-51-3), tri-tert-butyl-phosphine (P(^{t}Bu)₃, CAS: 13716-12-6, 0.16 equivalents) and sodium tert-butoxide (NaO^{t}Bu; 3.50 equivalents) are stirred under nitrogen atmosphere in toluene at 110° C. overnight. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and I6 is obtained as solid.

### General Procedure for Synthesis AAV7:

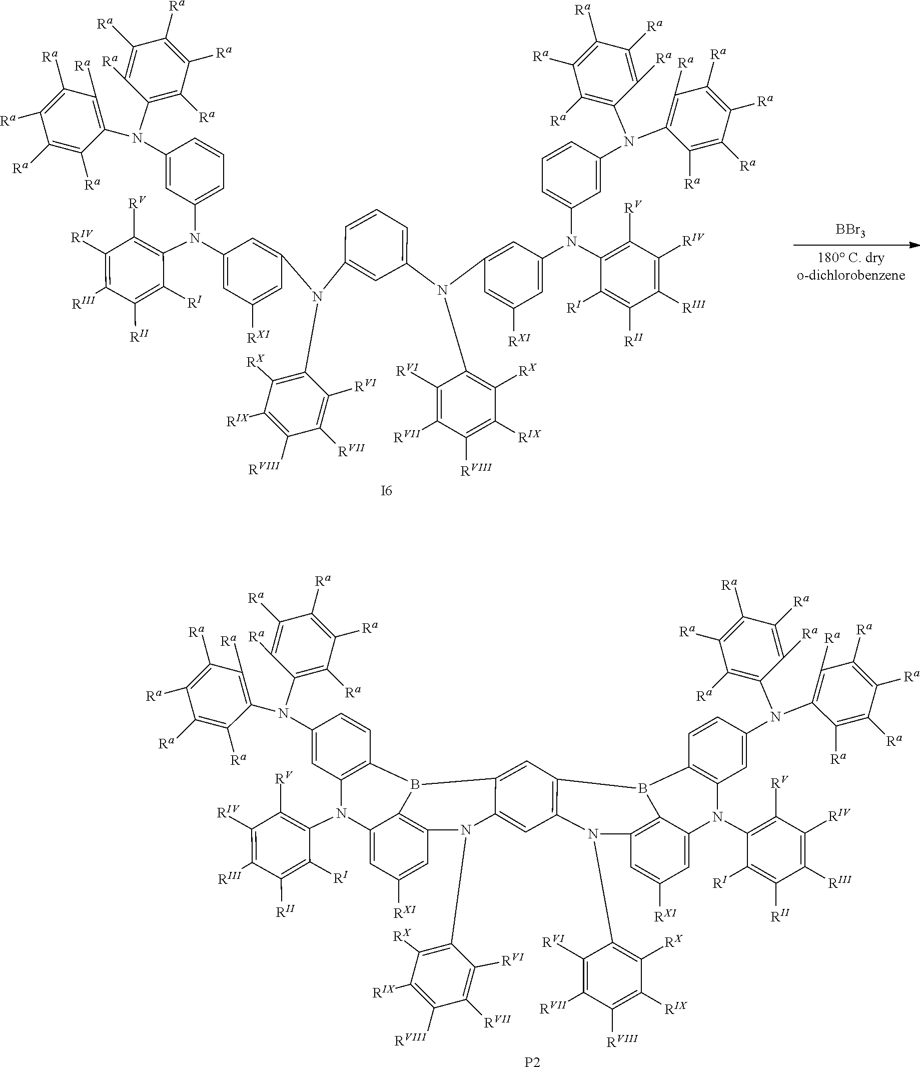

Under nitrogen atmosphere, boron tribromide (CAS 10294-33-4, 4.00 equiv.) is slowly added to a solution of I6 (1.00 equiv.) in o-dichlorobenzene. The reaction mixture is stirred at 180° C. overnight and, upon cooling to room temperature, quenched by the addition of N,N-Diisopropylethylamine (CAS 7087-68-5; 16.0 equivalents). The reaction mixture is extracted with dichloromethane and water and the phases are separated. The combined organic layers are dried over MgSO₄ and then the solvent is removed under reduced pressure. The crude product obtained is purified by recrystallization or column chromatography and P2 is obtained as solid.

### Cyclic Voltammetry

Cyclic voltammograms are measured from solutions having concentration of 10⁻³ mol/L of the organic molecules in dichloromethane or a suitable solvent and a suitable supporting electrolyte (e.g., 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent Density Functional Theory (TD-DFT) methods. Orbital and excited state energies are calculated with the B3LYP functional. Def2-SVP basis sets (and a m4-grid for numerical integration) are used. The Turbomole program package is used for all calculations.

### Photophysical Measurements

### Sample Pretreatment: Spin-Coating

Apparatus: Spin150, SPS euro.

The sample concentration is 0.2 mg/ml, dissolved in Toluene/DCM a suitable solvent.

Program: 7; 30 sec. at 2000 U/min. After coating, the films are dried at 70° C. for 1 min.

### Photoluminescence Spectroscopy and Time-Correlated Single-Photon Counting (TCSPC)

Steady-state emission spectroscopy is recorded using a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra are corrected using standard correction fits.

Excited state lifetimes are determined employing the same system using the TCSPC method with FM-2013 equipment and a Horiba Yvon TCSPC hub.

### Excitation Sources:

NanoLED 370 (wavelength: 371 nm, pulse duration: 1.1 ns)

NanoLED 290 (wavelength: 294 nm, pulse duration: <1 ns)

SpectraLED 310 (wavelength: 314 nm)

SpectraLED 355 (wavelength: 355 nm).

Data analysis (exponential fit) was done using the software suite DataStation and DAS6 analysis software. The fit is specified using the chi-squared-test.

Time-Resolved PL Spectroscopy in the μs-Range and Ns-Range (FS5)

Time-resolved PL measurements were performed on a FS5 fluorescence spectrometer from Edinburgh Instruments. Compared to measurements on the HORIBA setup, better light gathering allows for an optimized signal to noise ratio, which favors the FS5 system especially for transient PL measurements of delayed fluorescence characteristics. The continuous light source is a 150W xenon arc lamp, selected wavelengths are chosen by a Czerny-Turner monochromator, which is also used to set specific emission wavelengths. The sample emission is directed towards a sensitive R928P photomultiplier tube (PMT), allowing the detection of single photons with a peak quantum efficiency of up to 25% in the spectral range between 200 nm to 870 nm. The detector is a temperature stabilized PMT, providing dark counts below 300 cps (counts per second). Finally, to determine the transient decay lifetime of the delayed fluorescence, a tail fit using three exponential functions is applied. By weighting the specific lifetimes τᵢ with their corresponding amplitudes Aᵢ,

$${τ}_{DF} = {\sum }_{i = 1}^{3} \frac{{A}_{i} {τ}_{i}}{{A}_{i}}$$

the delayed fluorescence lifetime τ_{DF} is determined.

### Photoluminescence Quantum Yield Measurements

For photoluminescence quantum yield (PLQY) measurements an Absolute PL Quantum Yield Measurement C9920-03G system (Hamamatsu Photonics) is used. Quantum yields and CIE coordinates are determined using the software U6039-05 version 3.6.0.

Emission maxima are given in nm, quantum yields C in % and CIE coordinates as x,y values.

PLQY is determined using the following protocol:

Quality assurance: Anthracene in ethanol (set concentration) is used as a reference

Excitation wavelength: the absorption maximum of the organic molecule is determined and the molecule is excited using this wavelength

Measurement

Quantum yields are measured for sample of films (2% by weight of the emitter in PMMA) under nitrogen atmosphere. The yield is calculated using the equation:

$${Φ}_{PL} = \frac{{n}_{photon} , emitted}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ}$$

wherein nₚₕₒₜₒₙ denotes the photon count and Int. the intensity.

### Production and Characterization of Optoelectronic Devices

Optoelectronic devices, such as OLED devices, including organic molecules according to embodiments of the present disclosure can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The (not fully optimized) OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g., applying increased current densities). In one or more embodiments, LT80 values at 500 cd/m² are determined using the following equation:

$$LT 80 ( 500 \frac{cd}{{m}^{2}} ) = LT 80 ( {L}_{0} ) {( \frac{{L}_{0}}{500 \frac{cd}{{m}^{2}}} )}^{1.6}$$

wherein L₀ denotes the initial luminance at the applied current density.

The values correspond to the average of several pixels (e.g., two to eight), the standard deviation between these pixels is given.

### HPLC-MS

HPLC-MS analysis is performed on an HPLC by Agilent (1260 series) with MS-detector (Thermo LTQ XL).

For example, an example HPLC method is as follows: a reverse phase column 3.0 mm×100 mm, particle size 2.7 μm from Agilent (Poroshell 120EC-C18, 3.0×100 mm, 2.7 μm HPLC column) is used in the HPLC. The HPLC-MS measurements are performed at room temperature (rt) following gradients:

| Flow rate [ml/min] | Time [min] | A[%] | B[%] | C[%] |
|---|---|---|---|---|
| 1.5 | 30 | 40 | 40 | 30 |
| 1.5 | 45 | 10 | 10 | 80 |
| 1.5 | 50 | 40 | 10 | 80 |
| 1.5 | 51 | 30 | 40 | 30 |
| 1.5 | 55 | 30 | 10 | 30 |

using the following solvent mixtures containing 0.1% formic acid:

| | | |
|---|---|---|
| Solvent A: | H2O (10%) | MeCN (90%) |
| Solvent B: | H2O (90%) | MeCN (10%) |
| Solvent C: | THF (50%) | MeCN (50%) |

An injection volume of 2 μL from a solution having a concentration of 0.5 mg/mL of the analyte is taken for the measurements.

Ionization of the probe is performed using an atmospheric pressure chemical ionization (APCI) source either in positive (APCI+) or negative (APCI−) ionization mode or an atmospheric pressure photoionization (APPI) source.

### Example 1

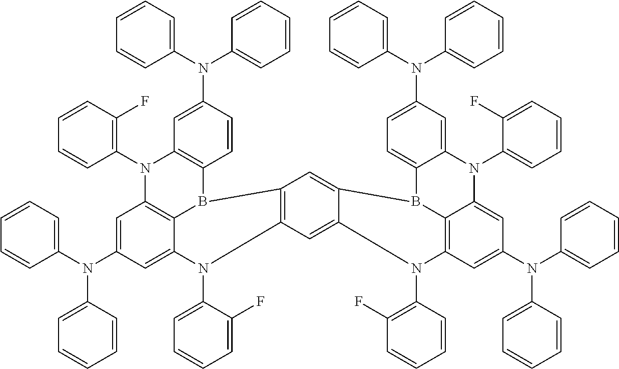 [SMILES: Fc1ccccc1N1c2cc(N(c3ccccc3)c3ccccc3)ccc2B2c3cc4c(cc3N(c3ccccc3F)c3cc(N(c5ccccc5)c5ccccc5)cc1c32)N(c1ccccc1F)c1cc(N(c2ccccc2)c2ccccc2)cc2c1B4c1ccc(N(c3ccccc3)c3ccccc3)cc1N2c1ccccc1F]

Example 1 was synthesized according to:

AAV1 (73% yield), wherein 3,5-dichloro-N,N-diphenylaniline [1329428-05-8] was used as compound E1a and 2-fluoroaniline [348-54-9] was used as compound E1b;

AAV2 (59% yield), wherein 3-bromotriphenylamine [78600-33-6] was used as compound E2;

AAV3 (94% yield);

AAV4 (25% yield).

MS (HPLC-MS): m/z (retention time)=1503.3 (7.13 min).

The emission maximum of example 1 (2% by weight in PMMA) is at 460 nm, the full width at half maximum (FWHM) is 0.10 eV (17 nm), the CIE_{X} and CIE_{Y} coordinates are 0.14, and 0.07, respectively, the PLQY is 71% and excited state lifetime is 2.9 μs.

### Example 2

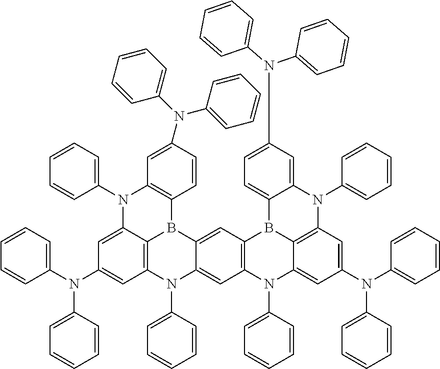 [SMILES: c1ccc(N(c2ccccc2)c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccc(N(c3ccccc3)c3ccccc3)cc2N4c2ccccc2)cc1]

Example 2 was synthesized according to:

AAV5 (54% yield), wherein 3,5-dichloro-N,N-diphenylaniline [1329428-05-8] was used as compound E1a and N,N,N′-triphenyl-benzene-1,3-diamine [1554227-26-7] was used as compound E5;

AAV6 (21% yield), wherein N,N′-diphenyl-m-phenylenediamine [5905-36-2] was used as compound E6;

AAV7 (17% yield).

MS (HPLC-MS): m/z (retention time)=1431.4 (7.99 min).

The emission maximum of example 2 (2% by weight in PMMA) is at 471 nm, the full width at half maximum (FWHM) is 0.11 eV (20 nm), the CIE_{X} and CIE_{Y} coordinates are 0.13, and 0.15, respectively, and the PLQY is 51%.

### Example 3

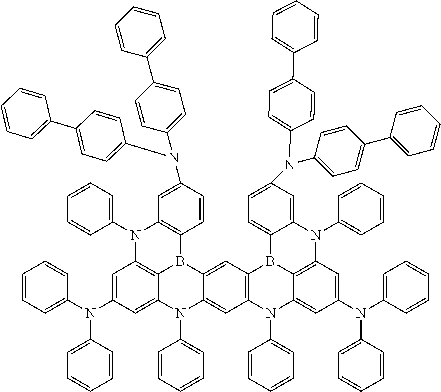 [SMILES: c1ccc(-c2ccc(N(c3ccc(-c4ccccc4)cc3)c3ccc4c(c3)N(c3ccccc3)c3cc(N(c5ccccc5)c5ccccc5)cc5c3B4c3cc4c(cc3N5c3ccccc3)N(c3ccccc3)c3cc(N(c5ccccc5)c5ccccc5)cc5c3B4c3ccc(N(c4ccc(-c6ccccc6)cc4)c4ccc(-c6ccccc6)cc4)cc3N5c3ccccc3)cc2)cc1]

Example 3 was synthesized according to:

AAV8 (99% yield), wherein N-[1,1′-biphenyl]-4-yl[1,1′-biphenyl]-4-amine [102113-98-4] was used as compound E8;

AAV9 (40% yield), wherein 3-bromotriphenylamine [78600-33-6] was used as compound E1b;

AAV8a (55% yield), wherein 3,5-dichloro-N,N-diphenylaniline [1329428-05-8] and anilin [62-53-3] was used as compound E1a and E1b, respectively;

AAV9a (73% yield);

AAV10 (14% yield);

AAV7 (17% yield).

MS (HPLC-MS): m/z (retention time)=1735.8 (8.56 min).

The emission maximum of example 3 (2% by weight in PMMA) is at 473 nm, the full width at half maximum (FWHM) is 0.10 eV (19 nm), the CIE_{X} and CIE_{Y} coordinates are 0.12, and 0.15, respectively.

### Example 4

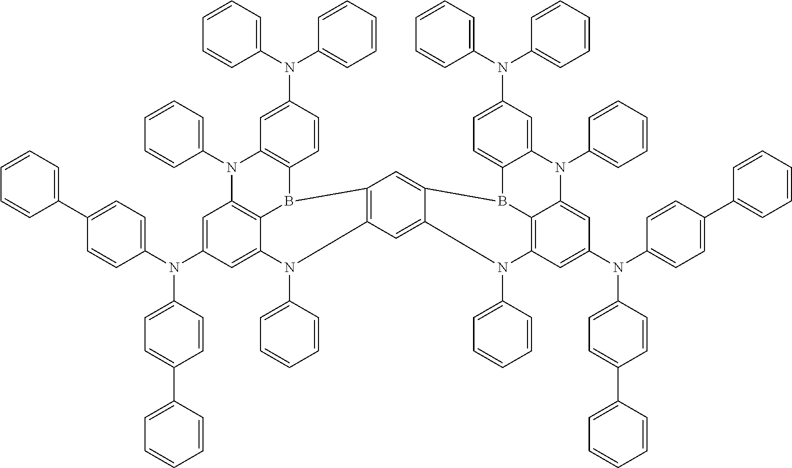 [SMILES: c1ccc(-c2ccc(N(c3ccc(-c4ccccc4)cc3)c3cc4c5c(c3)N(c3ccccc3)c3cc6c(cc3B5c3ccc(N(c5ccccc5)c5ccccc5)cc3N4c3ccccc3)B3c4ccc(N(c5ccccc5)c5ccccc5)cc4N(c4ccccc4)c4cc(N(c5ccc(-c7ccccc7)cc5)c5ccc(-c7ccccc7)cc5)cc(c43)N6c3ccccc3)cc2)cc1]

Example 4 was synthesized according to:

AAV0 (94% yield), wherein bis(4-biphenylyl)amine [102113-98-4] was used as compound E0;

AAV1 (87% yield), wherein aniline [62-53-3] was used as compound E1b;

AAV2 (54% yield), wherein 3-bromotriphenylamine [78600-33-6] was used as compound E2;

AAV3 (54% yield);

AAV4 (21% yield).

MS (HPLC-MS): m/z (retention time)=1735.8 (8.62 min).

The emission maximum of example 4 (2% by weight in PMMA) is at 472 nm, the full width at half maximum (FWHM) is 0.11 eV (20 nm), the CIE_{X} and CIE_{Y} coordinates are 0.13, and 0.16, respectively.

### Example 5

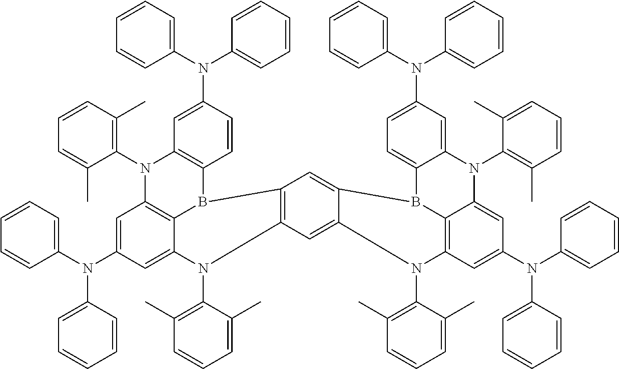 [SMILES: Cc1cccc(C)c1N1c2cc(N(c3ccccc3)c3ccccc3)ccc2B2c3cc4c(cc3N(c3c(C)cccc3C)c3cc(N(c5ccccc5)c5ccccc5)cc1c32)N(c1c(C)cccc1C)c1cc(N(c2ccccc2)c2ccccc2)cc2c1B4c1ccc(N(c3ccccc3)c3ccccc3)cc1N2c1c(C)cccc1C]

Example 5 was synthesized according to:

AAV1 (58% yield), wherein 3,5-dichloro-N,N-diphenylaniline [1329428-05-8] was used as compound E1a and 2,6-dimethylaniline [87-62-7] was used as compound E1b;

AAV2 (39% yield), wherein 3-bromotriphenylamine [78600-33-6] was used as compound E2;

AAV3 (55% yield);

AAV4 (3% yield).

MS (HPLC-MS): m/z (retention time)=1543.6 (8.39 min).

The emission maximum of example 5 (2% by weight in PMMA) is at 469 nm, the full width at half maximum (FWHM) is 0.10 eV (18 nm), the CIE_{X} and CIE_{Y} coordinates are 0.13, and 0.16, respectively, the PLQY is 75%.

### Additional Examples of Organic Molecules of Embodiments of the Present Disclosure

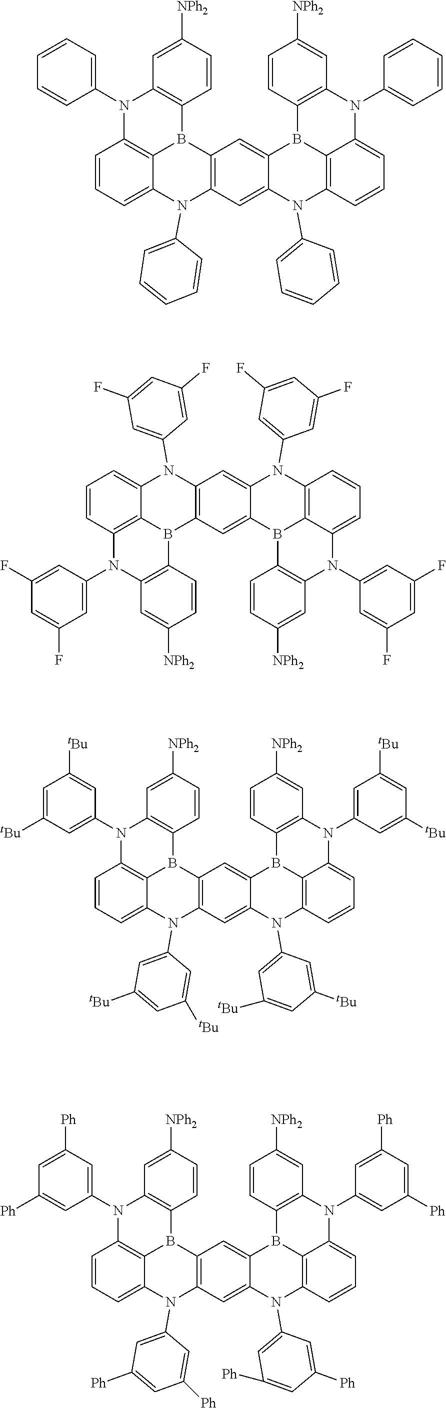

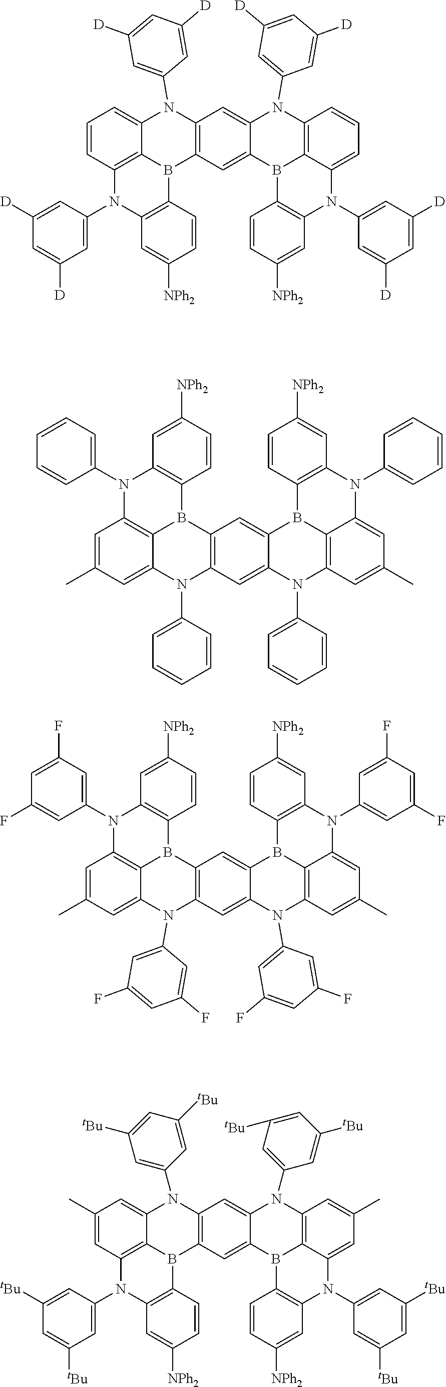

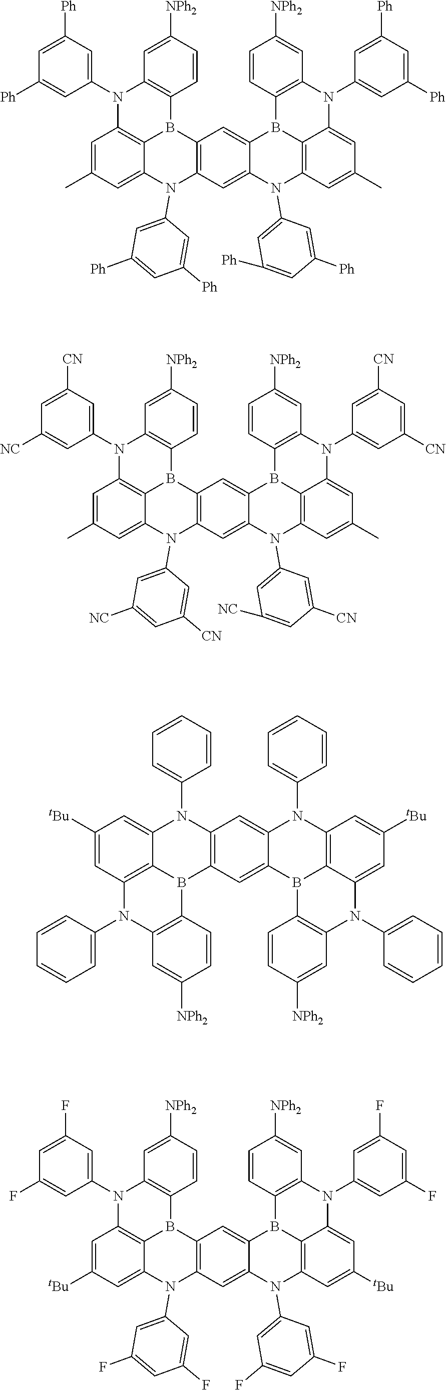

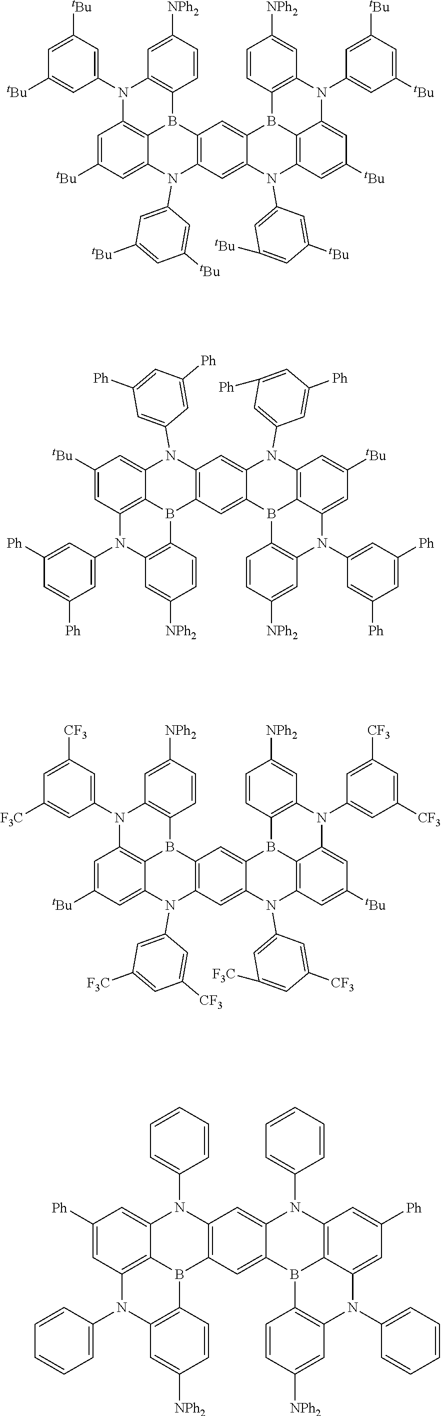

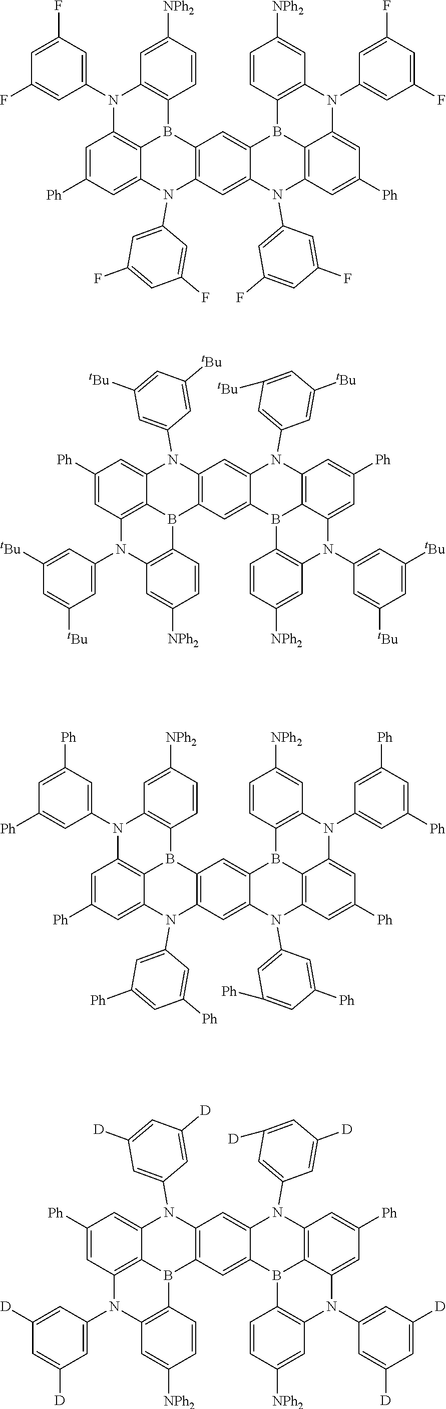

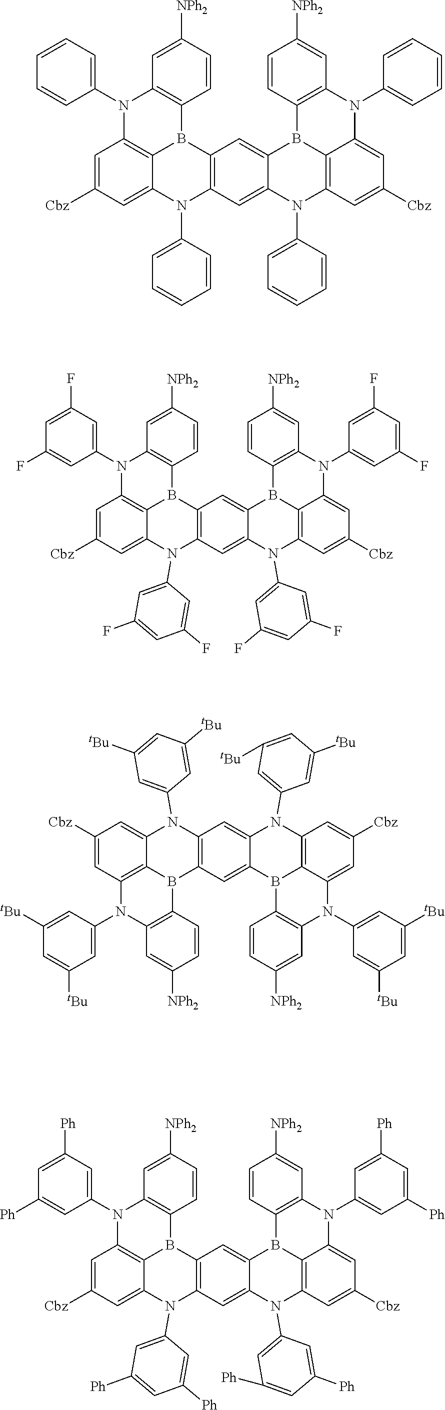

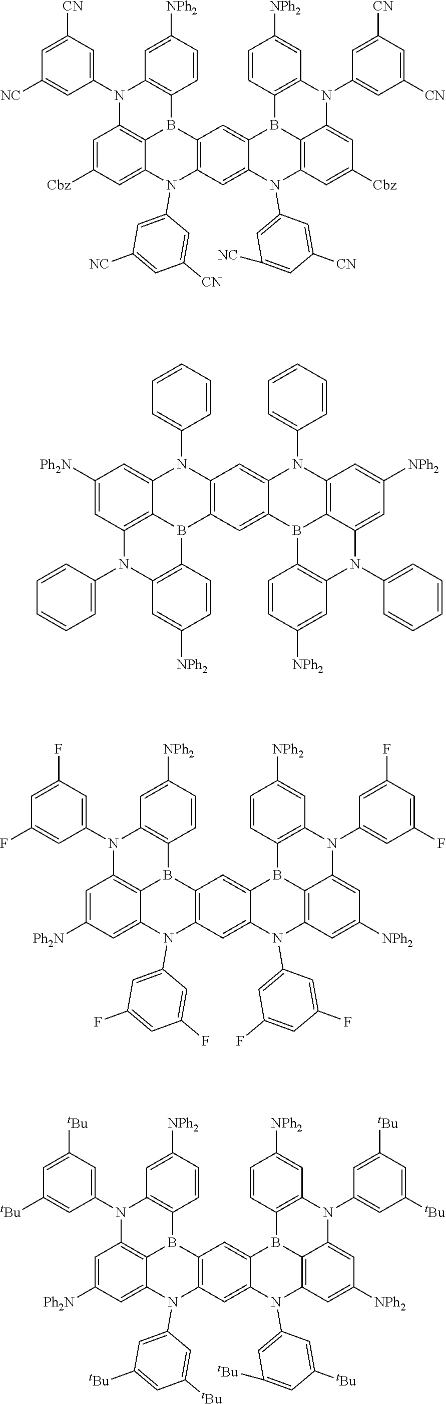

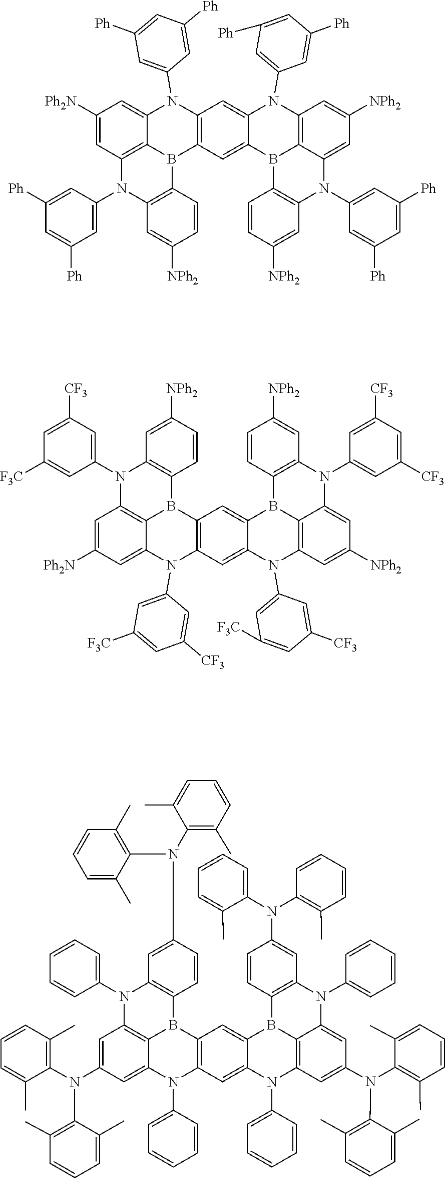

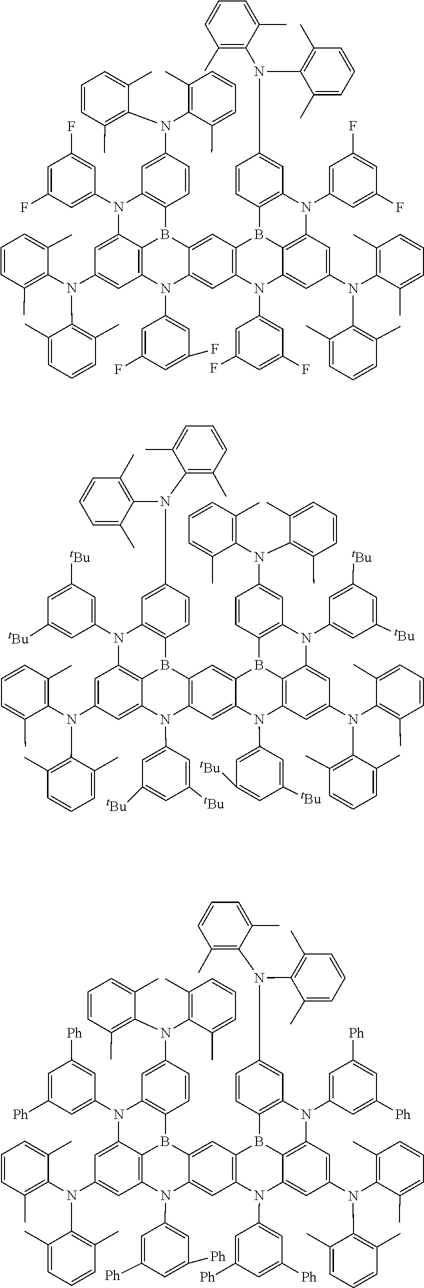

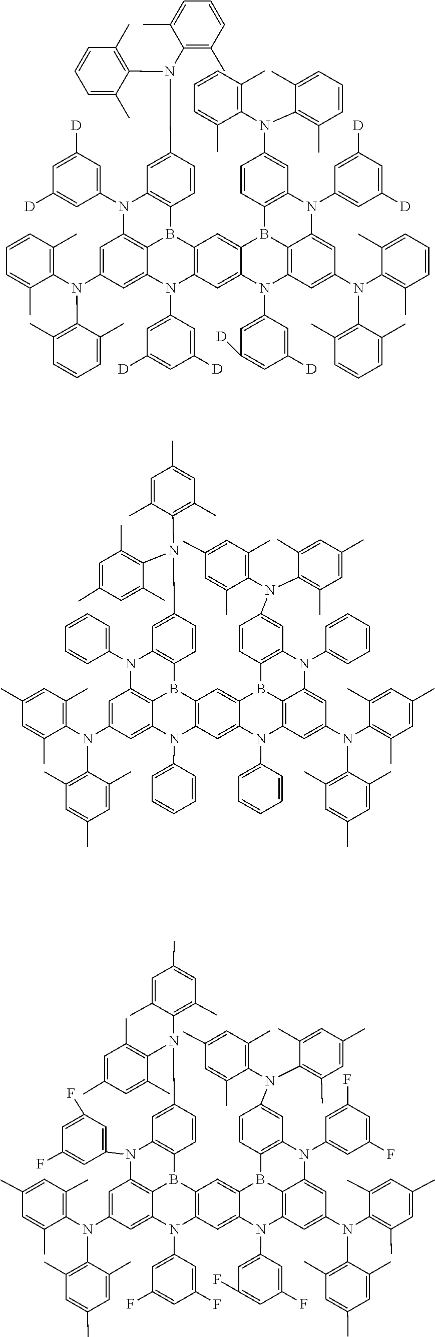

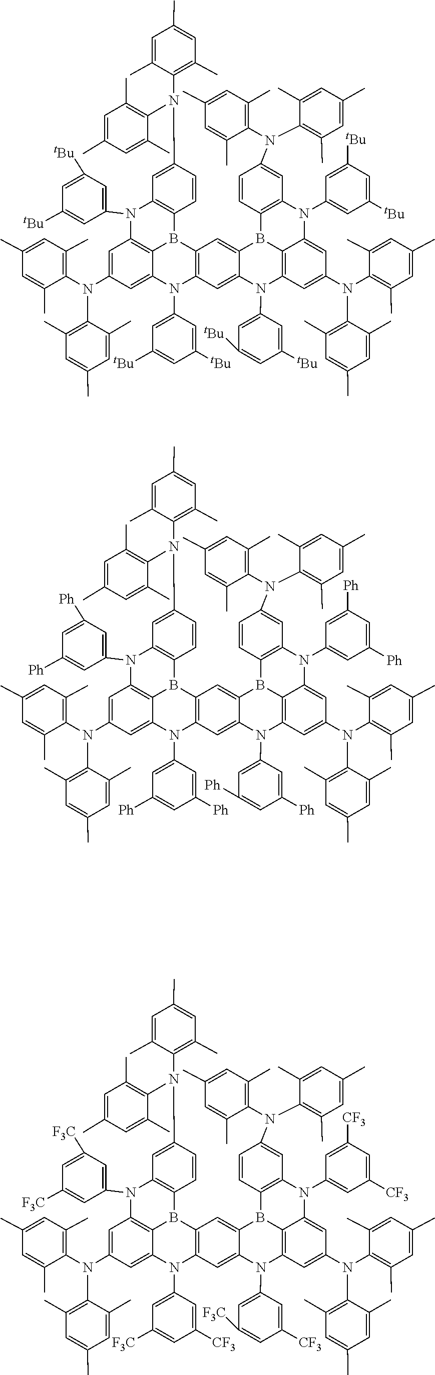

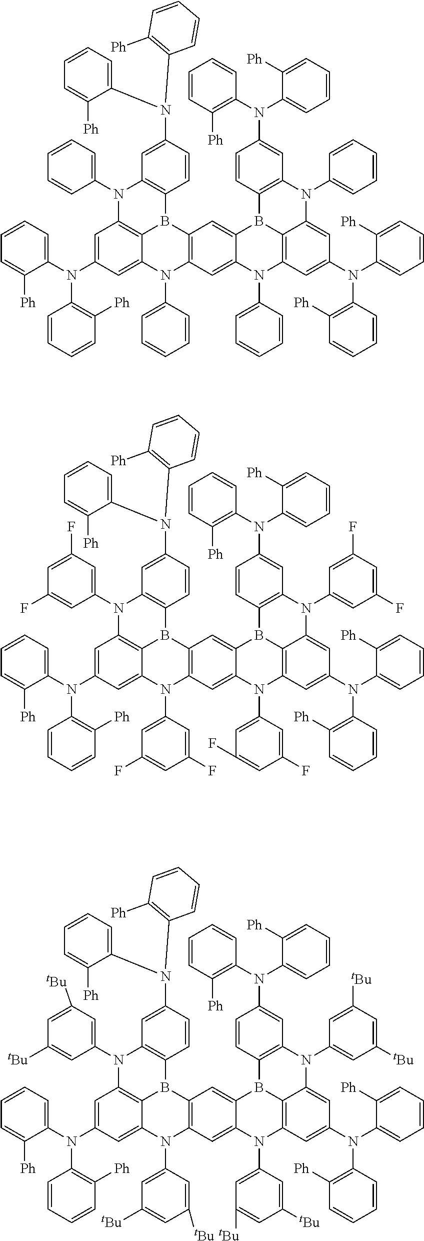

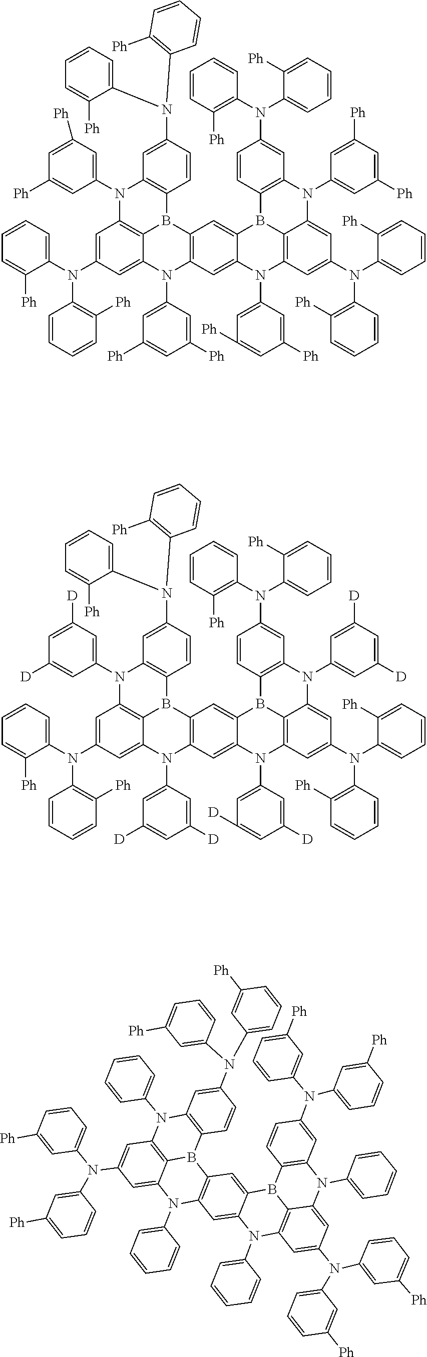

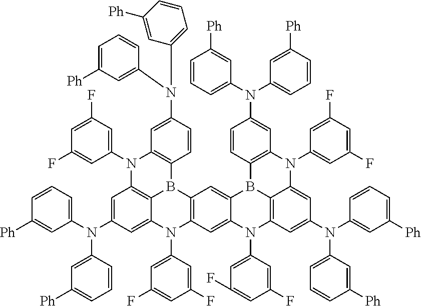 [SMILES: Fc1cc(F)cc(N2c3cc(N(c4cccc(-c5ccccc5)c4)c4cccc(-c5ccccc5)c4)ccc3B3c4cc5c(cc4N(c4cc(F)cc(F)c4)c4cc(N(c6cccc(-c7ccccc7)c6)c6cccc(-c7ccccc7)c6)cc2c43)N(c2cc(F)cc(F)c2)c2cc(N(c3cccc(-c4ccccc4)c3)c3cccc(-c4ccccc4)c3)cc3c2B5c2ccc(N(c4cccc(-c5ccccc5)c4)c4cccc(-c5ccccc5)c4)cc2N3c2cc(F)cc(F)c2)c1]

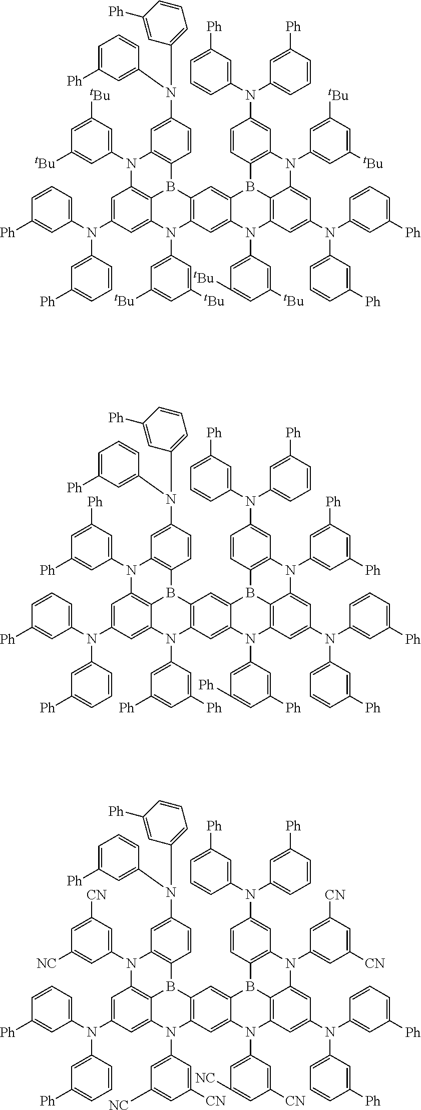

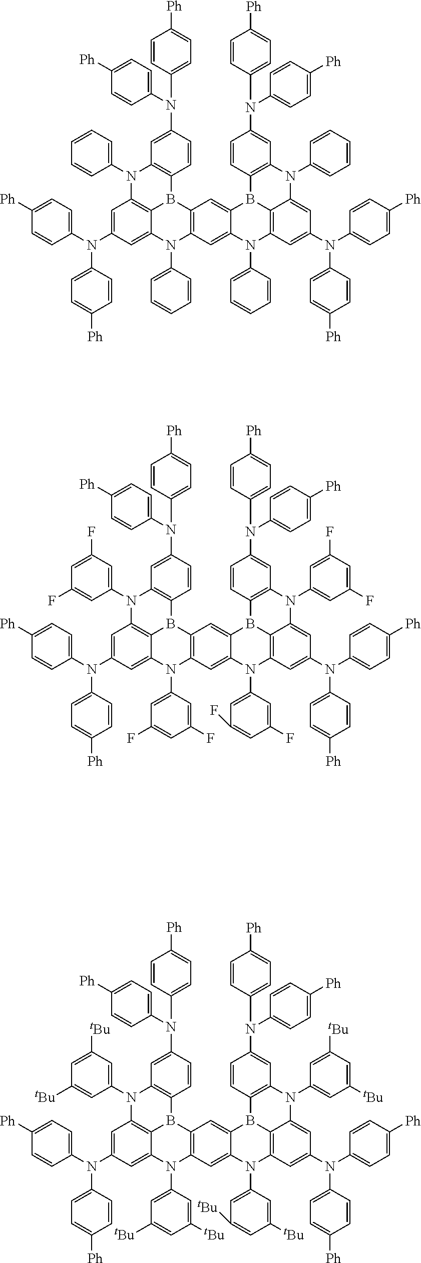

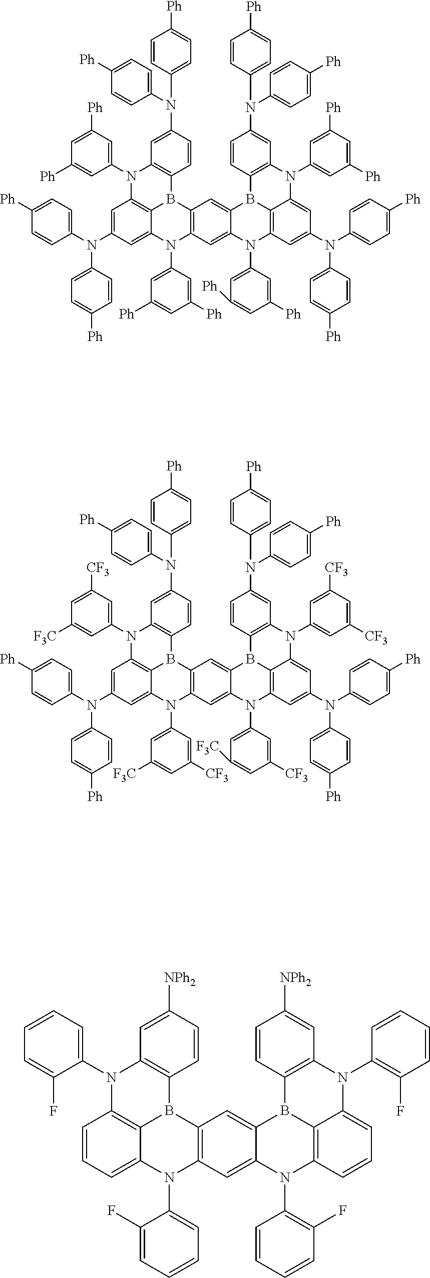

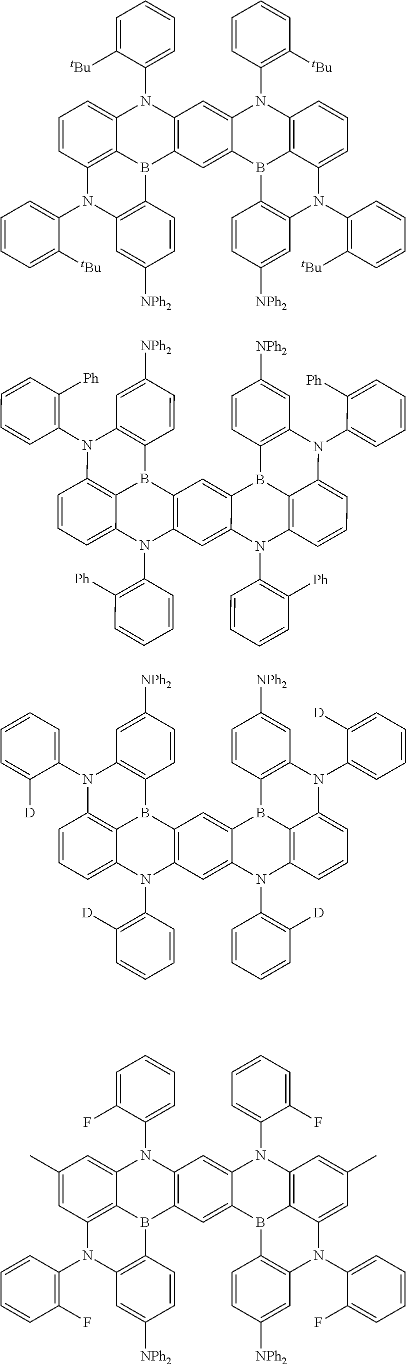

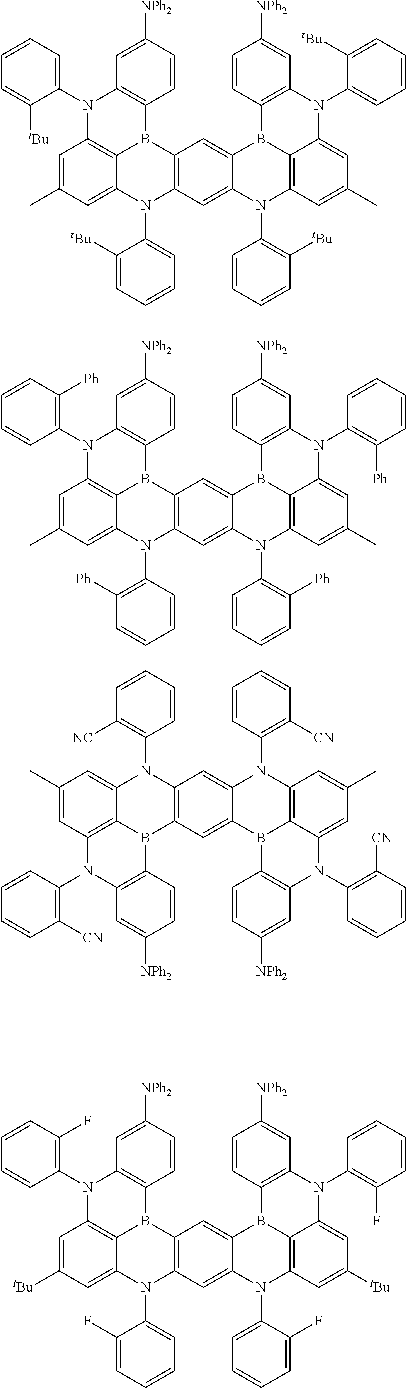

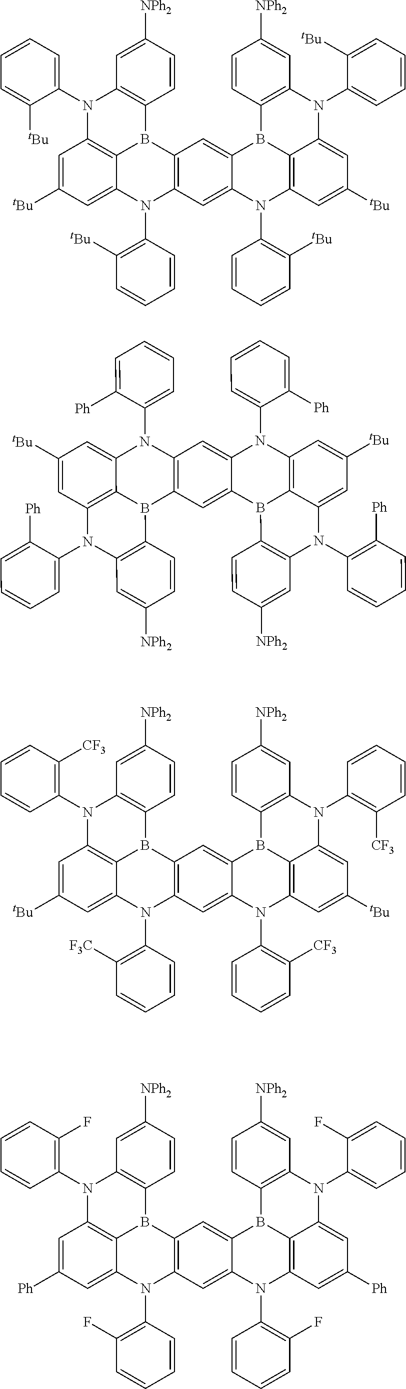

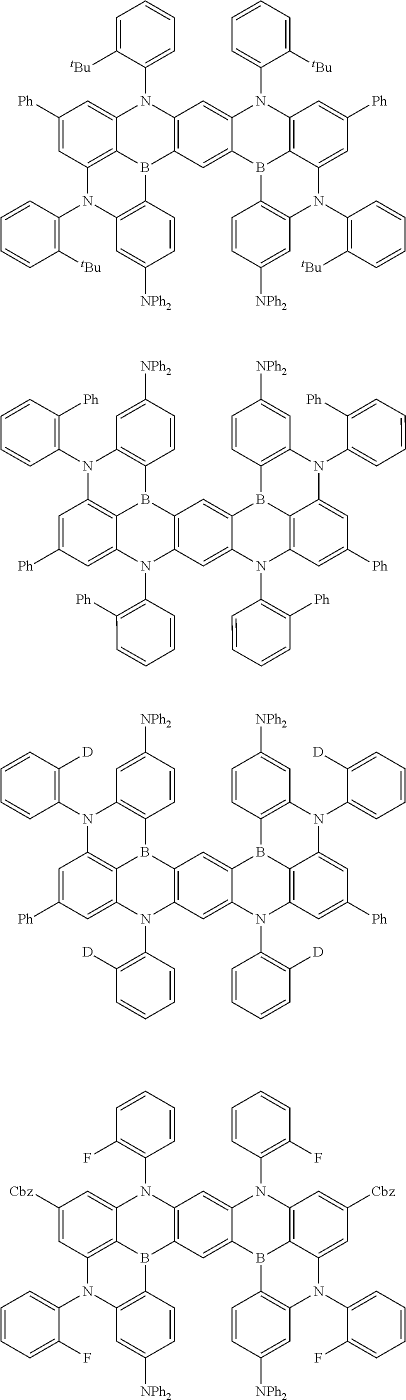

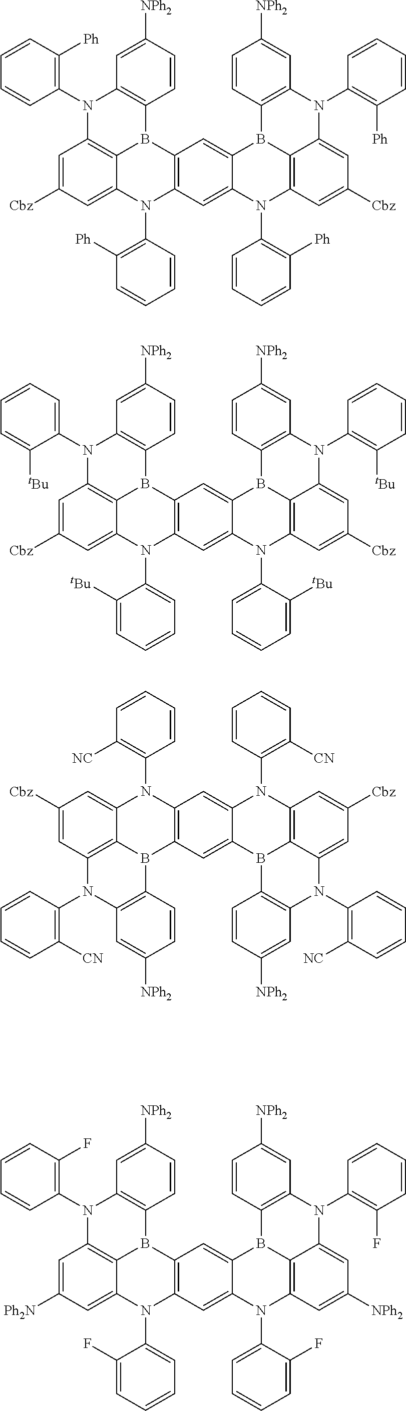

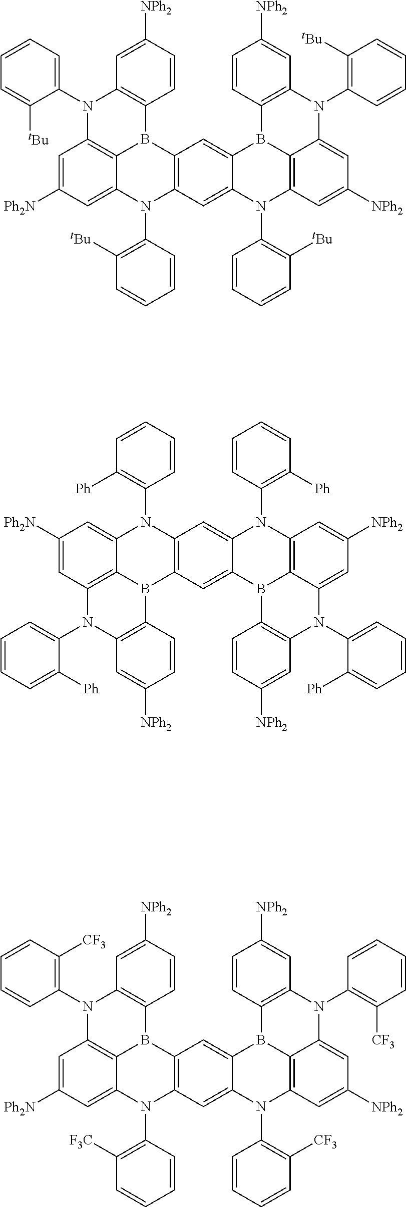

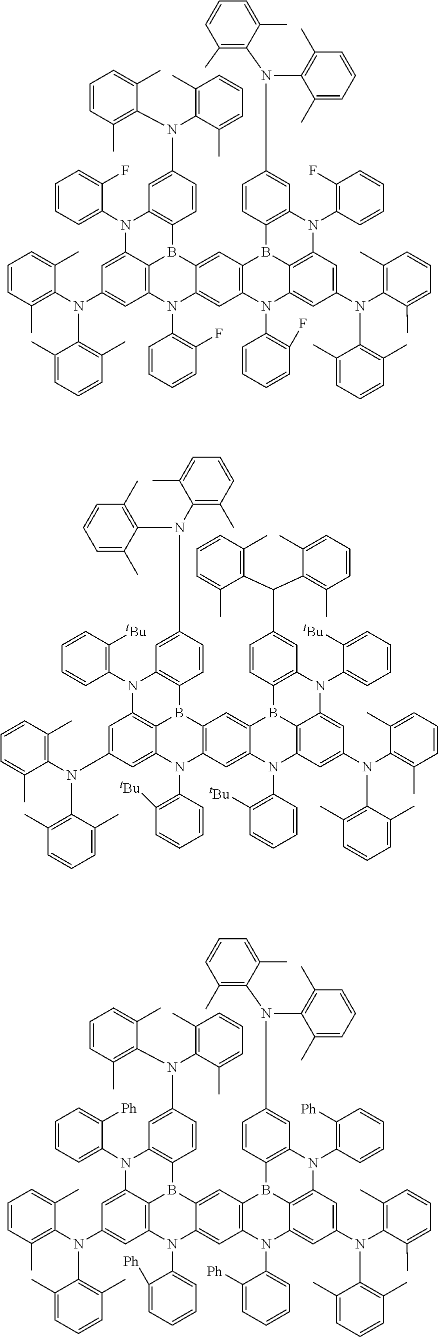

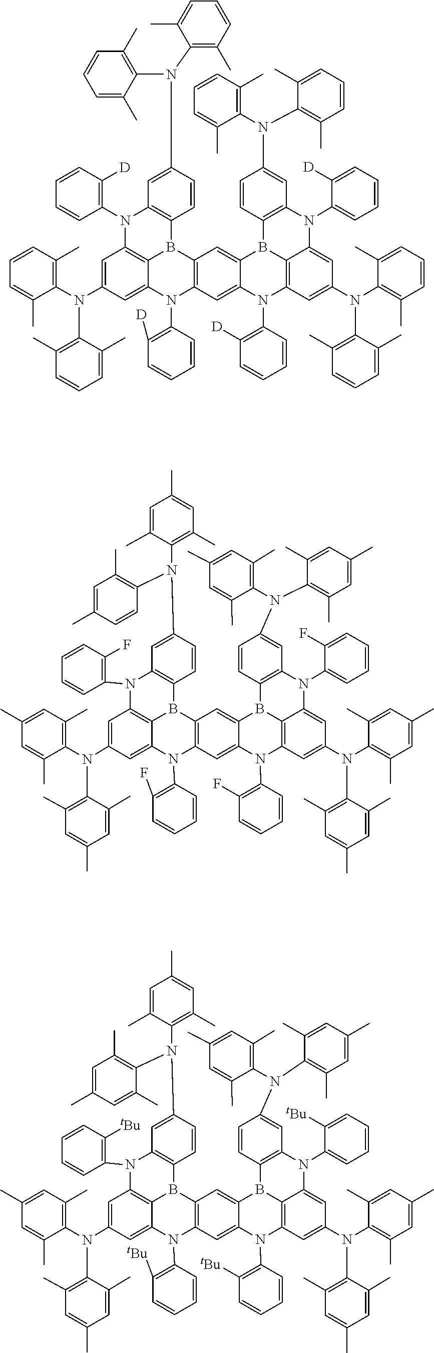

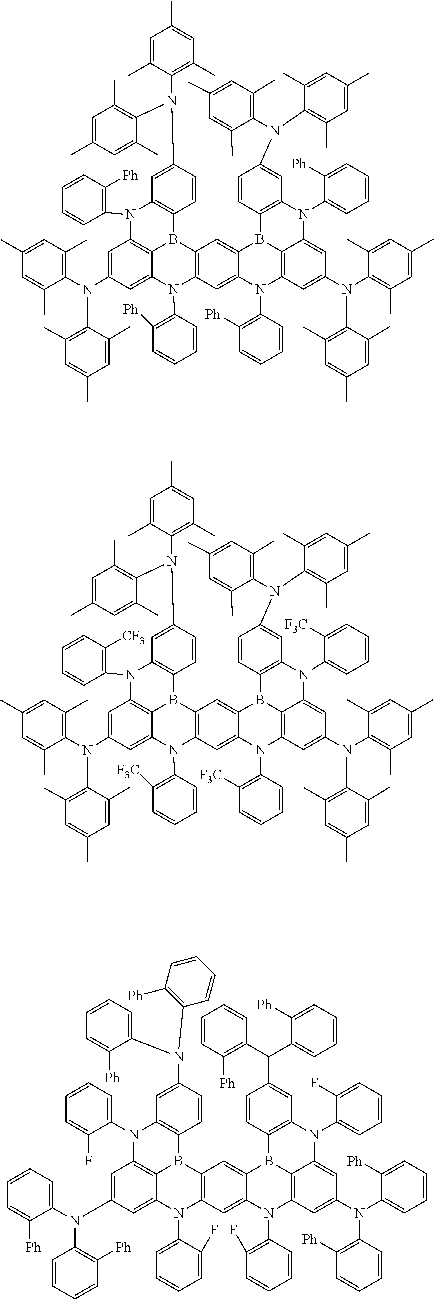

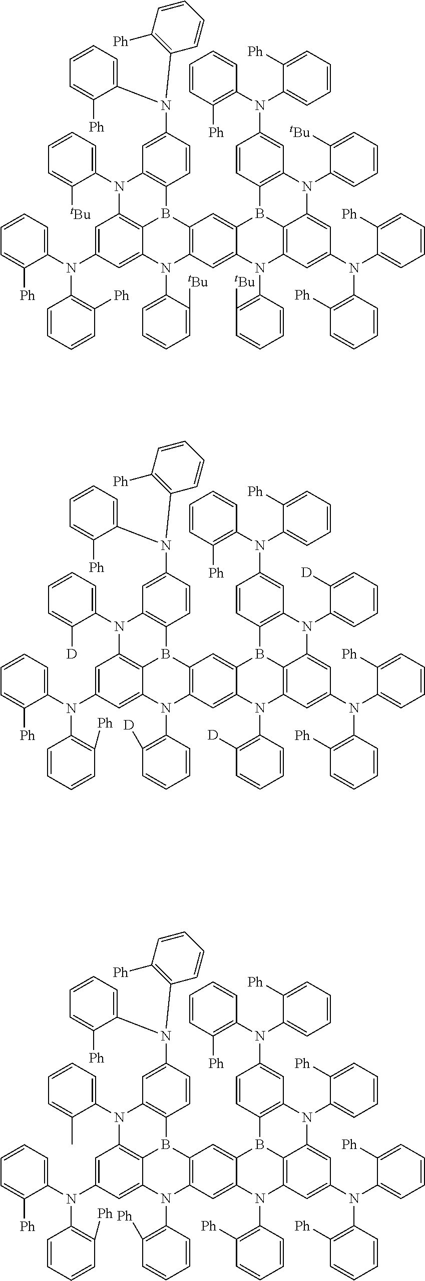

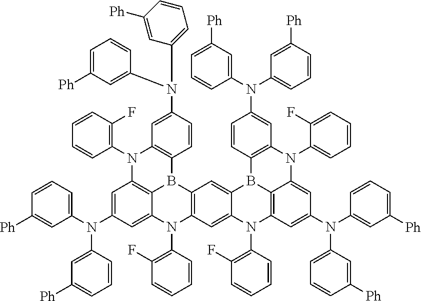 [SMILES: Fc1ccccc1N1c2cc(N(c3cccc(-c4ccccc4)c3)c3cccc(-c4ccccc4)c3)ccc2B2c3cc4c(cc3N(c3ccccc3F)c3cc(N(c5cccc(-c6ccccc6)c5)c5cccc(-c6ccccc6)c5)cc1c32)N(c1ccccc1F)c1cc(N(c2cccc(-c3ccccc3)c2)c2cccc(-c3ccccc3)c2)cc2c1B4c1ccc(N(c3cccc(-c4ccccc4)c3)c3cccc(-c4ccccc4)c3)cc1N2c1ccccc1F]

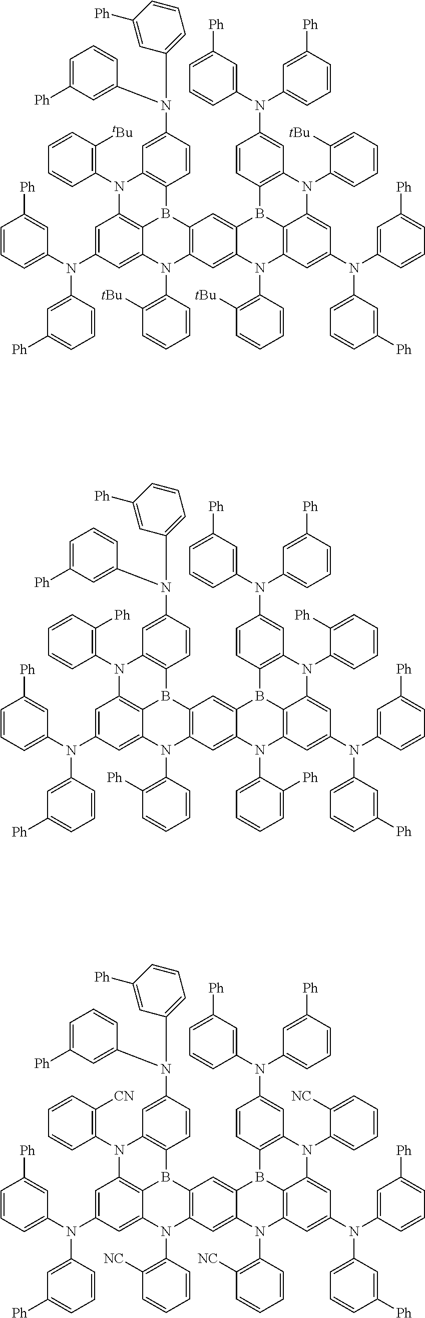

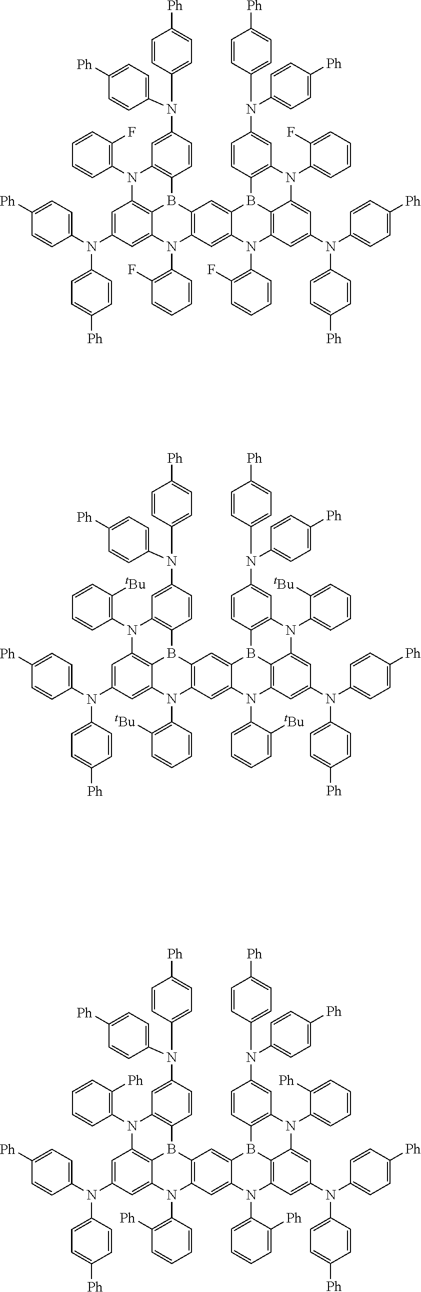

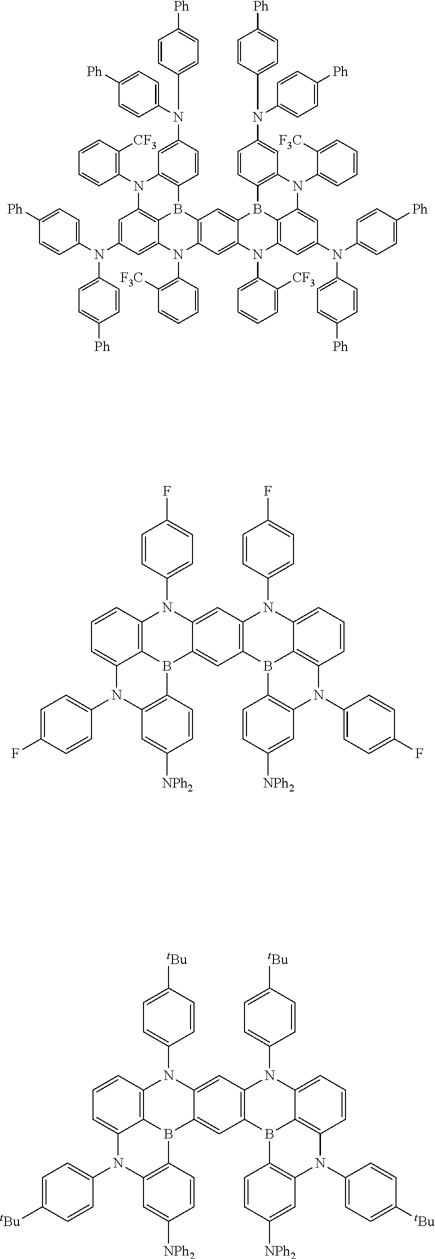

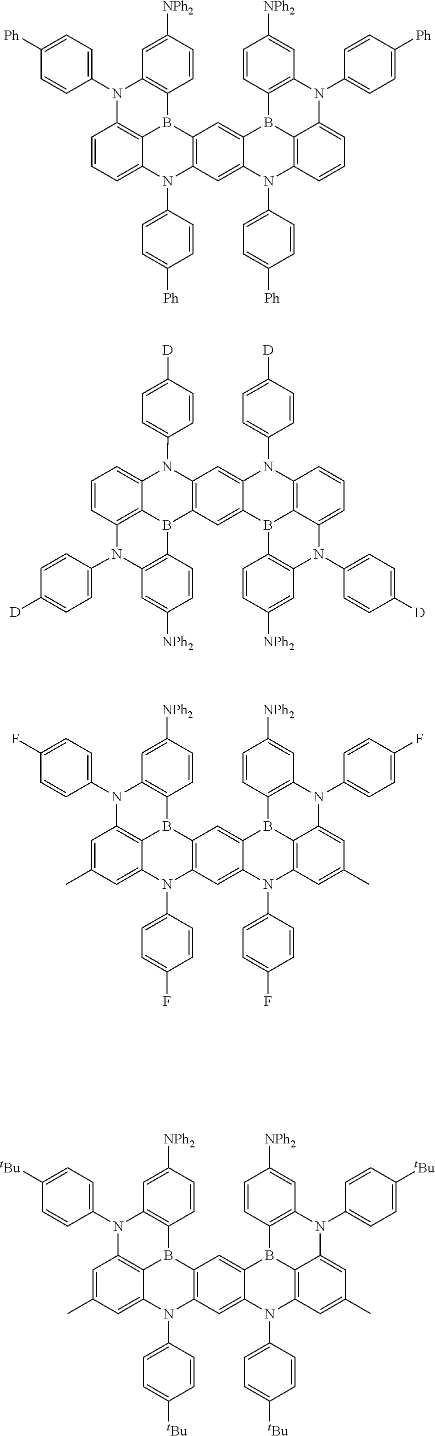

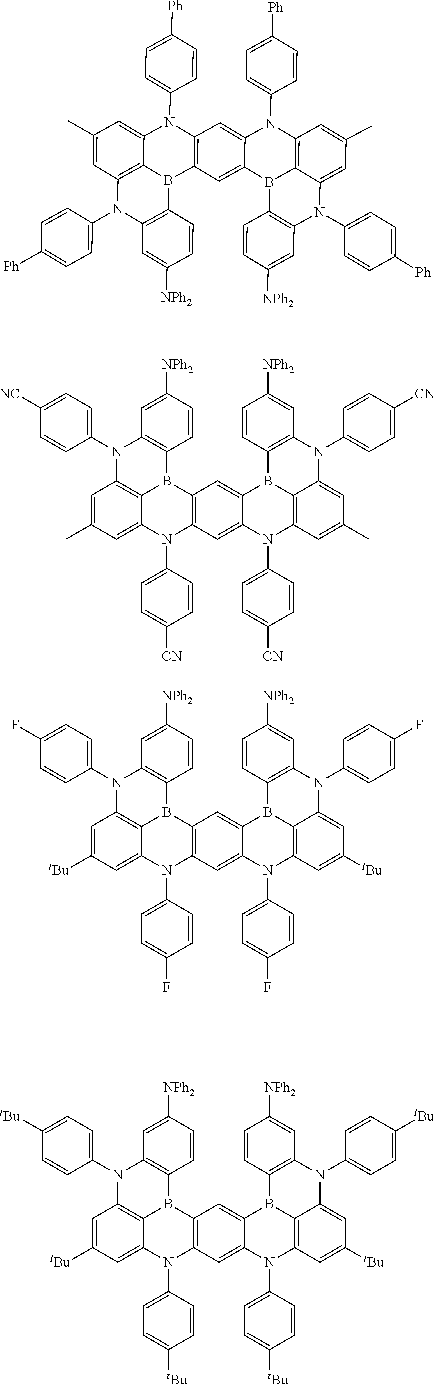

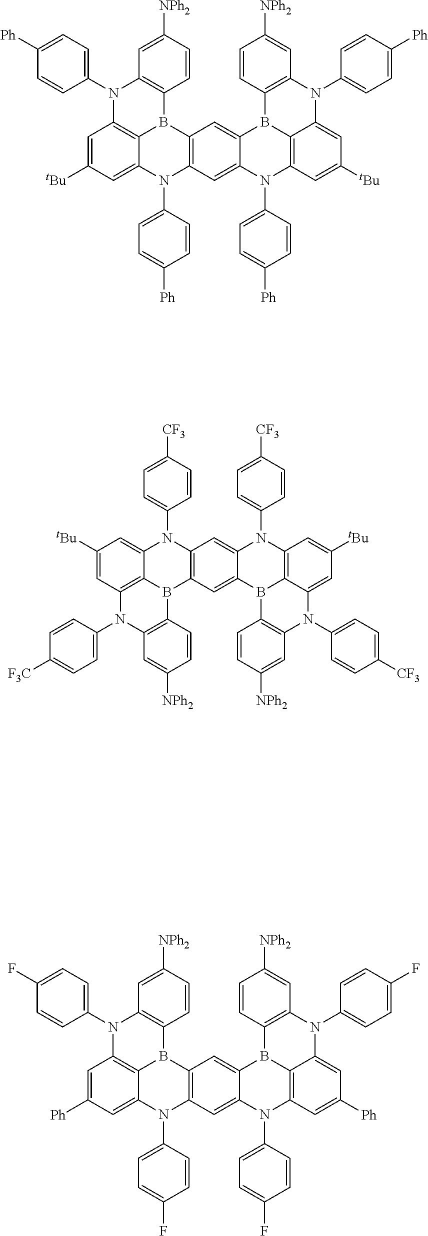

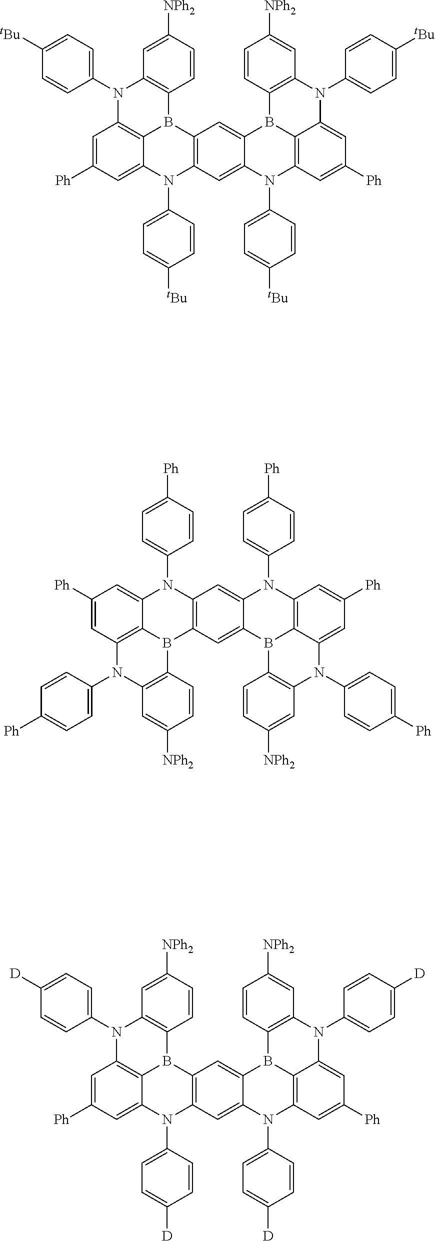

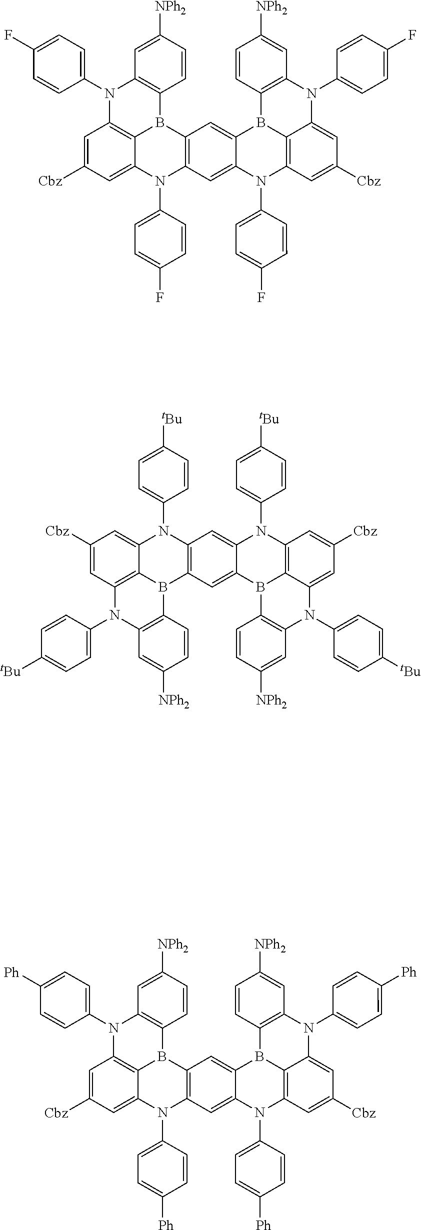

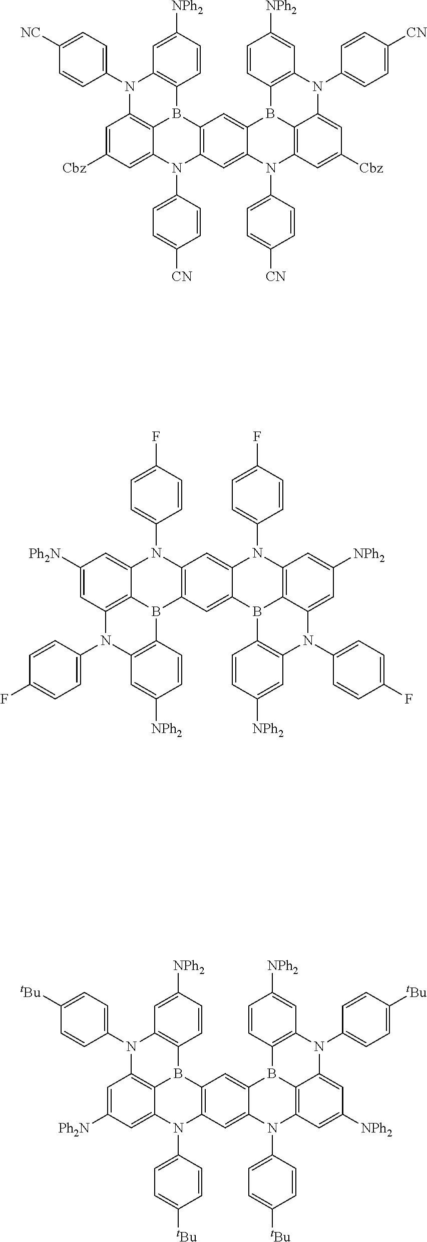

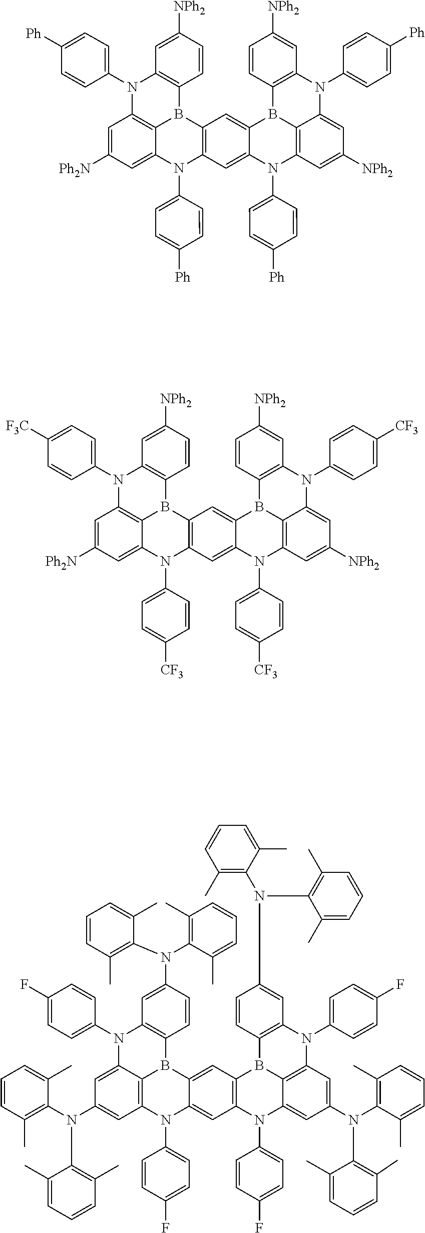

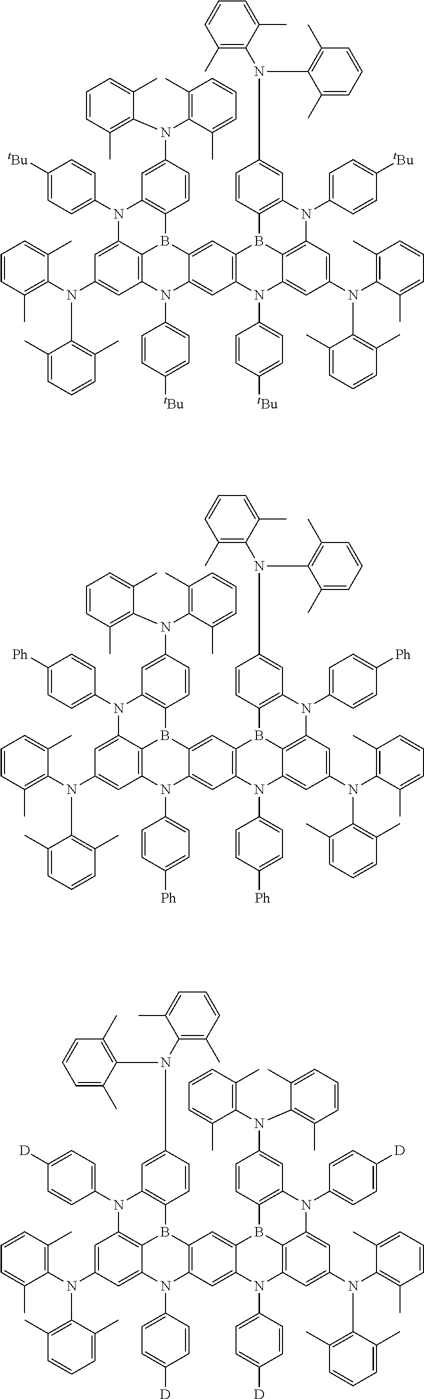

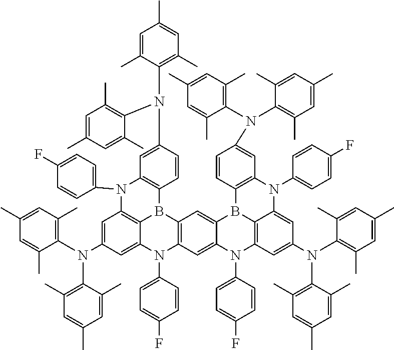

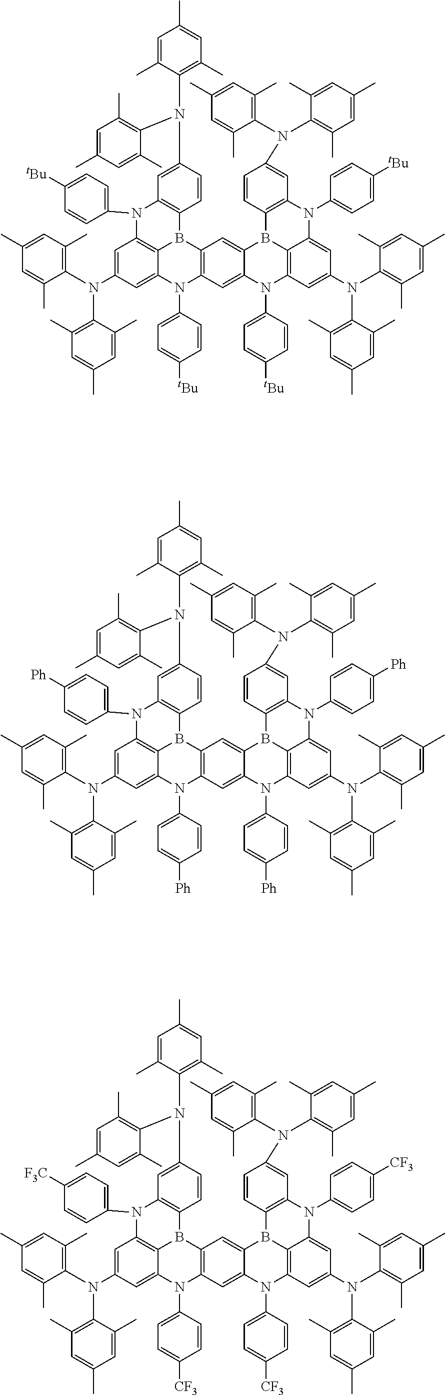

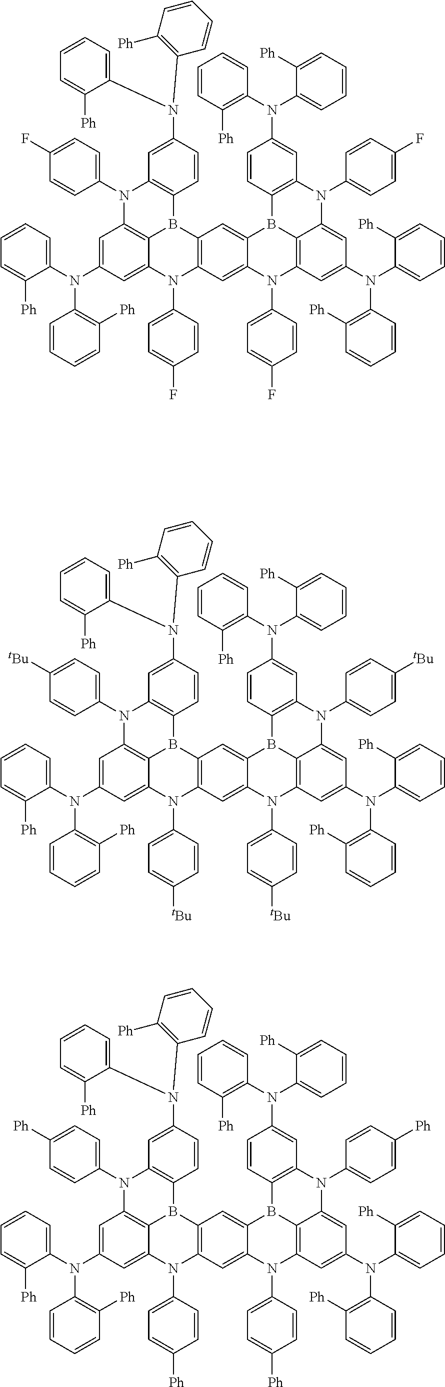

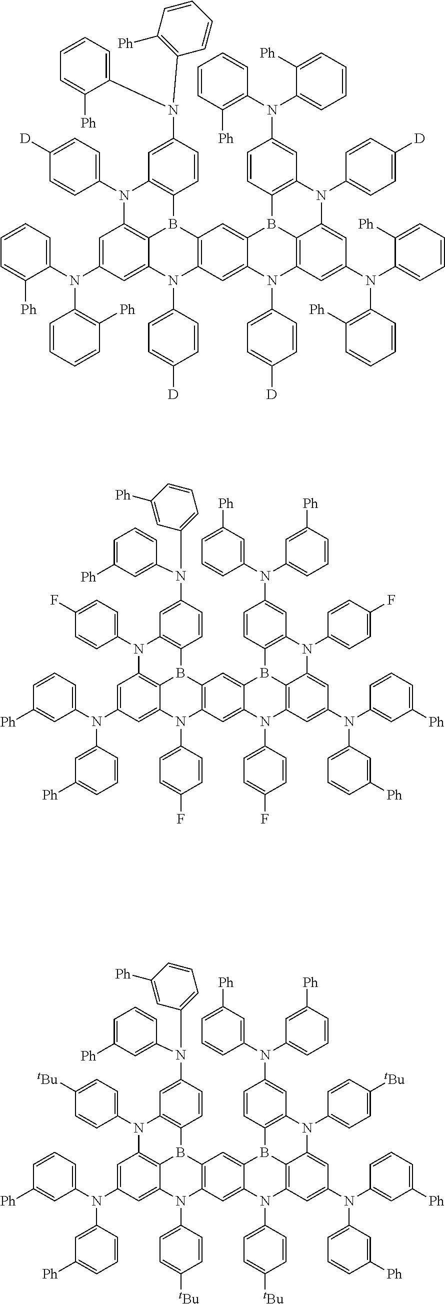

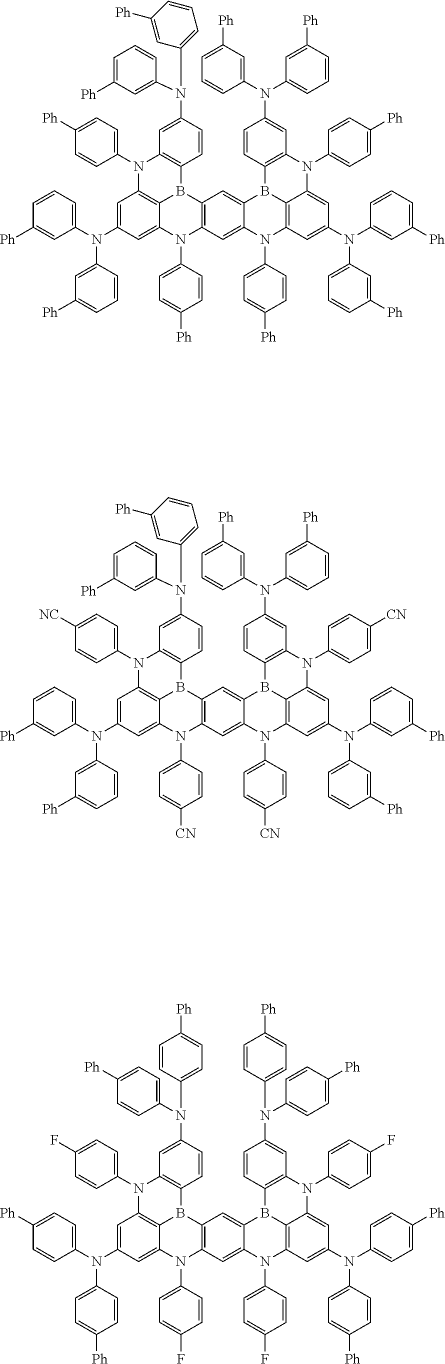

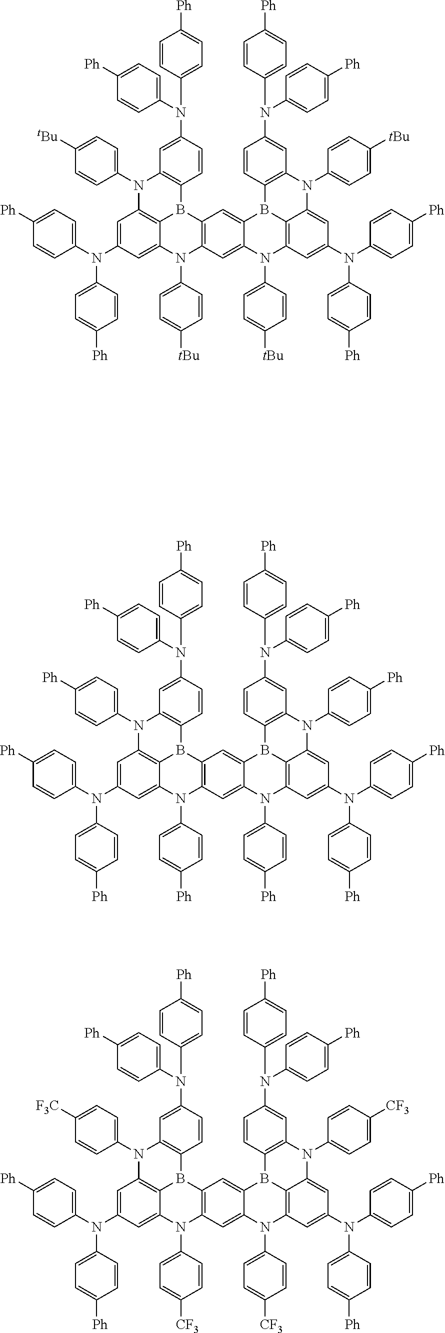

1. An organic molecule represented by formula I: 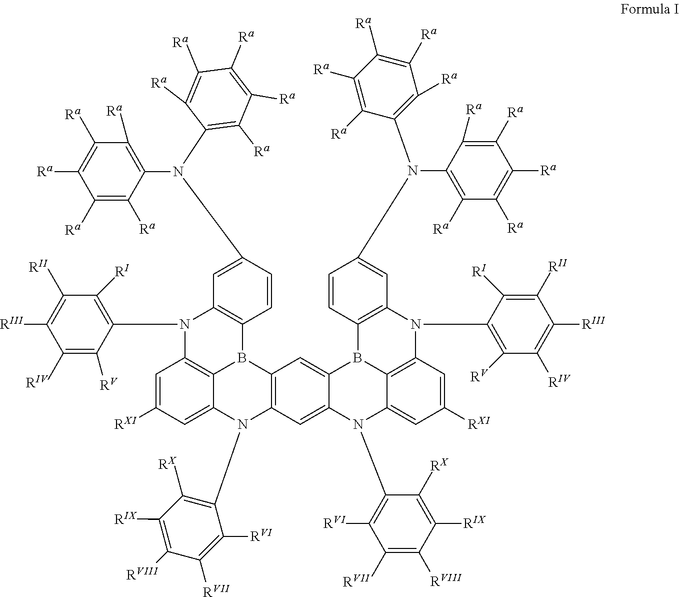
wherein:
R^{a} is at each occurrence independently selected from the group consisting of:
hydrogen, deuterium, N(R⁵)₂, OR⁵, SR⁵, CF₃, CN, F, Cl, Br, I,
C₁-C₄₀-alkyl,
which is optionally substituted with one or more substituents R⁵ and
wherein one or more non-adjacent CH₂— groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂— groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂— groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₃-C₅₇-heteroaryl,
which is optionally substituted with one or more substituents R⁵;
R⁵ is at each occurrence independently selected from the group consisting of:
hydrogen, deuterium, F, Cl, Br, I,
C₁-C₁₂-alkyl,
wherein optionally one or more hydrogen atoms are independently substituted by R⁶;
C₆-C₁₈-aryl,
wherein optionally one or more hydrogen atoms are independently substituted R⁶; and
C₃-C₁₅-heteroaryl,
wherein optionally one or more hydrogen atoms are independently substituted R⁶;
R⁶ is at each occurrence independently selected from the group consisting of:
hydrogen, deuterium, F, Cl, Br, I, C₁-C₁₂-alkyl,
C₆-C₁₈-aryl,
wherein optionally one or more hydrogen atoms are independently substituted by C₁-C₁₅-alkyl substituents; and
C₃-C₁₅-heteroaryl,
wherein optionally one or more hydrogen atoms are independently substituted by C₁-C₁₅-alkyl substituents;
R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen, deuterium, N(R⁴)₂, OR⁴, SR⁴, Si(R⁴)₃, B(OR⁴)₂, OSO₂R⁴, CF₃, CN, F, Cl, Br, I,
C₁-C₄₀-alkyl,
which is optionally substituted with one or more substituents R⁴ and
wherein one or more non-adjacent CH₂— groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-alkoxy,
which is optionally substituted with one or more substituents R⁴ and
wherein one or more non-adjacent CH₂— groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-thioalkoxy,
which is optionally substituted with one or more substituents R⁴ and
wherein one or more non-adjacent CH₂— groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkenyl,
which is optionally substituted with one or more substituents R⁴ and
wherein one or more non-adjacent CH₂— groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkynyl,
which is optionally substituted with one or more substituents R⁴ and
wherein one or more non-adjacent CH₂— groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₆₀-aryl,
which is optionally substituted with one or more substituents R⁴; and
C₃-C₅₇-heteroaryl,
which is optionally substituted with one or more substituents R⁴;
R⁴ is at each occurrence independently from another selected from the group consisting of:
hydrogen, deuterium, F, Cl, Br, I, OPh, SPh, CF₃, CN, Si(C₁-C₅-alkyl)₃, Si(Ph)₃, C₁-C₅-alkyl,
wherein optionally one or more hydrogen atoms are independently substituted by deuterium, F, Cl, Br, I, CN, or CF₃;
C₁-C₅-alkoxy,
wherein optionally one or more hydrogen atoms are independently substituted by deuterium, F, Cl, Br, I, CN, or CF₃;
C₁-C₅-thioalkoxy,
wherein optionally one or more hydrogen atoms are independently substituted by deuterium, F, Cl, Br, I, CN, or CF₃;
C₂-C₅-alkenyl,
wherein optionally one or more hydrogen atoms are independently substituted by deuterium, F, C₁, Br, I, CN, or CF₃;
C₂-C₅-alkynyl,
wherein optionally one or more hydrogen atoms are independently substituted by deuterium, F, C₁, Br, I, CN, or CF₃;
C₆-C₁₈-aryl,
which is optionally substituted with one or more substituents R⁵;
C₃-C₁₇-heteroaryl,
which is optionally substituted with one or more substituents R⁵;
N(C₆-C₁₈-aryl)₂,
N(C₃-C₁₇-heteroaryl)₂; and
N(C₃-C₁₇-heteroaryl)(C₆-C₁₈-aryl).

2. The organic molecule according to claim 1, wherein the organic molecule is represented by formula III:

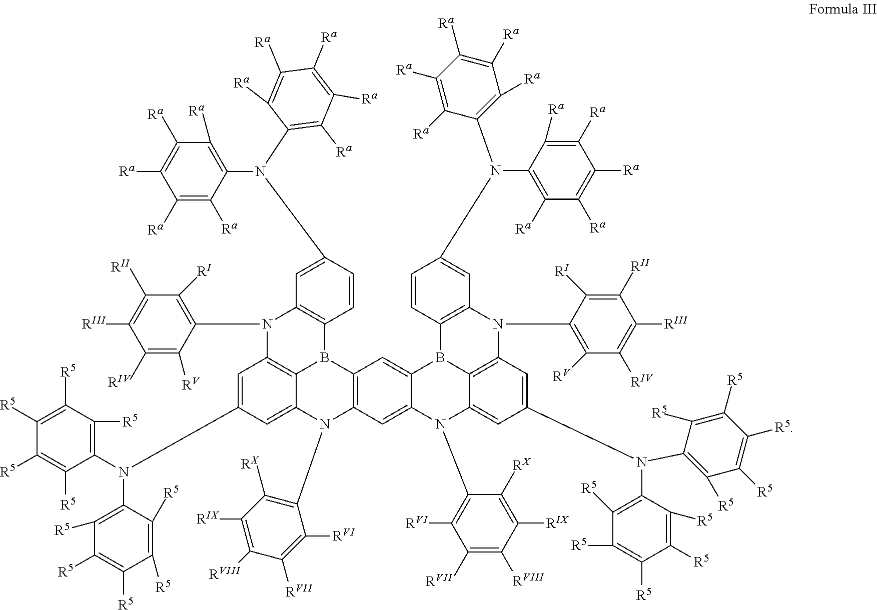

3. The organic molecule according to claim 1, wherein the organic molecule is represented by formula II-a:

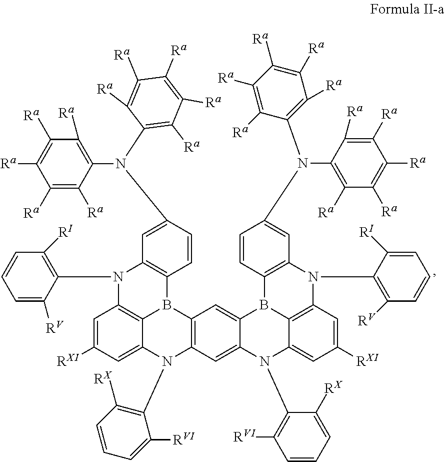

4. The organic molecule according to claim 1, wherein, R^{I}, R^{II}, R^{III}, R^{IV}, R^{V}, R^{VI}, R^{VII}, R^{VIII}, R^{IX}, R^{X}, and R^{XI} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

5. The organic molecule according to claim 1, wherein R^{I}, R^{II}, R^{III}, R^{IV}, R^{V}, R^{VI}, R^{VII}, R^{VIII}, R^{IX}, and R^{X} are at each occurrence independently selected from the group consisting of:
hydrogen,
Me, ⁱPr, ^{t}Bu, CN, CF₃, F,
Ph, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph.

6. The organic molecule according to claim 1, wherein R^{a} is at each occurrence independently selected from the group consisting of:
hydrogen,
Me, ⁱPr, ^{t}Bu, CN, CF₃, F,
aryl, which is optionally substituted with one or more substituents independently from each other selected from the group consisting of Me, ⁱPr, ^{t}Bu, CN, CF₃, F and Ph,
pyridinyl, which is optionally substituted with one or more substituents independently from each other selected from the group consisting of Me, ⁱPr, ^{t}Bu, CN, CF₃, F and Ph,
carbazolyl, which is optionally substituted with one or more substituents independently from each other selected from the group consisting of Me, ⁱPr, ^{t}Bu, CN, CF₃, F and Ph,
triazinyl, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

7. The organic molecule according to claim 1, wherein R^{XI} is at each occurrence independently selected from the group consisting of:
hydrogen,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, F and Ph,
and N(Ph)₂, which is optionally substituted with one or more substituents independently from each other selected from the group consisting of Me, ⁱPr, ^{t}Bu, F and Ph.

8. The organic molecule according to claim 1, wherein R^{V}═R^{X} and R^{I}═R^{VI}.

9-15. (canceled)

16. A composition, comprising:
(a) an organic molecule according to claim 1, and
(b) an emitter and/or a host material, which differs from the organic molecule, and
(c) optionally, a dye and/or a solvent.

17. An optoelectronic device, comprising an organic molecule according to claim 1.

18. Optoelectronic device according to claim 17 in the form of a device selected from the group consisting of organic light-emitting diode (OLED), light-emitting electrochemical cell, OLED-sensor, organic diode, organic solar cell, organic transistor, organic field-effect transistor, organic laser, and down-conversion element.

19. The optoelectronic device according to claim 17, comprising:
a substrate,
an anode, and
a cathode, wherein the anode or the cathode is on the substrate, and
a light-emitting layer, which is arranged between the anode and the cathode and which comprises the organic molecule or the composition.

20. A method for producing an optoelectronic device, wherein an organic molecule according to claim 1 is used, the method comprising the processing of the organic molecule by a vacuum evaporation method or from a solution.
